(19) United States
(12) Patent Application Publication
(10) Pub. No.: US 2024/0313501 A1
(43) Pub. Date: Sep. 19, 2024

(54) SEMICONDUCTOR LIGHT EMITTING DEVICE AND SEMICONDUCTOR LIGHT EMITTING UNIT

(71) Applicant: ROHM CO., LTD., Kyoto (JP)

(72) Inventor: Koki SAKAMOTO, Kyoto-shi (JP)

(21) Appl. No.: 18/672,653

(22) Filed: May 23, 2024

Related U.S. Application Data
(63) Continuation of application No. PCT/JP2022/044005, filed on Nov. 29, 2022.

(30) Foreign Application Priority Data
Nov. 30, 2021 (JP) 2021-194116

(51) Int. Cl. H01S 5/023; H01S 5/024; H01S 5/042

(52) U.S. Cl. CPC H01S 5/023; H01S 5/02469; H01S 5/042

(57) ABSTRACT

This semiconductor light emitting device comprises: a substrate that has a substrate front surface, a substrate back surface, and substrate lateral surfaces; front-surface-side wiring; back-surface-side wiring; and a semiconductor light emitting element that has a light emitting element lateral surface as a light emitting surface. The substrate lateral surfaces include a first substrate lateral surface which faces the same side as the light emitting element lateral surface that is a light emitting surface, and a second substrate lateral surface on the reverse side from the first substrate lateral surface. The semiconductor light emitting element is disposed so as to be offset more toward the first substrate lateral surface than the second substrate lateral surface. Provided to the first substrate lateral surface is an end surface through hole which passes through the substrate in the thickness direction of the substrate and which connects the front-surface-side wiring and the back-surface-side wiring.

### CROSS-REFERENCE TO RELATED APPLICATIONS

This application is a continuation of, and claims the benefit of priority from International Application No. PCT/JP2022/044005, filed on Nov. 29, 2022, which claims the benefit of priority from Japanese Patent Application No. 2021-194116, filed on Nov. 30, 2021, the entire contents of each of which are incorporated herein by reference.

### BACKGROUND

### 1. Field

The following description relates to a semiconductor light emitting device and a semiconductor light emitting unit.

### 2. Description of Related Art

Japanese Laid-Open Patent Publication No. 2016-29718 describes an example of a semiconductor laser device that includes a semiconductor light emitting element as the source of laser light, which is one type of semiconductor light emitting device. Such a semiconductor laser device is widely used as a light source device mounted on various electronic apparatuses.

### BRIEF DESCRIPTION OF THE DRAWINGS

FIG. 1 is a perspective view showing a first embodiment of a semiconductor light emitting device.

FIG. 2 is a plan view of the semiconductor light emitting device shown in FIG. 1.

FIG. 3 is a plan view showing a substrate of the semiconductor light emitting device shown in FIG. 1.

FIG. 4 is a back view of the substrate shown in FIG. 3.

FIG. 5 is a cross-sectional view of the semiconductor light emitting device taken along line F5-F5 in FIG. 2.

FIG. 6 is an enlarged view of a semiconductor light emitting element and its surroundings shown in FIG. 2.

FIG. 7 is a side view of the semiconductor light emitting device shown in FIG. 1.

FIG. 8 is a side view of the semiconductor light emitting device in a direction different from that of FIG. 7.

FIG. 9 is a circuit diagram of a laser system including the semiconductor light emitting device of the first embodiment.

FIG. 10 is a graph showing a thermal conductivity analysis result of a comparative example of a semiconductor light emitting device that includes a substrate having a thickness of 0.3 mm.

FIG. 11 is a graph showing a thermal conductivity analysis result of a comparative example of a semiconductor light emitting device that includes a substrate having a thickness of 0.6 mm.

FIG. 12 is a graph showing a thermal conductivity analysis result of a comparative example of a semiconductor light emitting device that includes a substrate having a thickness of 0.8 mm.

FIG. 13 is a graph showing a thermal conductivity analysis result of the semiconductor light emitting device of the first embodiment when the substrate has a thickness of 0.3 mm.

FIG. 14 is a graph showing a thermal conductivity analysis result of the semiconductor light emitting device of the first embodiment when the substrate has a thickness of 0.6 mm.

FIG. 15 is a graph showing a thermal conductivity analysis result of the semiconductor light emitting device of the first embodiment when the substrate has a thickness of 0.8 mm.

FIG. 16 is a perspective view of a semiconductor light emitting unit that includes a second embodiment of a semiconductor light emitting device.

FIG. 17 is a schematic cross-sectional view showing the semiconductor light emitting unit shown in FIG. 16.

FIG. 18 is a schematic perspective view showing a stem and lead pins of the semiconductor light emitting unit shown in FIG. 16.

FIG. 19 is a schematic perspective view of the stem and the lead pins from a side opposite to that of FIG. 18.

FIG. 20 is a schematic plan view showing the semiconductor light emitting device of the second embodiment.

FIG. 21 is a plan view showing a substrate of the semiconductor light emitting device shown in FIG. 20.

FIG. 22 is a back view of the substrate shown in FIG. 21.

FIG. 23 is a cross-sectional view of the semiconductor light emitting device taken along line F23-F23 in FIG. 20.

FIG. 24 is a cross-sectional view of the semiconductor light emitting device taken along line F24-F24 in FIG. 20.

FIG. 25 is an enlarged view of the semiconductor light emitting element and its surroundings shown in FIG. 20.

FIG. 26 is a perspective view showing a third embodiment of a semiconductor light emitting device.

FIG. 27 is a schematic side view of the semiconductor light emitting device shown in FIG. 26.

FIG. 28 is a plan view showing a front surface substrate included in a substrate of the semiconductor light emitting device shown in FIG. 26.

FIG. 29 is a plan view showing a back surface substrate included in the substrate shown in FIG. 28.

FIG. 30 is a back view of the back surface substrate shown in FIG. 29.

FIG. 31 is a schematic cross-sectional view of the semiconductor light emitting device taken along line F31-F31 in FIG. 28.

FIG. 32 is a schematic plan view of a modified example of a semiconductor light emitting device enlarging a semiconductor light emitting element and its surroundings.

FIG. 33 is a schematic plan view of a modified example of a semiconductor light emitting device enlarging a semiconductor light emitting element and its surroundings.

FIG. 34 is a schematic plan view of a modified example of a semiconductor light emitting device enlarging a semiconductor light emitting element and its surroundings.

FIG. 35 is a schematic plan view of a modified example of a semiconductor light emitting device enlarging a semiconductor light emitting element and its surroundings.

FIG. 36 is a schematic side view of a modified example of the semiconductor light emitting device.

FIG. 37 is a schematic plan view of a modified example of a semiconductor light emitting device.

FIG. 38 is a plan view showing a front surface substrate included in a substrate of a semiconductor light emitting device in a modified example.

FIG. 39 is a plan view showing a back surface substrate included in the substrate shown in FIG. 38.

FIG. 40 is a back view of the back surface substrate shown in FIG. 39.

FIG. 41 is a schematic plan view of a modified example of a semiconductor light emitting device.

FIG. 42 is a graph showing a thermal conductivity analysis result of a modified example of a semiconductor light emitting device when the substrate is formed from glass epoxy resin.

FIG. 43 is a graph showing a thermal conductivity analysis result of a modified example of a semiconductor light emitting device when the substrate is formed from alumina.

FIG. 44 is a graph showing a thermal conductivity analysis result of a modified example of a semiconductor light emitting device when the substrate is formed from aluminum nitride.

### DETAILED DESCRIPTION

Embodiments of a semiconductor light emitting device and a semiconductor light emitting unit according to the present disclosure will be described below with reference to the drawings. In the drawings, elements may not be drawn to scale for simplicity and clarity of illustration. In a cross-sectional view, hatching may be omitted to facilitate understanding. The accompanying drawings only illustrate embodiments of the present disclosure and are not intended to limit the present disclosure.

The following detailed description includes exemplary embodiments of a device, a system, and a method according to the present disclosure. The detailed description is illustrative and is not intended to limit embodiments of the present disclosure or the application and use of the embodiments.

### First Embodiment

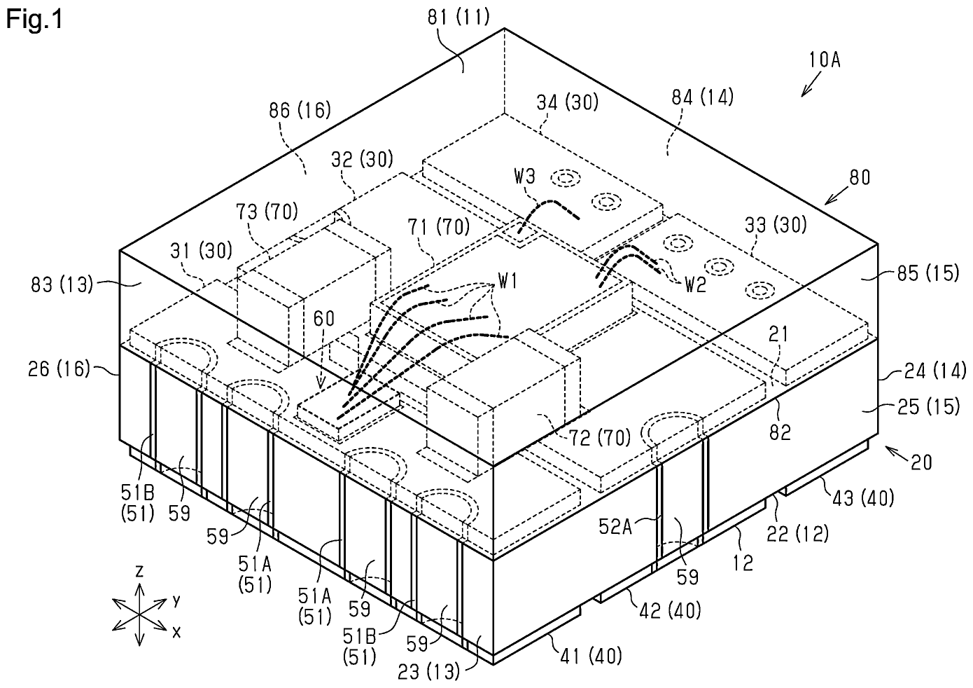

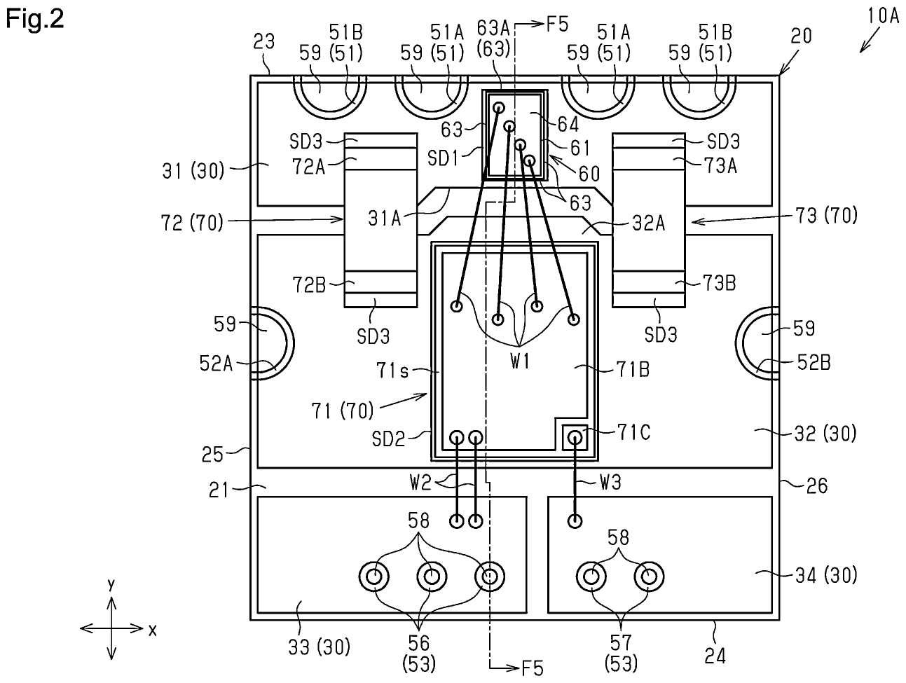

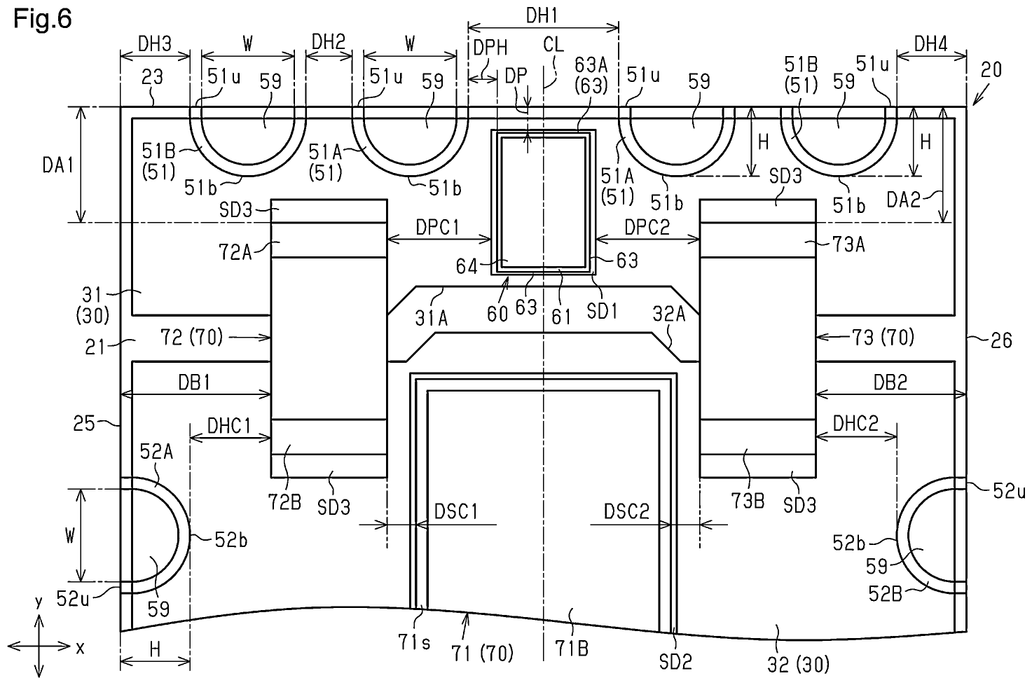

The structure of a first embodiment of a semiconductor light emitting device will now be described with reference to FIGS. 1 to 8. For the sake of convenience, FIGS. 2 and 6 to 8 do not show an encapsulation resin 80, which will be described later. For the sake of convenience, FIGS. 1, 7, and 8 do not show a back surface insulation layer 45, which will be described later. For the sake of convenience, FIGS. 6 to 8 do not show a first wire W1, which will be described later.

FIG. 1 shows a semiconductor light emitting device 10A that may be used in, for example, a laser system such as light detection and ranging (LiDAR), or laser imaging detection and ranging, which is an example of three-dimensional distance measurement. The semiconductor light emitting device 10A may also be used in a laser system of two-dimensional distance measurement.

As shown in FIG. 1, the semiconductor light emitting device 10A is rectangular and flat. The semiconductor light emitting device 10A includes a device front surface 11 and a device back surface 12, which face opposite directions, and first to fourth device side surfaces 13 to 16, each of which extends in a direction intersecting with the device front surface 11 and the device back surface 12. In the present embodiment, the first to fourth device side surfaces 13 to 16 extend in a direction orthogonal to the device front surface 11 and the device back surface 12.

The device front surface 11 and the device back surface 12 are separate from each other. In the present embodiment, a direction in which the device front surface 11 and the device back surface 12 are arranged is referred to as a z-direction. The z-direction is referred to as the height-wise direction (thickness-wise direction) of the semiconductor light emitting device 10A. Two directions that are orthogonal to the z-direction and orthogonal to each other are referred to as an x-direction and a y-direction.

In the present embodiment, the first device side surface 13 and the second device side surface 14 define opposite end surfaces of the semiconductor light emitting device 10A in the x-direction. The third device side surface 15 and the fourth device side surface 16 define opposite end surfaces of the semiconductor light emitting device 10A in the y-direction. As viewed in the z-direction, the first device side surface 13 and the second device side surface 14 extend in the x-direction. The third device side surface 15 and the fourth device side surface 16 extend in the y-direction. The first device side surface 13 and the second device side surface 14 face opposite directions in the y-direction. The third device side surface 15 and the fourth device side surface 16 face opposite directions in the x-direction. In the present embodiment, as viewed in the z-direction, the semiconductor light emitting device 10A is square.

As shown in FIG. 1, the semiconductor light emitting device 10A includes a substrate 20. The substrate 20 is formed from an electrically insulative material. In the present embodiment, the substrate 20 is formed from a material including, for example, glass epoxy resin. As shown in FIG. 1, the substrate 20 is rectangular and flat and has a thickness-wise direction conforming to the z-direction. In the present embodiment, as viewed in the z-direction, the substrate 20 is square. The thickness of the substrate 20 is, for example, greater than or equal to 0.3 mm and less than or equal to 0.8 mm. In the z-direction, the substrate 20 is located in the semiconductor light emitting device 10A closer to the device back surface 12 than to the device front surface 11. The substrate 20 includes a portion of each of the first to fourth device side surfaces 13 to 16 in the z-direction.

More specifically, the substrate 20 includes a substrate front surface 21, a substrate back surface 22 opposite to the substrate front surface 21, and first to fourth substrate side surfaces 23 to 26, each of which is a substrate side surface. The substrate front surface 21 and the device front surface 11 face the same direction. The substrate back surface 22 and the device back surface 12 face the same direction. The first substrate side surface 23 and the first device side surface 13 face the same direction. The second substrate side surface 24 and the second device side surface 14 face the same direction. The third substrate side surface 25 and the third device side surface 15 face the same direction. The fourth substrate side surface 26 and the fourth device side surface 16 face the same direction. The first substrate side surface 23 forms a portion of the first device side surface 13 located close to the device back surface 12 in the z-direction. The second substrate side surface 24 forms a portion of the second device side surface 14 located close to the device back surface 12 in the z-direction. The third substrate side surface 25 forms a portion of the third device side surface 15 located close to the device back surface 12 in the z-direction. The fourth substrate side surface 26 forms a portion of the fourth device side surface 16 located close to the device back surface 12 in the z-direction.

The present embodiment further includes an encapsulation resin 80 formed on the substrate 20. Thus, the outer surface of the semiconductor light emitting device 10A is defined by the substrate 20 and the encapsulation resin 80. The encapsulation resin 80 is formed from a light-transmissive resin material. An example of the material forming the encapsulation resin 80 is a light-transmissive epoxy resin. The material forming the encapsulation resin 80 may be a light-transmissive acrylic resin. The encapsulation resin 80 is rectangular and flat and has a thickness-wise direction conforming to the z-direction. In the present embodiment, the thickness of the encapsulation resin 80 is equal to the thickness of the substrate 20. When the difference between the thickness of the encapsulation resin 80 and the thickness of the substrate 20 is, for example, within 10% of the thickness of the encapsulation resin 80, it is considered that the thickness of the encapsulation resin 80 is equal to the thickness of the substrate 20. The thickness of the encapsulation resin 80 may be changed in any manner. In an example, the encapsulation resin 80 may have a greater thickness than the substrate 20. In an example, the encapsulation resin 80 may have a smaller thickness than the substrate 20.

In the z-direction, the encapsulation resin 80 is located in the semiconductor light emitting device 10A closer to the device front surface 11 than to the device back surface 12. The encapsulation resin 80 includes the device front surface 11 and a portion of each of the first to fourth device side surfaces 13 to 16 in the z-direction.

More specifically, the encapsulation resin 80 includes an encapsulation front surface 81, an encapsulation back surface 82 opposite to the encapsulation front surface 81, and first to fourth encapsulation side surfaces 83 to 86. The encapsulation front surface 81 and the substrate front surface 21 face the same direction. The encapsulation back surface 82 and the substrate back surface 22 face the same direction. The encapsulation front surface 81 includes the device front surface 11. The encapsulation back surface 82 is in tight contact with the substrate front surface 21. The first encapsulation side surface 83 and the first device side surface 13 face the same direction. The second encapsulation side surface 84 and the second device side surface 14 face the same direction. The third encapsulation side surface 85 and the third device side surface 15 face the same direction. The fourth encapsulation side surface 86 and the fourth device side surface 16 face the same direction.

The first encapsulation side surface 83 forms a portion of the first device side surface 13 located toward the device front surface 11 in the z-direction. The second encapsulation side surface 84 forms a portion of the second device side surface 14 located toward the device front surface 11 in the z-direction. The third encapsulation side surface 85 forms a portion of the third device side surface 15 located toward the device front surface 11 in the z-direction. The fourth encapsulation side surface 86 forms a portion of the fourth device side surface 16 located toward the device front surface 11 in the z-direction. In other words, the first device side surface 13 includes the first encapsulation side surface 83 and the first substrate side surface 23. The second device side surface 14 includes the second encapsulation side surface 84 and the second substrate side surface 24. The third device side surface 15 includes the third encapsulation side surface 85 and the third substrate side surface 25. The fourth device side surface 16 includes the fourth encapsulation side surface 86 and the fourth substrate side surface 26.

In the present embodiment, the first encapsulation side surface 83 is flush with the first substrate side surface 23. The second encapsulation side surface 84 is flush with the second substrate side surface 24. The third encapsulation side surface 85 is flush with the third substrate side surface 25. The fourth encapsulation side surface 86 is flush with the fourth substrate side surface 26.

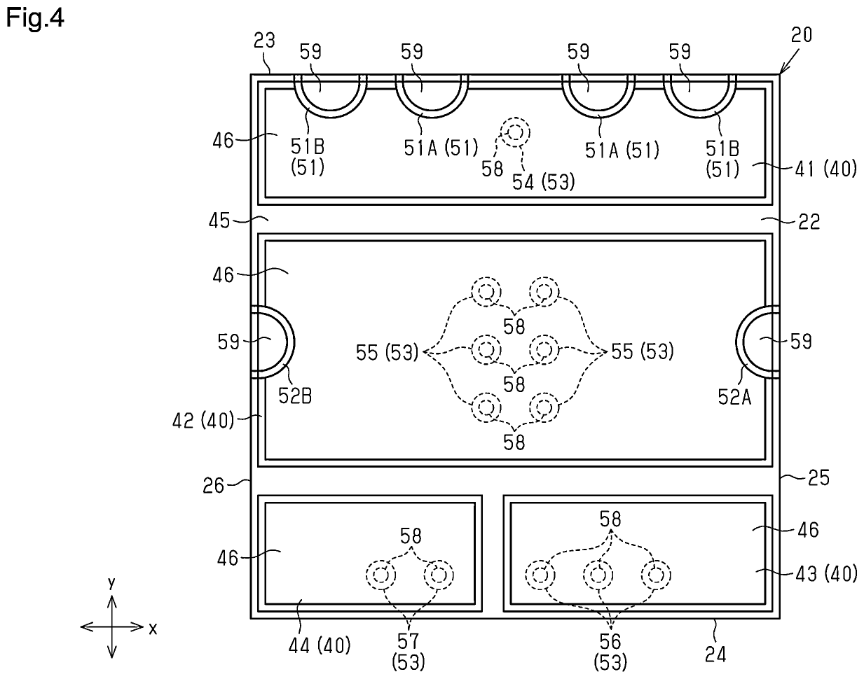

As shown in FIGS. 1 to 4, the semiconductor light emitting device 10A includes a front surface interconnect 30 formed on the substrate front surface 21, a back surface interconnect 40 (refer to FIG. 4) formed on the substrate back surface 22, and a semiconductor light emitting element 60 mounted on the front surface interconnect 30. The semiconductor light emitting device 10A further includes a light emitting element control circuit 70 mounted on the front surface interconnect 30. The light emitting element control circuit 70 is configured to have the semiconductor light emitting element 60 emit light and, in the present embodiment, includes a switching element 71 and two capacitors 72 and 73. As shown in FIG. 1, the front surface interconnect 30, the semiconductor light emitting element 60, and the light emitting element control circuit 70 are encapsulated by the encapsulation resin 80. The capacitor 72 corresponds to a “first capacitor.” The capacitor 73 corresponds to a “second capacitor.”

As shown in FIG. 2, the front surface interconnect 30 is electrically connected to the semiconductor light emitting element 60, the switching element 71, and the capacitors 72 and 73. The front surface interconnect 30 includes, for example, a metal layer and a plating layer formed on the metal layer. The metal layer includes, for example, a stack of a seed layer formed of a titanium (Ti) layer and an interconnect layer formed of a copper (Cu) layer. The interconnect layer is formed on the seed layer. The plating layer is formed on the interconnect layer. The plating layer includes, for example, a stack of a nickel (Ni) layer, a palladium (Pd) layer, and a gold (Au) layer.

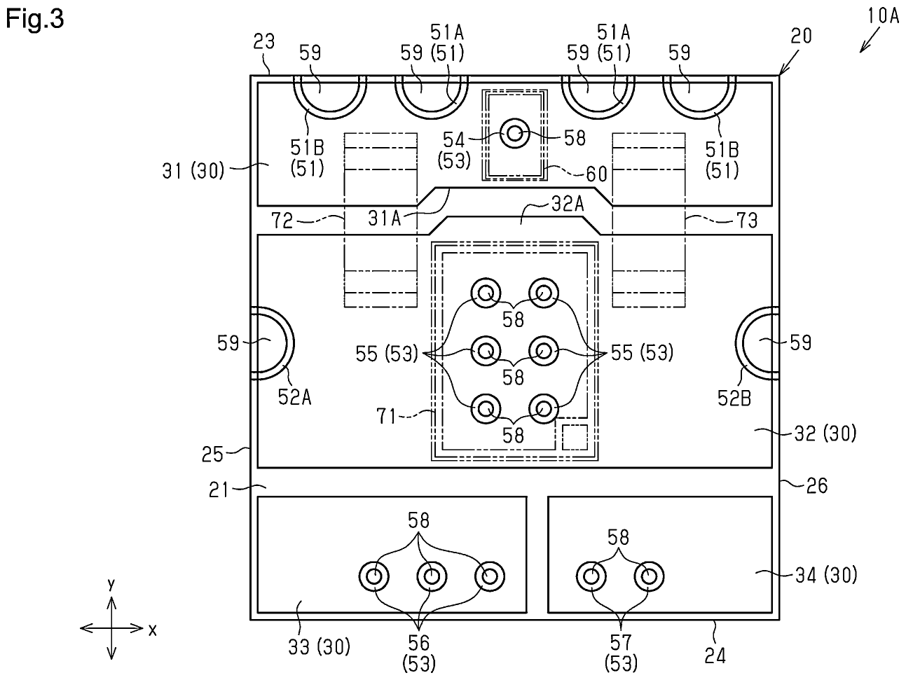

As shown in FIGS. 2 and 3, the front surface interconnect 30 includes a first front surface interconnect 31, a second front surface interconnect 32, a third front surface interconnect 33, and a fourth front surface interconnect 34. As viewed in the z-direction, the first to fourth front surface interconnects 31 to 34 are separate from each other.

The first front surface interconnect 31 is an interconnect on which the semiconductor light emitting element 60 is mounted. The first front surface interconnect 31 is located on one of two ends of the substrate front surface 21 in the y-direction located closer to the first substrate side surface 23. The first front surface interconnect 31 extends over a substantial portion of the substrate front surface 21 in the x-direction. One of two ends of the first front surface interconnect 31 in the y-direction located closer to the second substrate side surface 24 includes a recess 31A, which is recessed from the center in the x-direction toward the first substrate side surface 23 in the y-direction. In the present embodiment, the dimension of the recess 31A in the x-direction gradually decreases toward the first substrate side surface 23. The shape of the recess 31A may be changed in any manner.

The semiconductor light emitting element 60 is mounted on the center of the first front surface interconnect 31 in the x-direction. More specifically, the semiconductor light emitting element 60 is bonded to the center of the first front surface interconnect 31 in the x-direction by a conductive bonding material SD1 such as solder paste and silver (Ag) paste. Thus, the semiconductor light emitting element 60 is electrically connected to the first front surface interconnect 31.

As shown in FIG. 2, the semiconductor light emitting element 60 is located closer to the first substrate side surface 23 than to the second substrate side surface 24. In other words, the semiconductor light emitting element 60 is located on one of two ends of the substrate front surface 21 in the y-direction located closer to the first substrate side surface 23.

The second front surface interconnect 32 is an interconnect on which the switching element 71 is mounted. The second front surface interconnect 32 is located on the center of the substrate front surface 21 in the y-direction. The second front surface interconnect 32 extends over a substantial portion of the substrate front surface 21 in the x-direction. The second front surface interconnect 32 is greater than the first front surface interconnect 31, the third front surface interconnect 33, and the fourth front surface interconnect 34 in area as viewed in the z-direction. The second front surface interconnect 32 includes a projection 32A, which projects from the center in the x-direction toward the first substrate side surface 23 (the first front surface interconnect 31). As viewed in the z-direction, the projection 32A has the form of a trapezoid that tapers toward the first substrate side surface 23 (the first front surface interconnect 31). The projection 32A is formed to extend into the recess 31A of the first front surface interconnect 31. The shape of the projection 32A may be changed in any manner.

The switching element 71 is a semiconductor element that controls current supplied to the semiconductor light emitting element 60. The switching element 71 is, for example, a transistor. In the present embodiment, a metal-oxide-semiconductor field-effect transistor (MOSFET) is used as the switching element 71.

The switching element 71 is mounted on the center of the second front surface interconnect 32 in the x-direction. More specifically, the switching element 71 is bonded to the center of the second front surface interconnect 32 in the x-direction by a conductive bonding material SD2 such as solder paste or Ag paste. Thus, the switching element 71 and the second front surface interconnect 32 are electrically connected.

The third front surface interconnect 33 and the fourth front surface interconnect 34 are electrically connected to the switching element 71. The third front surface interconnect 33 and the fourth front surface interconnect 34 are located at a side of the second front surface interconnect 32 opposite from the first front surface interconnect 31 in the y-direction. In other words, the third front surface interconnect 33 and the fourth front surface interconnect 34 are located closer to the second substrate side surface 24 than the second front surface interconnect 32 is in the substrate front surface 21. In the present embodiment, the third front surface interconnect 33 and the fourth front surface interconnect 34 are located on one of two ends of the substrate front surface 21 in the y-direction located closer to the second substrate side surface 24. The third front surface interconnect 33 and the fourth front surface interconnect 34 are aligned with each other in the y-direction and separated from each other in the x-direction. The third front surface interconnect 33 is located closer to the third substrate side surface 25 than to the fourth front surface interconnect 34 is in the x-direction.

In the present embodiment, the third front surface interconnect 33 is equal to the fourth front surface interconnect 34 in dimension in the y-direction. When the difference in dimension in the y-direction between the third front surface interconnect 33 and the fourth front surface interconnect 34 is, for example, within 10% of the dimension of the third front surface interconnect 33 in the y-direction, it is considered that the third front surface interconnect 33 is equal to the fourth front surface interconnect 34 in dimension in the y-direction. Each of the third front surface interconnect 33 and the fourth front surface interconnect 34 is smaller than the second front surface interconnect 32 in dimension in the y-direction. The third front surface interconnect 33 is larger than the fourth front surface interconnect 34 in dimension in the x-direction. One of two ends of the third front surface interconnect 33 in the x-direction located closer to the fourth front surface interconnect 34 overlaps the switching element 71 as viewed in the y-direction. One of two ends of the fourth front surface interconnect 34 in the x-direction located closer to the third front surface interconnect 33 overlaps the switching element 71 as viewed in the y-direction.

The structure and the arrangement of the semiconductor light emitting element 60, the switching element 71, and the capacitors 72 and 73 will now be described.

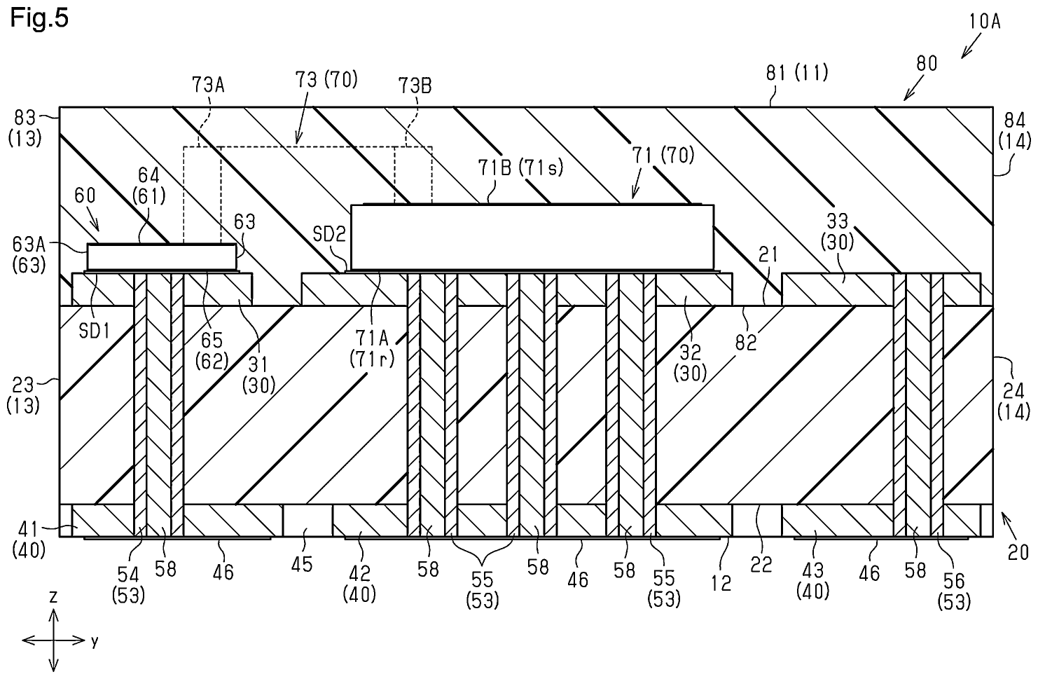

As shown in FIG. 1, the semiconductor light emitting element 60 is flat. As shown in FIG. 2, as viewed in the z-direction, the semiconductor light emitting element 60 is rectangular and includes long sides and short sides. As shown in FIG. 5, the semiconductor light emitting element 60 includes a light emitting element front surface 61 and a light emitting element back surface 62, which face opposite directions in the z-direction, and four light emitting element side surfaces 63, which join the light emitting element front surface 61 and the light emitting element back surface 62. In the present embodiment, each of the light emitting element side surfaces 63 is orthogonal to the light emitting element front surface 61 and the light emitting element back surface 62. The four light emitting element side surfaces 63 include a light emitting element side surface 63A defining a light emitting surface. More specifically, the semiconductor light emitting element 60 is configured to emit light from the light emitting element side surface 63A. In other words, the semiconductor light emitting element 60 includes a light emitting surface (light emitting element side surface 63A) that emits light in a predetermined direction. As viewed in the z-direction, the light emitting element side surface 63A and the first substrate side surface 23 of the substrate 20 face the same direction. In other words, the first substrate side surface 23 faces in a light irradiation direction of the semiconductor light emitting element 60. The first substrate side surface 23 and the light emitting surface (light emitting element side surface 63A) of the semiconductor light emitting element 60 face the same direction.

The light emitting element front surface 61 and the substrate front surface 21 face the same direction. The light emitting element front surface 61 includes a first electrode 64 used as an anode electrode. In the present embodiment, the first electrode 64 is formed on generally the entirety of the light emitting element front surface 61.

The light emitting element back surface 62 and the substrate back surface 22 face the same direction. In other words, the light emitting element back surface 62 and the first front surface interconnect 31 face each other. The light emitting element back surface 62 includes a second electrode 65 used as a cathode electrode. In the present embodiment, the second electrode 65 is formed on generally the entirety of the light emitting element back surface 62. The second electrode 65 is electrically connected to the first front surface interconnect 31 by the conductive bonding material SD1.

As shown in FIG. 2, in the present embodiment, the semiconductor light emitting element 60 is mounted on the first front surface interconnect 31 so that the long sides extend in the y-direction and the short sides extend in the x-direction. More specifically, the semiconductor light emitting element 60 is mounted on the first front surface interconnect 31 so that the light emitting element side surface 63A, which is used as the light emitting surface, faces toward the first substrate side surface 23. Therefore, the semiconductor light emitting device 10A is of a side-surface light emitting type.

As viewed in the y-direction, the semiconductor light emitting element 60 is located to overlap the recess 31A of the first front surface interconnect 31. In the present embodiment, the minimum value of the dimension of the recess 31A in the x-direction, that is, the dimension of the bottom of the recess 31A in the x-direction, is greater than the dimension (short side) of the semiconductor light emitting element 60 in the x-direction. The dimension (long side) of the semiconductor light emitting element 60 in the y-direction is slightly less than the dimension of the center, in the x-direction, of the first front surface interconnect 31 in the y-direction.

As shown in FIG. 1, the switching element 71 is flat. As shown in FIG. 5, the switching element 71 has a greater thickness than the semiconductor light emitting element 60. The switching element 71 includes a switching element front surface 71s and a switching element back surface 71r facing opposite directions in the z-direction.

The switching element front surface 71s and the substrate front surface 21 face the same direction. As shown in FIG. 2, the switching element front surface 71s includes a second electrode 71B and a control electrode 71C. In the present embodiment, the second electrode 71B is a source electrode, and the control electrode 71C is a gate electrode. The second electrode 71B extends on a substantial portion of the switching element front surface 71s. The control electrode 71C is formed on one of four corners of the switching element front surface 71s. In the present embodiment, among the four corners of the switching element front surface 71s, the control electrode 71C is formed on the corner located closest to the fourth front surface interconnect 34.

As shown in FIG. 5, the switching element back surface 71r and the substrate back surface 22 face the same direction. In other words, the switching element back surface 71r and the second front surface interconnect 32 face each other. The switching element back surface 71r includes a first electrode 71A. In the present embodiment, the first electrode 71A is a drain electrode. The first electrode 71A is electrically connected to the second front surface interconnect 32 by the conductive bonding material SD2. Thus, the switching element 71 of the present embodiment is a MOSFET having a vertical structure.

As shown in FIG. 2, as viewed in the z-direction, the switching element 71 is rectangular and includes long sides and short sides. The short side of the switching element 71 is greater than the short side of the semiconductor light emitting element 60. The long side of the switching element 71 is greater than the long side of the semiconductor light emitting element 60. In the present embodiment, the switching element 71 is mounted on the second front surface interconnect 32 so that the long sides extend in the y-direction and the short sides extend in the x-direction.

The switching element 71 and the projection 32A of the second front surface interconnect 32 are located at the same position in the x-direction. In the present embodiment, the dimension (short side) of the switching element 71 in the x-direction is slightly less than the maximum value of the dimension of the projection 32A in the x-direction. The dimension of the switching element 71 in the x-direction is greater than the minimum value of the dimension of the projection 32A in the x-direction, that is, the dimension of the distal edge of the projection 32A in the x-direction.

As viewed in the y-direction, the switching element 71 is located to overlap the semiconductor light emitting element 60. As viewed in the y-direction, the entirety of the semiconductor light emitting element 60 overlaps the switching element 71. The switching element 71 is separated from the semiconductor light emitting element 60 toward the second substrate side surface 24. Thus, the y-direction is the arrangement direction of the semiconductor light emitting element 60 and the switching element 71. In the present embodiment, the y-direction corresponds to a “first direction.” The x-direction corresponds to a “second direction.”

The first electrode 64 of the semiconductor light emitting element 60 and the second electrode 71B of the switching element 71 are electrically connected by one or more (in the present embodiment, four) first wires W1. As viewed in the z-direction, a gap between adjacent ones of the first wires W1 in the x-direction increases in a direction from the semiconductor light emitting element 60 toward the switching element 71.

The second electrode 71B of the switching element 71 and the third front surface interconnect 33 are electrically connected by one or more (in the present embodiment, two) second wires W2. The control electrode 71C of the switching element 71 and the fourth front surface interconnect 34 are electrically connected by one or more (in the present embodiment, one) third wires W3.

The first to third wires W1 to W3 are each a bonding wire formed by a wire bonder and are formed from a conductor such as gold (Au), aluminum (Al), Cu, or the like. In the present embodiment, the first to third wires W1 to W3 are formed from the same material (e.g., Cu). The material forming the first to third wires W1 to W3 may be changed in any manner. For example, each of the first to third wires W1 to W3 may be formed from a different material.

The capacitors 72 and 73 are electronic components that cooperate with the switching element 71 to supply current to the semiconductor light emitting element 60. As shown in FIG. 1, the capacitors 72 and 73 are substantially rectangular-box-shaped. As shown in FIG. 2, as viewed in the z-direction, the capacitors 72 and 73 are rectangular and include long sides and short sides.

The capacitors 72 and 73 include first electrodes 72A and 73A and second electrodes 72B and 73B, respectively. As viewed in the z-direction, the first electrode 72A and the second electrode 72B of the capacitor 72 are separately formed in two longitudinal ends of the capacitor 72. As viewed in the z-direction, the first electrode 73A and the second electrode 73B of the capacitor 73 are separately formed in two longitudinal ends of the capacitor 73. In the present embodiment, the capacitors 72 and 73 are identical to each other in shape and size. The capacitors 72 and 73 also have the same capacitance.

The capacitors 72 and 73 extend over the first front surface interconnect 31 and the second front surface interconnect 32. The capacitors 72 and 73 are bonded to the first front surface interconnect 31 and the second front surface interconnect 32 by a conductive bonding material SD3 such as solder paste or Ag paste. More specifically, the capacitors 72 and 73 are arranged so that the long sides extend in the y-direction and the short sides extend in the x-direction. As viewed in the z-direction, the first electrodes 72A and 73A of the capacitors 72 and 73 are bonded to the first front surface interconnect 31 by the conductive bonding material SD3. This electrically connects the first electrodes 72A and 73A to the first front surface interconnect 31. As viewed in the z-direction, the second electrodes 72B and 73B of the capacitors 72 and 73 are bonded to the second front surface interconnect 32 by the conductive bonding material SD3. This electrically connects the second electrodes 72B and 73B to the second front surface interconnect 32. Thus, the first electrodes 72A and 73A of the capacitors 72 and 73 are electrically connected to the second electrode 65 of the semiconductor light emitting element 60 by the first front surface interconnect 31. The second electrodes 72B and 73B of the capacitors 72 and 73 are electrically connected to the first electrode 71A of the switching element 71 by the second front surface interconnect 32.

The capacitors 72 and 73 are separately located at opposite sides of the semiconductor light emitting element 60 and the switching element 71 in the x-direction. More specifically, as viewed in the x-direction, the capacitors 72 and 73 are located to overlap with the semiconductor light emitting element 60 and the switching element 71. The capacitor 72 is located between the semiconductor light emitting element 60 and the third substrate side surface 25 and between the switching element 71 and the third substrate side surface 25 in the x-direction. The capacitor 73 is located between the semiconductor light emitting element 60 and the fourth substrate side surface 26 and between the switching element 71 and the fourth substrate side surface 26 in the x-direction.

The distance between the capacitor 72 and the capacitor 73 in the x-direction is greater than one side of the switching element 71 extending in the x-direction (short side of the switching element 71 in the present embodiment) and less than one side of the switching element 71 extending in the y-direction (long side of the switching element 71 in the present embodiment). The x-direction extends along the first substrate side surface 23. The short side of the switching element 71 corresponds to a “first side of a switching element.” The long side of the switching element 71 corresponds to a “second side of a switching element.”

As shown in FIG. 6, in the present embodiment, the capacitor 72 is located closer to the semiconductor light emitting element 60 and the switching element 71 than to the third substrate side surface 25 in the x-direction. The capacitor 73 is located closer to the semiconductor light emitting element 60 and the switching element 71 than to the fourth substrate side surface 26 in the x-direction. More specifically, a distance DPC1 between the capacitor 72 and the semiconductor light emitting element 60 in the x-direction is less than a distance DB1 between the capacitor 72 and the third substrate side surface 25 in the x-direction. A distance DSC1 between the capacitor 72 and the switching element 71 in the x-direction is less than the distance DB1 between the capacitor 72 and the third substrate side surface 25 in the x-direction. In addition, the distance DSC1 between the capacitor 72 and the switching element 71 in the x-direction is less than the distance DPC1 between the capacitor 72 and the semiconductor light emitting element 60 in the x-direction. A distance DPC2 between the capacitor 73 and the semiconductor light emitting element 60 in the x-direction is less than a distance DB2 between the capacitor 73 and the fourth substrate side surface 26 in the x-direction. A distance DSC2 between the capacitor 73 and the switching element 71 in the x-direction is less than the distance DB2 between the capacitor 73 and the fourth substrate side surface 26 in the x-direction. In addition, the distance DSC2 between the capacitor 73 and the switching element 71 in the x-direction is less than the distance DPC2 between the capacitor 73 and the semiconductor light emitting element 60 in the x-direction.

In the present embodiment, the distance DSC2 is equal to the distance DSC1. When the difference between the distance DSC2 and the distance DSC1 is, for example, within 10% of the distance DSC1, it is considered that the distance DSC2 is equal to the distance DSC1. In the present embodiment, the distance DPC1 is equal to the distance DPC2. When the difference between the distance DPC1 and the distance DPC2 is, for example, within 10% of the distance DPC2, it is considered that the distance DPC1 is equal to the distance DPC2.

The capacitors 72 and 73 are offset from the semiconductor light emitting element 60 toward the second substrate side surface 24 in the y-direction. More specifically, the first electrodes 72A and 73A of the capacitors 72 and 73 are offset from the light emitting element side surface 63A, which is used as the light emitting surface, of the semiconductor light emitting element 60 toward the second substrate side surface 24 in the y-direction. Thus, distances DA1 and DA2 between the first substrate side surface 23 and the first electrodes 72A and 73A in the y-direction are greater than a distance DP between the first substrate side surface 23 and the light emitting element side surface 63A in the y-direction. In other words, the distance DP between the first substrate side surface 23 and the light emitting element side surface 63A in the y-direction is less than the distances DA1 and DA2 between the first substrate side surface 23 and the first electrodes 72A and 73A in the y-direction. The distance DP is set so that light emitted from the semiconductor light emitting element 60 does not strike the substrate front surface 21 of the substrate 20.

As shown in FIG. 2, the capacitors 72 and 73 are offset from the switching element 71 toward the first substrate side surface 23 in the y-direction. More specifically, the distance between the second substrate side surface 24 and the second electrodes 72B and 73B of the capacitors 72 and 73 in the y-direction is greater than the distance between the second substrate side surface 24 and the switching element 71 in the y-direction.

As described above, while the capacitor 72 is located adjacent to the switching element 71 toward the third substrate side surface 25, the capacitor 73 is located adjacent to the switching element 71 toward the fourth substrate side surface 26. Thus, when a portion of the switching element 71 located toward the first substrate side surface 23 is located between the capacitors 72 and 73 in the x-direction, the switching element 71 is located close to the semiconductor light emitting element 60. This shortens the distance between the switching element 71 and the semiconductor light emitting element 60 on the substrate front surface 21 of the substrate 20. Accordingly, the wiring path (the first wire W1) connecting the semiconductor light emitting element 60 and the switching element 71 is shortened to reduce the effect of parasitic inductance of the wiring path.

The capacitor 72 and the capacitor 73 are symmetrically arranged on the substrate front surface 21 with respect to the semiconductor light emitting element 60 and the switching element 71. This forms a looped first wiring path, in which current flows from the capacitor 72 through the switching element 71 to the semiconductor light emitting element 60, and a looped second wiring path, in which current flows from the capacitor 73 through the switching element 71 to the semiconductor light emitting element 60. The first wiring path and the second wiring path are symmetrical to each other with respect to the semiconductor light emitting element 60 and the switching element 71.

As shown in FIGS. 5 and 6, the first wiring path includes a first path connecting the second electrode 72B of the capacitor 72 to the first electrode 71A (drain electrode) of the switching element 71, a first wire W1 connecting the second electrode 71B (source electrode) of the switching element 71 to the first electrode 64 (anode electrode) of the semiconductor light emitting element 60, and a second path connecting the second electrode 65 (cathode electrode) of the semiconductor light emitting element 60 to the first electrode 72A of the capacitor 72. The first path includes the second front surface interconnect 32, the conductive bonding material SD2, and the conductive bonding material SD3. The second path includes the first front surface interconnect 31, the conductive bonding material SD1, and the conductive bonding material SD3.

The second wiring path includes a third path connecting the second electrode 73B of the capacitor 73 to the first electrode 71A (drain electrode) of the switching element 71, a first wire W1 connecting the second electrode 71B (source electrode) of the switching element 71 to the first electrode 64 (anode electrode) of the semiconductor light emitting element 60, and a fourth path connecting the second electrode 65 (cathode electrode) of the semiconductor light emitting element 60 to the first electrode 73A of the capacitor 73. The third path includes the second front surface interconnect 32, the conductive bonding material SD2, and the conductive bonding material SD3. The fourth path includes the first front surface interconnect 31, the conductive bonding material SD1, and the conductive bonding material SD3.

The symmetrical arrangement of the first wiring path and the second wiring path cancels out the magnetic flux formed by a current flowing through the first wiring path and the magnetic flux formed by a current flowing through the second wiring path. This reduces parasitic inductance present in the first wiring path and parasitic inductance present in the second wiring path.

As shown in FIG. 4, the back surface interconnect 40 serves as an external terminal for electrically connecting the semiconductor light emitting device 10A to an interconnect of a circuit substrate, for example, when the semiconductor light emitting device 10A is mounted on the circuit substrate. The back surface interconnect 40 forms a portion of the device back surface 12. That is, the device back surface 12 is used as a mount surface, for example, when the semiconductor light emitting device 10A is mounted on the circuit substrate. Thus, the semiconductor light emitting device 10A of the present embodiment has a package structure of a surface mount type.

In the same manner as the front surface interconnect 30, the back surface interconnect 40 includes, for example, a metal layer and a plating layer formed on the metal layer. The back surface insulation layer 45 is arranged on the substrate back surface 22 of the substrate 20 to cover the substrate back surface 22 and expose the back surface interconnect 40. The back surface insulation layer 45 is formed of, for example, a waterproof insulation coating member. The insulation coating member is formed from, for example, an insulation material such as silicon dioxide (SiO₂). The back surface insulation layer 45 forms a portion of the device back surface 12. That is, the device back surface 12 includes the back surface interconnect 40 and the back surface insulation layer 45.

The back surface interconnect 40 includes a first back surface interconnect 41, a second back surface interconnect 42, a third back surface interconnect 43, and a fourth back surface interconnect 44.

The first back surface interconnect 41 is electrically connected to the first front surface interconnect 31 (refer to FIG. 2). More specifically, the first back surface interconnect 41 is electrically connected to the second electrode 65 (cathode electrode) of the semiconductor light emitting element 60 and the first electrodes 72A and 73A (refer to FIG. 2) of the capacitors 72 and 73.

The first back surface interconnect 41 is located on one of two ends of the substrate back surface 22 in the y-direction located closer to the first substrate side surface 23. As viewed in the z-direction, the first back surface interconnect 41 is located to overlap the first front surface interconnect 31. The first back surface interconnect 41 extends over a substantial portion of the substrate front surface 21 in the x-direction. As viewed in the z-direction, the first back surface interconnect 41 is rectangular so that the long sides extend in the x-direction and the short sides extend in the y-direction.

The second back surface interconnect 42 is electrically connected to the second front surface interconnect 32 (refer to FIG. 2). More specifically, the second back surface interconnect 42 is electrically connected to the first electrode 71A (drain electrode) of the switching element 71 and the second electrodes 72B and 73B (refer to FIG. 2) of the capacitors 72 and 73.

The second back surface interconnect 42 is located on the center of the substrate back surface 22 in the y-direction. As viewed in the z-direction, the second back surface interconnect 42 is located to overlap the second front surface interconnect 32. The second back surface interconnect 42 extends over a substantial portion of the substrate back surface 22 in the x-direction. As viewed in the z-direction, the second back surface interconnect 42 is rectangular so that the long sides extend in the x-direction and the short sides extend in the y-direction. The second back surface interconnect 42 is greater than the first front surface interconnect 31, the third front surface interconnect 33, and the fourth front surface interconnect 34 in area as viewed in the z-direction.

The third back surface interconnect 43 is electrically connected to the third front surface interconnect 33 (refer to FIG. 2). More specifically, the third back surface interconnect 43 is electrically connected to the second electrode 71B (source electrode, refer to FIG. 2) of the switching element 71.

The fourth back surface interconnect 44 is electrically connected to the fourth front surface interconnect 34 (refer to FIG. 2). More specifically, the fourth back surface interconnect 44 is electrically connected to the control electrode 71C (gate electrode, refer to FIG. 2) of the switching element 71.

The third back surface interconnect 43 and the fourth back surface interconnect 44 are located on one of two ends of the substrate back surface 22 in the y-direction located closer to the second substrate side surface 24. The third back surface interconnect 43 and the fourth back surface interconnect 44 are aligned with each other in the y-direction and separated from each other in the x-direction. The third back surface interconnect 43 is located closer to the third substrate side surface 25 than the fourth back surface interconnect 44 is in the x-direction. As viewed in the z-direction, the third back surface interconnect 43 is located to overlap the third front surface interconnect 33. As viewed in the z-direction, the fourth back surface interconnect 44 is located to overlap the fourth front surface interconnect 34.

In the present embodiment, the third back surface interconnect 43 is equal to the third front surface interconnect 33 in dimensions in the x-direction and the y-direction. The fourth back surface interconnect 44 is equal to the fourth front surface interconnect 34 in dimensions in the x-direction and the y-direction.

As shown in FIG. 5, in the present embodiment, a plating layer 46 is formed on the outer surface of each of the first to fourth back surface interconnects 41 to 44. When the semiconductor light emitting device 10A is mounted on a circuit substrate using a conductive bonding material such as solder or Ag paste, the conductive bonding material contacts the plating layer 46. The plating layer 46 includes metal layers stacked on one another. The metal layers are, for example, a Ni layer, a Pd layer, and an Au layer.

As shown in FIGS. 3 and 4, the semiconductor light emitting device 10A includes inner through holes 53 connecting the front surface interconnect 30 and the back surface interconnect 40. As viewed in the z-direction, the inner through holes 53 are arranged inward from the first to fourth substrate side surfaces 23 to 26 of the substrate 20. The inner through holes 53 include a first inner through hole 54, a second inner through holes 55, a third inner through hole 56, and a fourth inner through hole 57.

In the present embodiment, as viewed in the z-direction, the first to fourth inner through holes 54 to 57 are circular. In other words, the first to fourth inner through holes 54 to 57 are each cylindrical. In the present embodiment, the first to fourth inner through holes 54 to 57 are equal to each other in size (diameter). When the largest difference in size between the first to fourth inner through holes 54 to 57 is, for example, within 10% of the size of the first inner through hole 54, it is considered that the first to fourth inner through holes 54 to 57 are equal to each other in size.

The first to fourth inner through holes 54 to 57 are formed of a conductive material. In the present embodiment, the first to fourth inner through holes 54 to 57 are formed of Cu. Heat dissipation members 58 are arranged in the first to fourth inner through holes 54 to 57. The heat dissipation members 58 fill the inside of the first to fourth inner through holes 54 to 57. The heat dissipation members 58 are formed from, for example, a metal material. An example of the metal material is Cu. That is, the heat dissipation members 58 and the first to fourth inner through holes 54 to 57 may be formed from the same material.

The material of the heat dissipation members 58 may be changed in any manner. In an example, the heat dissipation members 58 may be formed from a metal material that differs from the metal material forming the first to fourth inner through holes 54 to 57. Alternatively, the heat dissipation members 58 may be formed from an insulation material having a good heat dissipation property such as ceramic instead of a metal material.

The first inner through hole 54 is an interconnect connecting the first front surface interconnect 31 and the first back surface interconnect 41. The first inner through hole 54 electrically connects the first front surface interconnect 31 and the first back surface interconnect 41. In the present embodiment, a single first inner through hole 54 is arranged. As viewed in the z-direction, the first inner through hole 54 is located to overlap the semiconductor light emitting element 60.

The second inner through hole 55 is an interconnect connecting the second front surface interconnect 32 and the second back surface interconnect 42. The second inner through hole 55 electrically connects the second front surface interconnect 32 and the second back surface interconnect 42. Multiple (in the present embodiment, six) second inner through holes 55 are arranged. As viewed in the z-direction, the second inner through holes 55 are located to overlap the switching element 71.

The third inner through hole 56 is an interconnect connecting the third front surface interconnect 33 and the third back surface interconnect 43. The third inner through hole 56 electrically connects the third front surface interconnect 33 and the third back surface interconnect 43. Multiple (in the present embodiment, three) third inner through holes 56 are arranged. As viewed in the z-direction, the third inner through holes 56 are aligned with each other in the y-direction and separated from each other in the x-direction. In the present embodiment, the third inner through holes 56 are located in the third back surface interconnect 43 toward the second substrate side surface 24 in the y-direction.

The fourth inner through hole 57 is an interconnect connecting the fourth front surface interconnect 34 and the fourth back surface interconnect 44. The fourth inner through hole 57 electrically connects the fourth front surface interconnect 34 and the fourth back surface interconnect 44. Multiple (in the present embodiment, two) fourth inner through holes 57 are arranged. As viewed in the z-direction, the fourth inner through holes 57 are aligned with each other in the y-direction and separated from each other in the x-direction. In the present embodiment, the fourth inner through holes 57 are located in the fourth back surface interconnect 44 toward the second substrate side surface 24 in the y-direction. In the present embodiment, as viewed in the x-direction, the fourth inner through holes 57 are located to overlap the third inner through holes 56.

The number of each of the first to fourth inner through holes 54 to 57 may be changed in any manner. The shape of the first to fourth inner through holes 54 to 57 as viewed in the z-direction may be changed in any manner. For example, each of the first to fourth inner through holes 54 to 57 may have a different shape as viewed in the z-direction. The size of each of the first to fourth inner through holes 54 to 57 may be changed in any manner. For example, each of the first to fourth inner through holes 54 to 57 may have a different size.

The structure of the semiconductor light emitting element 60 and its surroundings will now be described in detail with reference to FIGS. 6 to 8.

As shown in FIG. 6, the first substrate side surface 23 of the substrate 20 includes end surface through holes 51 extending through the substrate 20 in the z-direction, that is, the thickness-wise direction of the substrate 20. The end surface through holes 51 connect the first front surface interconnect 31 and the first back surface interconnect 41 (refer to FIG. 4).

As viewed in the z-direction, the end surface through holes 51 are recessed from the first substrate side surface 23 toward the second substrate side surface 24 in the y-direction. In an example, as viewed in the z-direction, the end surface through holes 51 have the form of a curved recess. In the present embodiment, as viewed in the z-direction, the end surface through holes 51 are semicircular. In addition to the first substrate side surface 23, the first front surface interconnect 31 and the first back surface interconnect 41 include a semicircular recess. The end surface through holes 51, which are interconnects formed from a conductive material, are arranged on the recessed semicircular side surfaces of the first substrate side surface 23, the first front surface interconnect 31, and the first back surface interconnect 41. The end surface through holes 51 extend along the recessed semicircular side surfaces. Each end surface through hole 51 includes an open end 51u. The open end 51u includes a portion corresponding to the first substrate side surface 23 that is flush with the first substrate side surface 23, a portion corresponding to the first front surface interconnect 31 that is flush with the first front surface interconnect 31, and a portion corresponding to the first back surface interconnect 41 that is flush with the first back surface interconnect 41. Thus, in the present embodiment, opposite ends of the end surface through holes 51 in the z-direction include a step. The conductive material forming the end surface through holes 51 may be, for example, Cu. That is, the material forming the end surface through holes 51 is the same as the material forming the inner through holes 53. The conductive material forming the end surface through holes 51 may be changed in any manner.

In the present embodiment, an opening width W of the end surface through hole 51 is greater than a depth-wise dimension H of the end surface through hole 51. As viewed in the z-direction, the opening width W of the end surface through hole 51 is defined by the distance in the open end 51u of the end surface through hole 51 in the x-direction. The depth-wise dimension H of the end surface through hole 51 is defined by the maximum distance between the open end 51u of the end surface through hole 51 and a side surface 51b of the end surface through hole 51 in the y-direction. As in the present embodiment, when the end surface through hole 51 is semicircular, the opening width W is approximately two times the depth-wise dimension H. The depth-wise dimension H may be defined as the radius of the semicircular end surface through hole 51.

In the present embodiment, the opening width W of the end surface through hole 51 is greater than the outer diameters of the first to fourth inner through holes 54 to 57 (refer to FIG. 3). The depth-wise dimension H of the end surface through hole 51 is greater than or equal to the outer diameters of the first to fourth inner through holes 54 to 57.

The opening width W of the end surface through hole 51 is, for example, equal to the dimension of the semiconductor light emitting element 60 in the x-direction. When the difference between the opening width W of the end surface through hole 51 and the dimension of the semiconductor light emitting element 60 in the x-direction is, for example, within 10% of the dimension of the semiconductor light emitting element 60 in the x-direction, it is considered that the opening width W of the end surface through hole 51 is equal to the dimension of the semiconductor light emitting element 60 in the x-direction.

The first substrate side surface 23 includes multiple (in the present embodiment, four) end surface through holes 51. For the sake of convenience, among the four end surface through holes 51, the two end surface through holes 51 located toward the center of the first substrate side surface 23 in the x-direction are referred to as an “end surface through holes 51A.” The two end surface through holes 51 located toward the third substrate side surface 25 and the fourth substrate side surface 26 are referred to as an “end surface through holes 51B.” Each end surface through hole 51A and each end surface through hole 51B are identical to each other in shape and size. The end surface through hole 51A corresponds to a “first end surface through hole located near a semiconductor light emitting element.” The end surface through hole 51B corresponds to a “second end surface through hole located far from the semiconductor light emitting element.”

In the present embodiment, the four end surface through holes 51 (51A, 51B) are aligned with each other in the y-direction and separated from each other in the x-direction. In the present embodiment, the four end surface through holes 51 (51A, 51B) are symmetrically arranged with respect to a centerline CL extending in the y-direction through the center of the substrate front surface 21 in the x-direction. In the present embodiment, a distance DH1 between the two end surface through holes 51A in the x-direction is greater than a distance DH2 between the end surface through hole 51A and the end surface through hole 51B that are located adjacent to each other in the x-direction.

The distance DH1 is greater than the dimension of the semiconductor light emitting element 60 in the x-direction. The distance DH1 is greater than the dimension of each of the capacitors 72 and 73 in the x-direction and less than the dimension of the switching element 71 in the x-direction.

As viewed in the y-direction, the end surface through holes 51A and 51B are separated from the semiconductor light emitting element 60. More specifically, as viewed in the z-direction, the two end surface through holes 51A are separately located at opposite sides of the semiconductor light emitting element 60 in the x-direction. As viewed in the z-direction, the end surface through holes 51A are located adjacent to the semiconductor light emitting element 60 in the x-direction. In the present embodiment, the distance DPH between the end surface through hole 51A and the semiconductor light emitting element 60 in the x-direction is less than the opening width of the end surface through holes 51A (the opening width W of the end surface through hole 51). The distance DPH is also less than the dimension of the semiconductor light emitting element 60 in the x-direction. As viewed in the z-direction, the distance DPH is defined by the distance between the side surface 51b of the end surface through hole 51A and the semiconductor light emitting element 60 in the x-direction. In other words, the distance DPH is the minimum distance between the end surface through hole 51A and the semiconductor light emitting element 60 in the x-direction.

The end surface through hole 51A partially overlaps the semiconductor light emitting element 60 as viewed in a direction extending along the first substrate side surface 23 (x-direction). More specifically, the side surface 51b of the end surface through hole 51A includes a portion located toward the second substrate side surface 24 (toward the switching element 71) from the light emitting element side surface 63A of the semiconductor light emitting element 60. In other words, the distance DP between the first substrate side surface 23 and the light emitting element side surface 63A (light emitting surface) of the semiconductor light emitting element 60 in the y-direction is less than the depth-wise dimension of the end surface through hole 51A (the depth-wise dimension H of the end surface through hole 51).

The switching element 71 and the capacitor 72 are located toward the second substrate side surface 24 (refer to FIG. 3) from one of the two end surface through holes 51A that is located closer to the third substrate side surface 25. The end surface through hole 51A located closer to the third substrate side surface 25 is separate from the first electrode 72A of the capacitor 72 and located closer to the first substrate side surface 23 than the first electrode 72A of the capacitor 72 is. Thus, the end surface through hole 51A located closer to the third substrate side surface 25 is located away from the current path between the second electrode 65 of the semiconductor light emitting element 60 and the first electrode 72A of the capacitor 72. As described above, as viewed in a direction (x-direction) extending along the first substrate side surface 23, the first electrode 72A of the capacitor 72 overlaps the semiconductor light emitting element 60 and is located toward the second substrate side surface 24 from the end surface through hole 51A located closer to the third substrate side surface 25. The current path refers to a portion of the first wiring path through which current substantially flows, that is, a portion of the first front surface interconnect 31 that electrically connects the second electrode 65 of the semiconductor light emitting element 60 and the first electrode 72A of the capacitor 72 and allows current to mainly flow. In the present embodiment, the current path is a portion of the first front surface interconnect 31 located between the second electrode 65 of the semiconductor light emitting element 60 and the first electrode 72A of the capacitor 72 in the x-direction.

The end surface through hole 51A located closer to the third substrate side surface 25 partially overlaps with the switching element 71 and the capacitor 72 as viewed in the y-direction. More specifically, the end surface through hole 51A located closer to the third substrate side surface 25 is located toward the semiconductor light emitting element 60 from the center of the capacitor 72 in the x-direction and toward the capacitor 72 from the center of the switching element 71 in the x-direction. The distance DSC1 between the switching element 71 and the capacitor 72 in the x-direction is less than the opening width of the end surface through holes 51A (the opening width W of the end surface through hole 51).

The switching element 71 and the capacitor 73 are located toward the second substrate side surface 24 (refer to FIG. 3) from one of the two end surface through holes 51A that is located closer to the fourth substrate side surface 26. The end surface through hole 51A located closer to the fourth substrate side surface 26 is separated from the first electrode 73A of the capacitor 73 and located closer to the first substrate side surface 23 than the first electrode 73A of the capacitor 73 is. Thus, the end surface through hole 51A located closer to the fourth substrate side surface 26 is located away from the current path between the second electrode 65 of the semiconductor light emitting element 60 and the first electrode 73A of the capacitor 73. As described above, as viewed in a direction (x-direction) extending along the first substrate side surface 23, the first electrode 73A of the capacitor 73 overlaps the semiconductor light emitting element 60 and is located toward the second substrate side surface 24 from the end surface through hole 51A located closer to the fourth substrate side surface 26. The current path refers to a portion of the second wiring path through which current substantially flows, that is, a portion of the first front surface interconnect 31 that electrically connects the second electrode 65 of the semiconductor light emitting element 60 and the first electrode 73A of the capacitor 73 and allows current to mainly flow. In the present embodiment, the current path is a portion of the first front surface interconnect 31 located between the second electrode 65 of the semiconductor light emitting element 60 and the first electrode 73A of the capacitor 73 in the x-direction.

The end surface through hole 51A located closer to the fourth substrate side surface 26 partially overlaps with the switching element 71 and the capacitor 73 as viewed in the y-direction. More specifically, the end surface through hole 51A located closer to the fourth substrate side surface 26 is located toward the semiconductor light emitting element 60 from the center of the capacitor 73 in the x-direction and toward the capacitor 73 from the center of the switching element 71 in the x-direction. The distance DSC2 between the switching element 71 and the capacitor 73 in the x-direction is less than the opening width of the end surface through holes 51A (the opening width W of the end surface through hole 51).

The distance DH2 between the end surface through hole 51A and the end surface through hole 51B that are located adjacent to each other in the x-direction is less than the opening width W of the end surface through hole 51. The distance DH2 is, for example, less than a distance DH3 between the third substrate side surface 25 and the open end 51u of the end surface through hole 51B located closer to the third substrate side surface 25 in the x-direction. The distance DH2 is, for example, less than a distance DH4 between the fourth substrate side surface 26 and the open end 51u of the end surface through hole 51B located closer to the fourth substrate side surface 26 in the x-direction. In the present embodiment, the distance DH4 is equal to the distance DH3. When the difference between the distance DH4 and the distance DH3 is, for example, within 10% of the distance DH3, it is considered that the distance DH4 is equal to the distance DH3. Each of the distances DH3 and DH4 is less than the opening width of the end surface through holes 51B (the opening width W of the end surface through hole 51).

The end surface through hole 51B located closer to the third substrate side surface 25 is located closer to the third substrate side surface 25 than the switching element 71 is. More specifically, the distance DH3 between the third substrate side surface 25 and the open end 51u of the end surface through hole 51B located closer to the third substrate side surface 25 in the x-direction is less than the distance DB1 between the capacitor 72 and the third substrate side surface 25 in the x-direction. As viewed in the y-direction, the end surface through hole 51B located closer to the third substrate side surface 25 includes a portion overlapping the capacitor 72 and a portion extending out from the capacitor 72 toward the third substrate side surface 25. The end surface through holes 51A and 51B located closer to the third substrate side surface 25 each include a portion overlapping the capacitor 72 as viewed in the y-direction.

The end surface through hole 51B located closer to the fourth substrate side surface 26 is located toward the fourth substrate side surface 26 from the switching element 71. More specifically, the distance DH4 between the open end 51u of the end surface through hole 51B located closer to the fourth substrate side surface 26 and the fourth substrate side surface 26 in the x-direction is less than the distance DB2 between the capacitor 73 and the fourth substrate side surface 26 in the x-direction. As viewed in the y-direction, the end surface through hole 51B located closer to the fourth substrate side surface 26 includes a portion overlapping the capacitor 73 and a portion extending out from the capacitor 73 toward the fourth substrate side surface 26. The end surface through holes 51A and 51B located closer to the fourth substrate side surface 26 each include a portion overlapping the capacitor 73 as viewed in the y-direction.

As shown in FIG. 3, the first inner through hole 54 is located closer to the second substrate side surface 24 than the end surface through holes 51A and 51B are. The first inner through hole 54 is located between the two end surface through holes 51A in the x-direction.

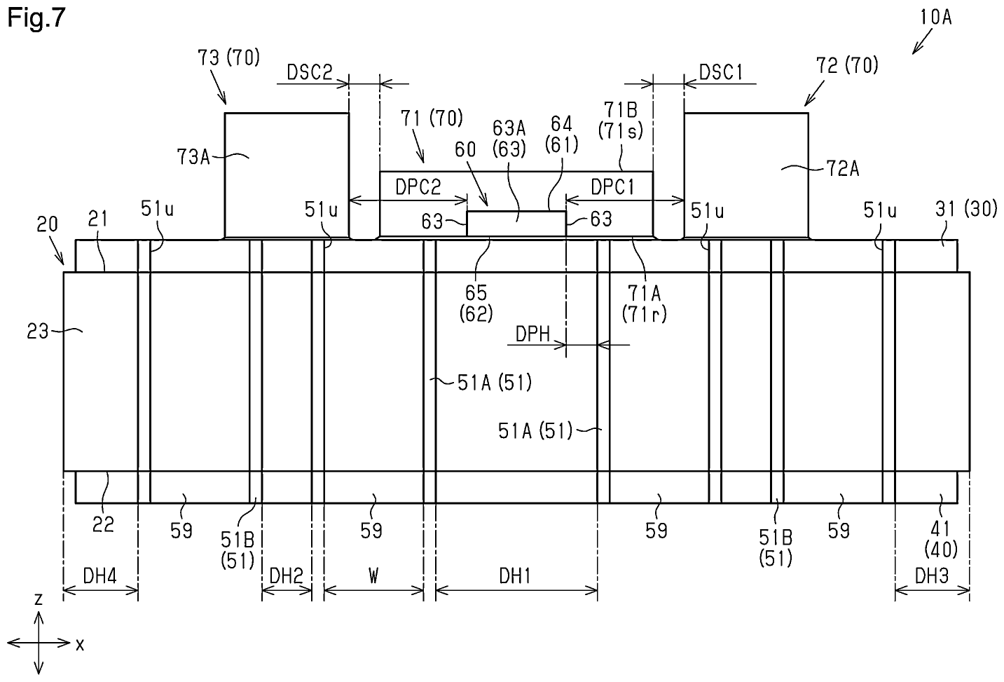

As shown in FIG. 6, the end surface through holes 51A and 51B are filled with heat dissipation members 59. The heat dissipation members 59 are flush with the end surfaces of the open ends 51u of the end surface through holes 51A and 51B. Opposite ends of each heat dissipation member 59 in the z-direction include a step in the same manner as the open end 51u of the end surface through holes 51A and 51B. As viewed in the z-direction, the heat dissipation member 59 is substantially semicircular. As shown in FIG. 7, the heat dissipation member 59 is equal to the end surface through holes 51A and 51B in the dimension in the z-direction.

The heat dissipation member 59 is formed from, for example, a metal material. An example of the metal material is Cu. That is, the heat dissipation member 59 and the end surface through holes 51A and 51B may be formed from the same material.

The material of the heat dissipation member 59 may be changed in any manner. In an example, the heat dissipation members 59 may be formed from a metal material that differs from the metal material forming the end surface through holes 51A and 51B. Alternatively, the heat dissipation member 59 may be formed from an insulation material having a good heat dissipation property such as ceramic instead of a metal material.

As shown in FIG. 6, the third substrate side surface 25 of the substrate 20 includes an end surface through hole 52A extending through the substrate 20 in the z-direction, that is, the thickness-wise direction of the substrate 20. The fourth substrate side surface 26 of the substrate 20 includes an end surface through hole 52B extending through the substrate 20 in the z-direction. The end surface through holes 52A and 52B connect the second front surface interconnect 32 and the second back surface interconnect 42 (refer to FIG. 4). Each of the end surface through holes 52A and 52B corresponds to a “control circuit end surface through hole.”

As viewed in the z-direction, the end surface through hole 52A is recessed from the third substrate side surface 25 toward the fourth substrate side surface 26 in the x-direction. As viewed in the z-direction, the end surface through hole 52B is recessed from the fourth substrate side surface 26 toward the third substrate side surface 25 in the x-direction. As viewed in the z-direction, the end surface through holes 52A and 52B have the form of a curved recess. In the present embodiment, as viewed in the z-direction, the end surface through holes 52A and 52B are semicircular.

In addition to the third substrate side surface 25 and the fourth substrate side surface 26, the second front surface interconnect 32 and the second back surface interconnect 42 include a semicircular recess. The end surface through hole 52A, which is an interconnect formed from a conductive material, is arranged on the recessed semicircular side surfaces of the third substrate side surface 25, the second front surface interconnect 32, and the second back surface interconnect 42. The end surface through hole 52A extends along the recessed semicircular side surfaces. The end surface through hole 52A includes an open end 52u that is flush with the third substrate side surface 25. The conductive material forming the end surface through hole 52A may be, for example, Cu. That is, the material forming the end surface through hole 52A is the same as the material forming the inner through holes 53 (refer to FIG. 3). In other words, the material forming the end surface through hole 52A is the same as the material forming the end surface through holes 51. The conductive material forming the end surface through hole 52A may be changed in any manner. The end surface through hole 52B is arranged in the same manner as the end surface through hole 52A and thus will not be described in detail.

In the present embodiment, the end surface through hole 52A and the end surface through hole 52B are identical to each other in shape and size. In the present embodiment, the end surface through holes 52A and 52B and the end surface through holes 51A and 51B are identical to each other in shape and size.

As viewed in the x-direction, the end surface through holes 52A and 52B are located to overlap the switching element 71. The end surface through holes 52A and 52B are offset from the capacitors 72 and 73 toward the second substrate side surface 24. The end surface through hole 52A is offset from the capacitor 72 toward the third substrate side surface 25. The end surface through hole 52B is offset from the capacitor 73 toward the fourth substrate side surface 26. Thus, the end surface through hole 52A is located away from the current path between the second electrode 72B of the capacitor 72 and the first electrode 71A of the switching element 71. The end surface through hole 52B is located away from the current path between the second electrode 73B of the capacitor 73 and the first electrode 71A of the switching element 71.

The capacitor 72 is located closer to the switching element 71 than to the end surface through hole 52A in the x-direction. A distance DHC1 between a side surface 52b of the end surface through hole 52A and the capacitor 72 in the x-direction is greater than the distance DSC1 between the capacitor 72 and the switching element 71 in the x-direction.

The capacitor 73 is located closer to the switching element 71 than to the end surface through hole 52B in the x-direction. A distance DHC2 between the side surface 52b of the end surface through hole 52B and the capacitor 73 in the x-direction is greater than the distance DSC2 between the capacitor 73 and the switching element 71 in the x-direction. The distance DHC2 is equal to the distance DHC1. When the difference between the distance DHC2 and the distance DHC1 is, for example, within 10% of the distance DHC1, it is considered that the distance DHC2 is equal to the distance DH1.

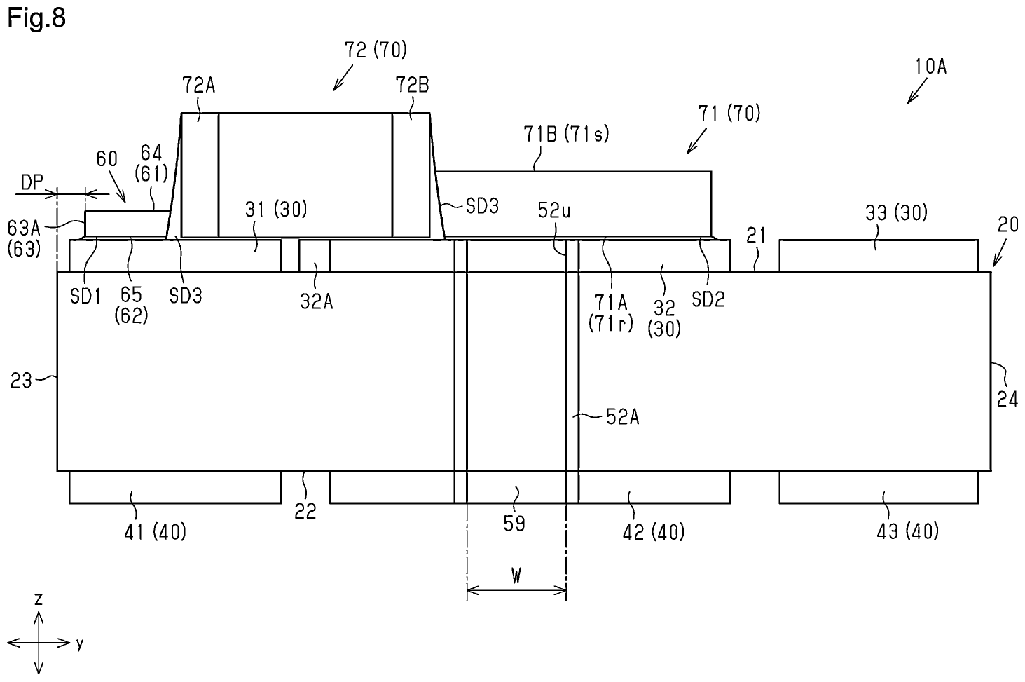

The end surface through holes 52A and 52B are filled with the heat dissipation members 59. The heat dissipation members 59 are flush with the end surfaces of the open ends 52u of the end surface through holes 52A and 52B. As viewed in the z-direction, the heat dissipation member 59 is substantially semicircular. As shown in FIG. 8, the heat dissipation member 59 is equal to the end surface through holes 52A in the dimension in the z-direction. Although not shown, the heat dissipation member 59 is equal to the end surface through hole 52B in the dimension in the z-direction. The heat dissipation members 59 filling the end surface through holes 52A and 52B correspond to a “control circuit heat dissipation member.”

The material filling the end surface through holes 52A and 52B to form the heat dissipation members 59 is the same as the material filling the end surface through holes 51A and 51B to form the heat dissipation members 59.

The material filling the end surface through holes 52A and 52B to form the heat dissipation members 59 may be changed in any manner. In an example, the material filling the end surface through holes 52A and 52B to form the heat dissipation members 59 may differ from the material filling the end surface through holes 51A and 51B to form the heat dissipation members 59.

As shown in FIG. 1, the encapsulation resin 80 covers the substrate front surface 21 of the substrate 20 and the semiconductor light emitting element 60. More specifically, as viewed in the z-direction, that is, the thickness-wise direction of the substrate 20, the encapsulation resin 80 covers the end surface through holes 51A, 51B, 52A, and 52B. As viewed in the z-direction, the encapsulation resin 80 covers the heat dissipation members 59. The encapsulation resin 80 is in contact with the end surface through holes 51A, 51B, 52A, and 52B and the heat dissipation members 59.

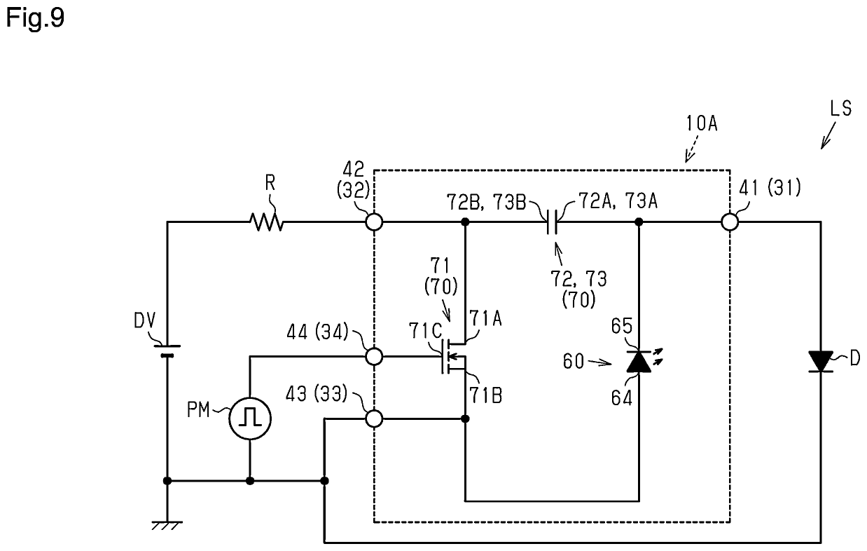

The circuit configuration of the semiconductor light emitting device 10A, the structure of which has been described above, will now be described with reference to FIG. 9. FIG. 9 is a circuit configuration of a laser system LS in which the semiconductor light emitting device 10A is used. As shown in FIG. 9, the laser system LS includes the semiconductor light emitting device 10A, a drive power supply DV, a current limiting resistor R, a diode D, and a driver circuit PM.

The drive power supply DV is a direct current power supply having a positive electrode and a negative electrode and supplies electric power to the semiconductor light emitting device 10A. The current limiting resistor R is arranged between the positive electrode of the drive power supply DV and the semiconductor light emitting device 10A to limit current flowing from the drive power supply DV to the semiconductor light emitting device 10A. The diode D is connected in antiparallel to the semiconductor light emitting element 60 to prevent a reverse flow of current to the semiconductor light emitting element 60. An example of the diode D is a Schottky barrier diode. The driver circuit PM transmits a control signal for controlling activation and deactivation of the switching element 71 to the control electrode 71C of the switching element 71. The driver circuit PM includes, for example, a square wave oscillation circuit that generates a pulse signal and a gate driver IC arranged between the square wave oscillation circuit and the semiconductor light emitting device 10A. The gate driver IC generates a control signal for the switching element 71 based on a signal from the square wave oscillation circuit.

The semiconductor light emitting element 60 is connected in series to the switching element 71. More specifically, the first electrode 64 (anode electrode) of the semiconductor light emitting element 60 is electrically connected to the second electrode 71B (source electrode) of the switching element 71. The first electrode 71A (drain electrode) of the switching element 71 is electrically connected to the second front surface interconnect 32 (second back surface interconnect 42). The second electrode 65 (cathode electrode) of the semiconductor light emitting element 60 is electrically connected to the first front surface interconnect 31 (first back surface interconnect 41).

The capacitors 72 and 73 are connected in parallel to the semiconductor light emitting element 60 and the switching element 71 that are connected in series. More specifically, the first electrodes 72A and 73A of the capacitors 72 and 73 are electrically connected to the second electrode 65 of the semiconductor light emitting element 60, and the second electrodes 72B and 73B of the capacitors 72 and 73 are electrically connected to the first electrode 71A of the switching element 71.

The second electrode 71B of the switching element 71 is electrically connected to the third front surface interconnect 33 (third back surface interconnect 43). The diode D includes an anode electrode electrically connected to the first back surface interconnect 41 (first front surface interconnect 31) and a cathode electrode electrically connected to the third back surface interconnect 43 (third front surface interconnect 33). Thus, the diode D is connected in antiparallel to the semiconductor light emitting element 60.

The control electrode 71C of the switching element 71 is electrically connected to the fourth front surface interconnect 34 (fourth back surface interconnect 44). The driver circuit PM is electrically connected to the fourth back surface interconnect 44 (fourth front surface interconnect 34). Thus, the driver circuit PM is electrically connected to the control electrode 71C of the switching element 71. The driver circuit PM and the drive power supply DV each have a negative electrode connected to ground.

The laser system LS having the configuration described above operates as follows. When the switching element 71 is switched off by a control signal of the driver circuit PM, power is stored in the capacitors 72 and 73 by the drive power supply DV. When the switching element 71 is switched on by a control signal of the driver circuit PM, the capacitors 72 and 73 are discharged so that a current flows to the semiconductor light emitting element 60. As a result, the semiconductor light emitting element 60 outputs a pulse laser beam.

### Operation

The operation of the semiconductor light emitting device 10A of the present embodiment will now be described. In the following description, a comparative example of a semiconductor light emitting device has a structure such that the end surface through holes 51 (51A, 51B), 52A, and 52B are omitted from the semiconductor light emitting device 10A.

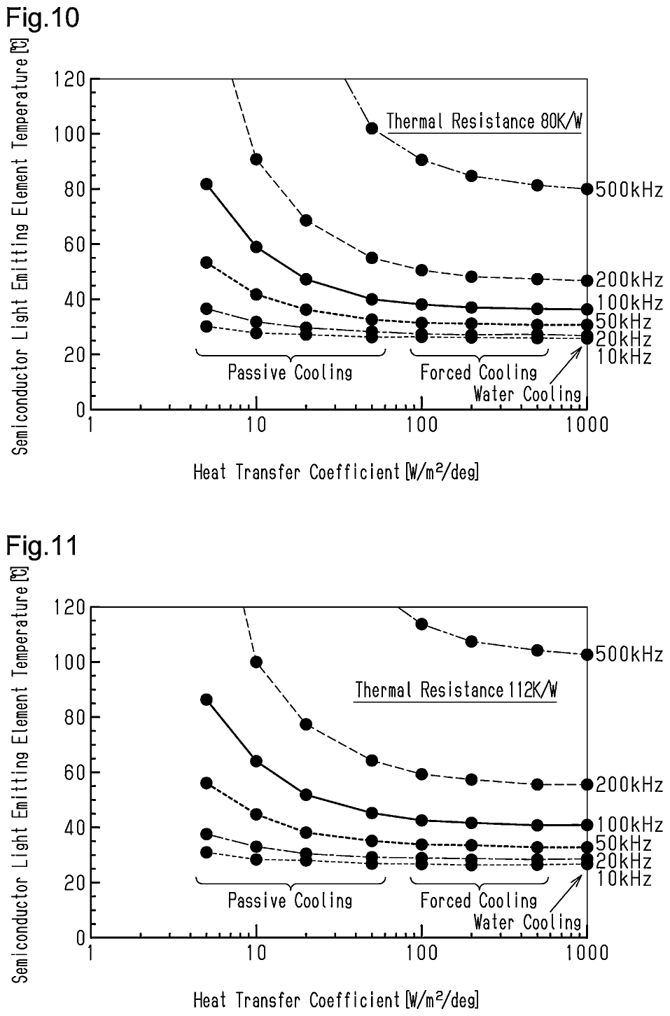

FIGS. 10 to 12 are graphs showing relationships between the heat transfer coefficient of the semiconductor light emitting device of the comparative example and the temperature of the semiconductor light emitting element 60. FIGS. 13 to 15 are graphs showing relationships between the heat transfer coefficient of the semiconductor light emitting device 10A of the present embodiment and the temperature of the semiconductor light emitting element 60. The graphs in FIGS. 10 to 15 show thermal conduction analysis results when passive cooling is performed, forced cooling is performed, and water cooling is performed. The graphs in FIGS. 10 to 15 also show thermal conduction analysis results when the frequency of a control signal for driving the switching element 71 is changed to 10 kHz, 20 kHz, 50 kHz, 100 kHz, 200 kHz, and 500 kHz. In the thermal conduction analyses, the control signal for activating the switching element 71 has a pulse width of 2 nS, and the semiconductor light emitting element 60 has a peak optical output of 150 W.

In FIGS. 10 to 12, the thickness of the substrate 20 in the semiconductor light emitting device of the comparative example is changed between the graphs.

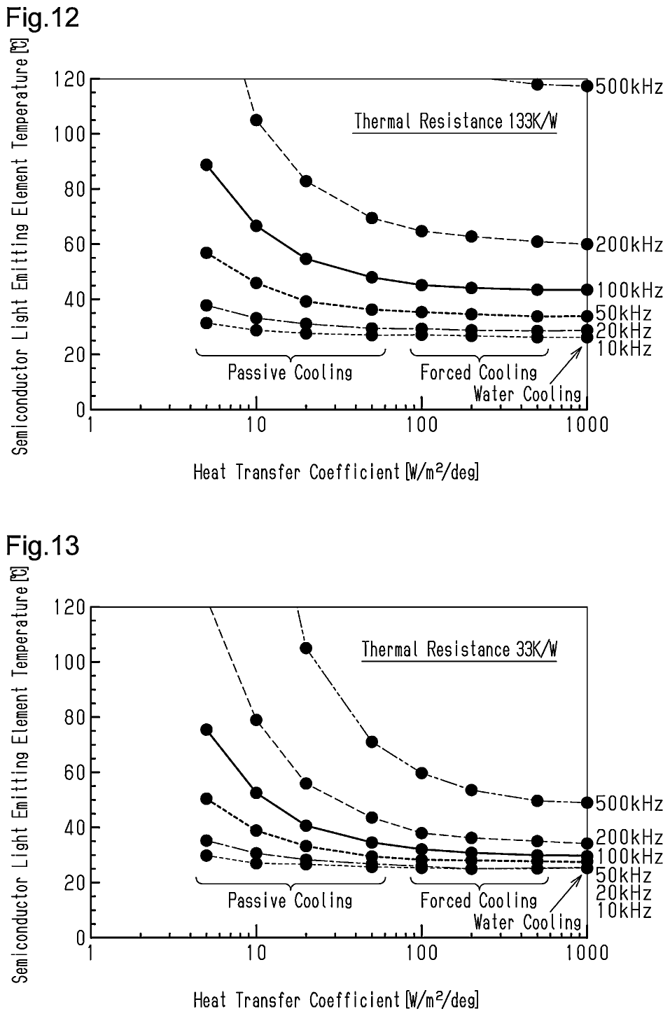

In the graph shown in FIG. 10, the substrate 20 in the semiconductor light emitting device of the comparative example has a thickness of 0.3 mm. In this case of the semiconductor light emitting device of the comparative example, the path (hereafter, “heat conduction path”) from the semiconductor light emitting element 60 to the first back surface interconnect 41 has a thermal resistance of 80 K/W. In the graph shown in FIG. 11, the substrate 20 in the semiconductor light emitting device of the comparative example has a thickness of 0.6 mm. In this case, the heat conductive path of the semiconductor light emitting device of the comparative example has a thermal resistance of 112 K/W. In the graph shown in FIG. 12, the substrate 20 in the semiconductor light emitting device of the comparative example has a thickness of 0.8 mm. In this case, the heat conductive path of the semiconductor light emitting device of the comparative example has a thermal resistance of 133 K/W. As shown in FIGS. 10 to 12, as the thickness of the substrate 20 is increased, the heat conduction path becomes longer. Accordingly, the thermal resistance of the heat conduction path becomes higher.

As described above, in the semiconductor light emitting device of the comparative example, heat transfers from the semiconductor light emitting element 60 to the first back surface interconnect 41 through the first inner through hole 54 in addition to the first front surface interconnect 31. Since the first inner through hole 54 is a single hole, the heat conduction path has a low heat transfer efficiency. As shown in FIGS. 10 to 12, taking into consideration the temperature of the semiconductor light emitting element 60 in the semiconductor light emitting device of the comparative example, the tolerance value of the frequency of the control signal is 100 kHz when a passive cooling is performed, 200 kHz when forced cooling is performed, and 500 kHz when water cooling is performed.

In the graph shown in FIG. 13, the substrate 20 in the semiconductor light emitting device 10A has a thickness of 0.3 mm. In this case, the heat conductive path of the semiconductor light emitting device 10A has a thermal resistance of 33 K/W. In the graph shown in FIG. 14, the substrate 20 in the semiconductor light emitting device 10A has a thickness of 0.6 mm. In this case, the heat conductive path of the semiconductor light emitting device 10A has a thermal resistance of 40 K/W. In the graph shown in FIG. 15, the substrate 20 in the semiconductor light emitting device 10A has a thickness of 0.8 mm. In this case, the heat conductive path of the semiconductor light emitting device 10A has a thermal resistance of 46 K/W.

As described above, in the semiconductor light emitting device 10A of the present embodiment, heat transfers from the semiconductor light emitting element 60 to the end surface through holes 51A and 51B. Thus, the thermal resistance is smaller than the semiconductor light emitting device of the comparative example. Specifically, the thermal resistance of the semiconductor light emitting device 10A is decreased to ½ to ⅓ of that of the semiconductor light emitting device of the comparative example. As a result, as shown in FIGS. 13 to 15, at each frequency of a control signal, the temperature of the semiconductor light emitting element 60 is decreased as compared to the semiconductor light emitting element 60 of the semiconductor light emitting device in the comparative example. In particular, when the frequency of the control signal is 200 kHz and 500 kHz, the temperature of the semiconductor light emitting element 60 is greatly decreased. Thus, as shown in FIGS. 13 to 15, taking into consideration the temperature of the semiconductor light emitting element 60 in the semiconductor light emitting device 10A, the tolerance value of the frequency of the control signal is 100 kHz when a passive cooling is performed, 500 kHz when forced cooling is performed, and 500 kHz when water cooling is performed. In other words, in the semiconductor light emitting device 10A, even when the frequency of the control signal is 500 kHz, the forced cooling inhibits an excessive increase in the temperature of the semiconductor light emitting element 60.

### Advantages

The semiconductor light emitting device 10A of the present embodiment has the following advantages.
(1-1) The semiconductor light emitting device 10A includes the substrate 20 including the substrate front surface 21, the substrate back surface 22 opposite to the substrate front surface 21, and the substrate side surfaces, the front surface interconnect 30 formed on the substrate front surface 21, the back surface interconnect 40 formed on the substrate back surface 22, the light emitting element side surface 63A, which is used as a light emitting surface that emits light in a predetermined direction, and the semiconductor light emitting element 60 mounted on the front surface interconnect 30. The substrate side surfaces include the first substrate side surface 23 facing the same direction as the light emitting element side surface 63A, which is used as the light emitting surface, and the second substrate side surface 24 opposite to the first substrate side surface 23. The semiconductor light emitting element 60 is located closer to the first substrate side surface 23 than to the second substrate side surface 24. The first substrate side surface 23 includes the end surface through holes 51 (51A, 51B) extending through the substrate 20 in the z-direction, which is the thickness-wise direction of the substrate 20, and connecting the front surface interconnect 30 and the back surface interconnect 40.

In this structure, when heat is generated in the semiconductor light emitting element 60, which is mounted on the front surface interconnect 30, the heat transfers from the front surface interconnect 30 to the back surface interconnect 40 through the end surface through holes 51 (51A, 51B). Thus, the heat transfer path for transferring heat from the semiconductor light emitting element 60 to the outside of the semiconductor light emitting device 10A has a volume that is increased as compared to a structure that does not include the end surface through holes 51 (51A, 51B). This facilitates dissipation of heat from the semiconductor light emitting element 60 to the outside of the semiconductor light emitting device 10A. Thus, the heat dissipation property of the semiconductor light emitting device 10A is improved.

The end surface through holes 51 (51A, 51B) are arranged in the first substrate side surface 23 and thus are exposed to the outside of the semiconductor light emitting device 10A. Thus, heat is readily dissipated from the semiconductor light emitting element 60 to the outside of the semiconductor light emitting device 10A as compared to a through hole that is not exposed to the outside of the semiconductor light emitting device 10A and connects the front surface interconnect 30 and the back surface interconnect 40. This further improves the heat dissipation property of the semiconductor light emitting device 10A.
(1-2) As viewed in the z-direction, which is the thickness-wise direction of the substrate 20, the end surface through holes 51 (51A, 51B) are arranged in the first substrate side surface 23 and separated from the semiconductor light emitting element 60.

With this structure, when light is emitted from the light emitting element side surface 63A of the semiconductor light emitting element 60, the light does not strike the end surface through holes 51 (51A, 51B) and thus does not scatter. This limits a decrease in the efficiency of laser light emitted to the outside from the semiconductor light emitting device 10A. When the semiconductor light emitting device 10A is used in the laser system LS of three-dimensional distance measurement, the ranging detection performance is less likely to be lowered.
(1-3) As viewed in the z-direction, which is the thickness-wise direction of the substrate 20, the end surface through holes 51 (51A, 51B) are located adjacent to the semiconductor light emitting element 60 in the x-direction, which is a direction extending along the first substrate side surface 23.

In this structure, the end surface through holes 51 (51A) are arranged near the semiconductor light emitting element 60. Thus, heat efficiently transfers from the semiconductor light emitting element 60 to the end surface through holes 51(51A). Thus, the heat dissipation property of the semiconductor light emitting device 10A is improved.
(1-4) The distance DPH between the end surface through holes 51(51A) and the semiconductor light emitting element 60 is less than the opening width W of the end surface through holes 51(51A).

In this structure, the end surface through holes 51(51A) are arranged near the semiconductor light emitting element 60. Thus, heat efficiently transfers from the semiconductor light emitting element 60 to the end surface through holes 51 (51A). This improves the heat dissipation property of the semiconductor light emitting device 10A.
(1-5) The first substrate side surface 23 includes multiple end surface through holes 51 (51A, 51B).

This structure increases the volume of the heat transfer path that transfers heat from the semiconductor light emitting element 60 to the outside of the semiconductor light emitting device 10A. Thus, the heat dissipation property of the semiconductor light emitting device 10A is further improved.
(1-6) As viewed in the x-direction, which is the direction extending along the first substrate side surface 23, the end surface through holes 51 (51A, 51B) overlap the semiconductor light emitting element 60.

In this structure, the semiconductor light emitting element 60 is arranged close to the first substrate side surface 23. Thus, light of the semiconductor light emitting element 60 is less likely to strike the substrate front surface 21 of the substrate 20.

In addition, as viewed in the z-direction, when the end surface through holes 51 (51A, 51B) are arranged in the first substrate side surface 23 and separated from the semiconductor light emitting element 60, the end surface through holes 51 (51A, 51B) may be enlarged without enlarging the semiconductor light emitting device 10A in the y-direction (longitudinal direction of the semiconductor light emitting device 10A). When the volume of the heat transfer path that transfers heat from the semiconductor light emitting element 60 to the outside of the semiconductor light emitting device 10A is increased, the heat dissipation property of the semiconductor light emitting device 10A is improved.
(1-7) The distance DP between the first substrate side surface 23 and the light emitting element side surface 63A, which is used as the light emitting surface, of the semiconductor light emitting element 60 is less than the depth-wise dimension H of the end surface through holes 51 (51A, 51B). This structure obtains the same advantage as the advantage (1-6) described above.
(1-8) The end surface through holes 51 (51A, 51B) are filled with the heat dissipation members 59.

In this structure, the heat dissipation members 59 further increase the volume of the heat transfer path that transfers heat from the semiconductor light emitting element 60 to the outside of the semiconductor light emitting device 10A through the end surface through holes 51 (51A, 51B). Thus, the heat dissipation property of the semiconductor light emitting device 10A is further improved.
(1-9) As viewed in the z-direction, which is the thickness-wise direction of the substrate 20, the substrate 20 includes the inner through hole 53 (the first inner through hole 54) overlapping the semiconductor light emitting element 60 and connecting the front surface interconnect 30 to the back surface interconnect 40.

This structure increases the number of paths for dissipating heat from the semiconductor light emitting element 60, thereby more efficiently transferring heat from the semiconductor light emitting element 60 to the back surface interconnect 40. Thus, the heat dissipation property of the semiconductor light emitting device 10A is further improved.

If a first inner through hole 54 is arranged between the semiconductor light emitting element 60 and each of the capacitors 72 and 73 in the x-direction, the first inner through hole 54 may hinder flow of current from the second electrode 65 of the semiconductor light emitting element 60 to the capacitors 72 and 73 through the first front surface interconnect 31. This may result in an increase in parasitic inductance of the conductive path between the second electrode 65 and each of the capacitors 72 and 73. In this regard, in the present embodiment, as viewed in the z-direction, the single first inner through hole 54 is located to overlap the semiconductor light emitting element 60. This limits hinderance of flow of current to the semiconductor light emitting element 60 by the first inner through hole 54.
(1-10) The inner through holes 53 are filled with the heat dissipation members 58.

In this structure, the heat dissipation members 58 further increase the volume of the heat transfer path that transfers heat from the semiconductor light emitting element 60 to the outside of the semiconductor light emitting device 10A through the inner through holes 53. Thus, the heat dissipation property of the semiconductor light emitting device 10A is further improved.
(1-11) The semiconductor light emitting device 10A includes the light emitting element control circuit 70 configured to have the semiconductor light emitting element 60 to emit light. The light emitting element control circuit 70 is mounted on the front surface interconnect 30.

This structure shortens the wiring path between the semiconductor light emitting element 60 and the light emitting element control circuit 70 as compared to a structure in which the light emitting element control circuit 70 is arranged outside the semiconductor light emitting device 10A. This decreases parasitic inductance in the wiring path.
(1-12) The light emitting element control circuit 70 includes the capacitors 72 and 73 mounted on the front surface interconnect 30. As viewed in the x-direction, which extends along the first substrate side surface 23, the capacitors 72 and 73 overlap the semiconductor light emitting element 60 and are located toward the second substrate side surface 24 from the end surface through holes 51 (51A, 51B).

In this structure, the capacitors 72 and 73 are located close to the semiconductor light emitting element 60. This shortens the wiring path between the semiconductor light emitting element 60 and the capacitors 72 and 73, thereby decreasing parasitic inductance in the wiring path.
(1-13) The light emitting element control circuit 70 includes the switching element 71 configured to control current supplied to the semiconductor light emitting element 60. As viewed in the z-direction, the semiconductor light emitting element 60 is rectangular and includes long sides and short sides. The switching element 71 is arranged so that the long sides of the switching element 71 extend along the long sides of the substrate 20 (in the y-direction). The switching element 71 is located to overlap the semiconductor light emitting element 60 as viewed in the y-direction. The switching element 71 is separated from the semiconductor light emitting element 60 and is located closer to the second substrate side surface 24 than the semiconductor light emitting element 60 is. The capacitors 72 and 73 are separately located at opposite sides of the switching element 71 in the x-direction (direction extending along the short sides of the switching element 71). As viewed in the z-direction, the capacitors 72 and 73 are rectangular and includes long sides and short sides. The capacitors 72 and 73 are arranged so that the long sides of the capacitors 72 and 73 extend along the long sides of the substrate 20 (in the y-direction). As viewed in the x-direction, the capacitors 72 and 73 are located to overlap with the semiconductor light emitting element 60 and the switching element 71.

In this structure, the switching element 71 and the capacitors 72 and 73 are arranged in the x-direction, which extends along the short sides of the substrate 20, so that the short sides of the switching element 71 and the short sides of the capacitors 72 and 73 extend in the x-direction. Thus, the semiconductor light emitting device 10A is reduced in size in the x-direction. As viewed in the x-direction, the capacitors 72 and 73 are located to overlap with the semiconductor light emitting element 60 and the switching element 71. Thus, the semiconductor light emitting device 10A is reduced in size in the y-direction as compared to, for example, a structure in which the capacitors 72 and 73 are entirely located closer to the first substrate side surface 23 than the switching element 71 is.

In addition, the semiconductor light emitting element 60, the switching element 71, and the capacitors 72 and 73 are arranged close to each other. This shortens a looped wiring path in which current flows through the semiconductor light emitting element 60, the switching element 71, and the capacitor 72 and a looped wiring path in which current flows through the semiconductor light emitting element 60, the switching element 71, and the capacitor 73. Thus, parasitic inductance in the wiring paths is decreased.
(1-14) The capacitor 72 is located closer to the switching element 71 than to the third substrate side surface 25 in the x-direction. The capacitor 73 is located closer to the switching element 71 than to the fourth substrate side surface 26 in the x-direction.

This structure shortens the wiring path between the switching element 71 and each of the capacitors 72 and 73. Thus, parasitic inductance in the wiring path is decreased.
(1-15) The switching element 71 is a vertical MOSFET.

In this structure, the wiring path in which current flows from the capacitors 72 and 73 through the switching element 71 to the semiconductor light emitting element 60 is shortened as compared to a lateral MOSFET in which the first electrode 71A, the second electrode 71B, and the control electrode 71C are formed on the switching element front surface 71s of the switching element 71. Thus, parasitic inductance in the wiring path is decreased.
(1-16) The capacitors 72 and 73 are symmetrically arranged with respect to the semiconductor light emitting element 60 and the switching element 71.

In this structure, the first wiring path, in which current flows from the capacitor 72 to the semiconductor light emitting element 60 through the switching element 71 and the first wire W1, and the second wiring path, in which current flows from the capacitor 73 to the semiconductor light emitting element 60 through the switching element 71 and the first wire W1, are symmetrically formed with respect to the semiconductor light emitting element 60 and the switching element 71. This arrangement cancels out the magnetic flux formed by current flowing through the first wiring path and the magnetic flux formed by current flowing through the second wiring path. Thus, parasitic inductance present in the first wiring path and parasitic inductance present in the second wiring path are decreased.
(1-17) The front surface interconnect 30 includes the second front surface interconnect 32 on which the switching element 71 is mounted. The back surface interconnect 40 includes the second back surface interconnect 42 overlapping the second front surface interconnect 32 as viewed in the z-direction, which is the thickness-wise direction of the substrate 20. Among the substrate side surfaces of the substrate 20, the third substrate side surface 25 joining the first substrate side surface 23 and the second substrate side surface 24 includes the end surface through hole 52A connecting the second front surface interconnect 32 and the second back surface interconnect 42.

In this structure, heat generated in the switching element 71 transfers from the second front surface interconnect 32 to the second back surface interconnect 42 through the end surface through hole 52A. This increases the volume of the heat transfer path that transfers heat from the switching element 71 to the outside of the semiconductor light emitting device 10A. Thus, the heat dissipation property of the semiconductor light emitting device 10A is improved.

The end surface through hole 52A is arranged in the third substrate side surface 25 and thus is exposed to the outside of the semiconductor light emitting device 10A. Thus, heat is readily transferred from the switching element 71 to the outside of the semiconductor light emitting device 10A as compared to a through hole that is not exposed to the outside of the semiconductor light emitting device 10A and connects the second front surface interconnect 32 and the second back surface interconnect 42. This further improves the heat dissipation property of the semiconductor light emitting device 10A.

Among the substrate side surfaces of the substrate 20, the fourth substrate side surface 26 joining the first substrate side surface 23 and the second substrate side surface 24 includes the end surface through hole 52B connecting the second front surface interconnect 32 and the second back surface interconnect 42. This structure obtains the same advantage as described above. In addition, the end surface through holes 52A and 52B increase the volume of the heat transfer path that transfers heat from the switching element 71 to the outside of the semiconductor light emitting device 10A. Thus, the heat dissipation property of the semiconductor light emitting device 10A is further improved.
(1-18) The first electrodes 72A and 73A of the capacitors 72 and 73 are located toward the second substrate side surface 24 from the end surface through holes 51 (51A, 51B). As viewed in the z-direction, which is the thickness-wise direction of the substrate 20, the opening width W of the end surface through hole 51 (51A, 51B) is greater than the diameter of the inner through hole 53 (54 to 57).

If the diameter of the inner through hole 53 (54) overlapping the semiconductor light emitting element 60 as viewed in the z-direction is increased, the effect on current supplied to the semiconductor light emitting element 60 will be increased. In comparison, the end surface through hole 51 (51A, 51B) is located away from the current paths between the semiconductor light emitting element 60 and the first electrodes 72A and 73A of the capacitors 72 and 73. Thus, even when the opening width W of the end surface through hole 51 (51A, 51B) is increased, the effect on the current supplied to the semiconductor light emitting element 60 is avoided. This improves the heat dissipation property of the semiconductor light emitting device 10A while avoiding the effect on the current supplied to the semiconductor light emitting element 60.
(1-19) As viewed in the y-direction, the capacitors 72 and 73 are located to overlap the end surface through holes 51A. The opening width W of the end surface through holes 51 (51A, 51B) is greater than the depth-wise dimension H of the end surface through holes 51 (51A, 51B).

In this structure, the end surface through holes 51 (51A, 51B) having the small depth-wise dimension H allow the first electrodes 72A and 73A of the capacitors 72 and 73 to be located to overlap the semiconductor light emitting element 60 as viewed in the x-direction. Meanwhile, the opening width W of the end surface through holes 51 (51A, 51B) may be enlarged to increase the surface area of the end surface through holes 51 (51A, 51B). Thus, while parasitic inductance is decreased in the wiring paths between the semiconductor light emitting element 60 and the capacitors 72 and 73, the heat dissipation property of the semiconductor light emitting device 10A is improved.

### Second Embodiment

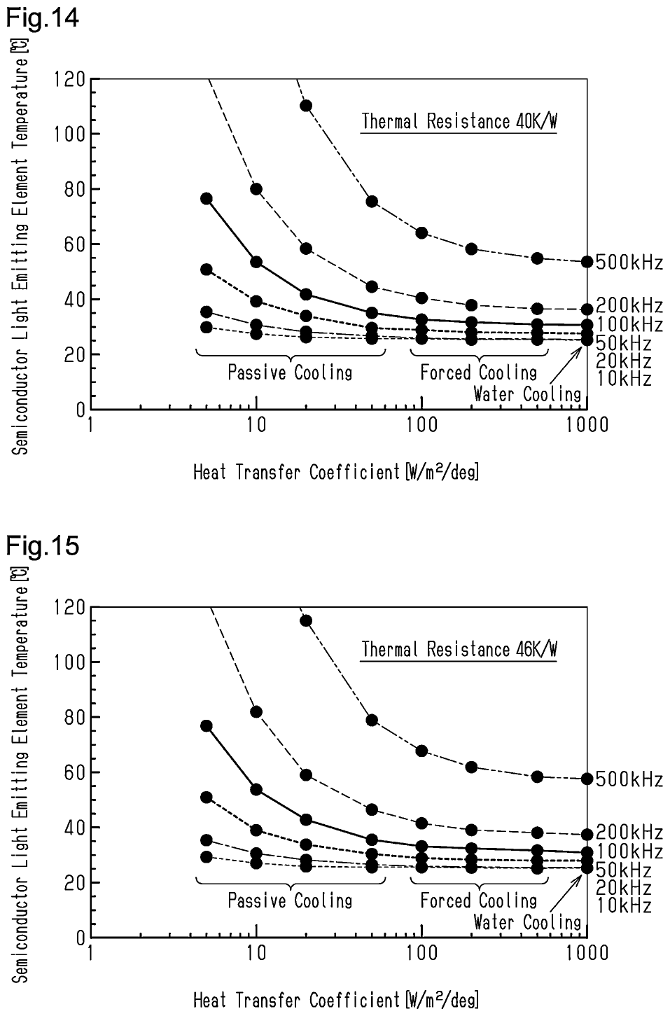

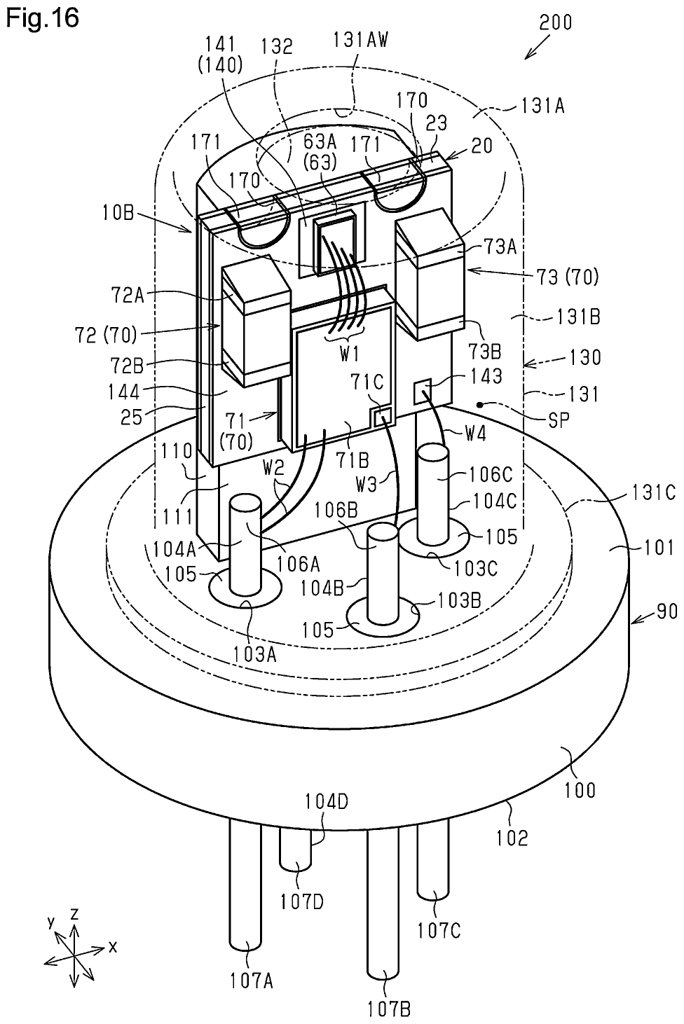

A second embodiment of a semiconductor light emitting device 10B and a semiconductor light emitting unit 200 will now be described with reference to FIGS. 16 to 25. The semiconductor light emitting device 10B of the present embodiment differs from the semiconductor light emitting device 10A of the first embodiment in the encapsulation resin 80 being omitted, structures of a front surface interconnect 140 and a back surface interconnect 150, and electrical connection of the switching element 71. In the following description of the semiconductor light emitting device 10B, same reference numerals are given to those components that are the same as the corresponding components of the semiconductor light emitting device 10A of the first embodiment. Such components will not be described in detail.

As shown in FIG. 16, the semiconductor light emitting unit 200 includes a stem 90, the semiconductor light emitting device 10B mounted on the stem 90, and a surrounding member 130 surrounding the semiconductor light emitting device 10B. The stem 90 includes a flat base 100 and a heat sink 110 arranged upright on the base 100. The semiconductor light emitting device 10B is mounted on the heat sink 110. The surrounding member 130 surrounds the semiconductor light emitting device 10B and the heat sink 110. The structure for packaging the semiconductor light emitting device 10B using the stem 90 and the surrounding member 130 may be referred to as a CAN package structure.

In the following description of the present embodiment, the thickness-wise direction of the base 100 is referred to as the z-direction. Two directions that are orthogonal to each other and to the z-direction are referred to as the x-direction and the y-direction.

The surrounding member 130 is arranged on the base 100. The surrounding member 130 and the base 100 define an accommodation space SP that accommodates the semiconductor light emitting device 10B and the heat sink 110. The surrounding member 130 is fixed to the base 100. The surrounding member 130 and the base 100 hermetically seal the accommodation space SP in a hollow state to obtain a hollow sealing structure.

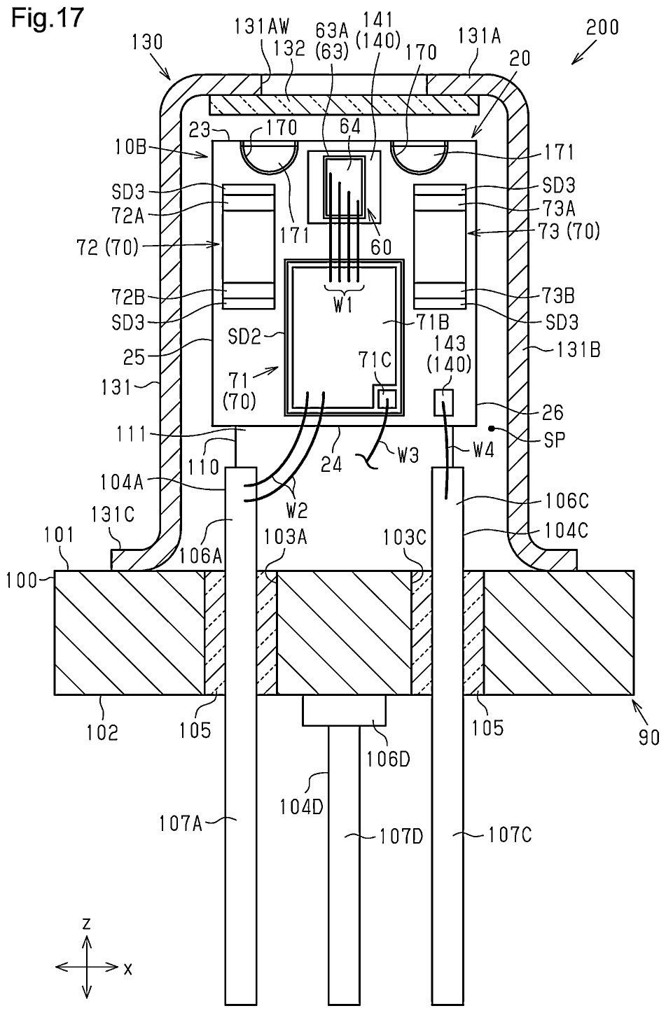

As shown in FIG. 17, the surrounding member 130 includes a cap 131 and a light-transmissive plate 132. The cap 131 is formed from a metal material having a light-shielding property such as iron (Fe) or a Fe alloy. The material forming the cap 131 may be changed in any manner. In an example, the cap 131 may be formed from a light-transmissive resin material or glass. Alternatively, the light-transmissive plate 132 may be omitted from the surrounding member 130.

The cap 131 includes a top 131A, a tube 131B, and a flange 131C. In the present embodiment, for example, the top 131A, the tube 131B, and the flange 131C are formed integrally with each other. Alternatively, the top 131A, the tube 131B, and the flange 131C may be separately formed. In this case, the top 131A, the tube 131B, and the flange 131C are joined by, for example, welding, adhesion, or the like.

The tube 131B is, for example, circular and extends in the z-direction. The top 131A is located on one of two ends of the tube 131B in the z-direction opposite from the base 100. The top 131A includes a window 131AW that allows transmission of light emitted from the semiconductor light emitting device 10B. As viewed in the z-direction, the window 131AW is, for example, circular.

The flange 131C is located on one of the two ends of the tube 131B in the z-direction located close to the base 100. The flange 131C is fixed to the base 100 by, for example, welding or using a bonding material.

The light-transmissive plate 132 is fixed to the top 131A of the cap 131 by a bonding material or the like. Thus, the light-transmissive plate 132 closes the window 131AW. The light-transmissive plate 132 may be formed from, for example, a light-transmissive resin material or a transparent material such as glass. The light-transmissive plate 132 allows transmission of light through the window 131AW. The light-transmissive plate 132 is also used as an encapsulating member that encapsulates the accommodation space SP, which is surrounded by the base 100 and the surrounding member 130.

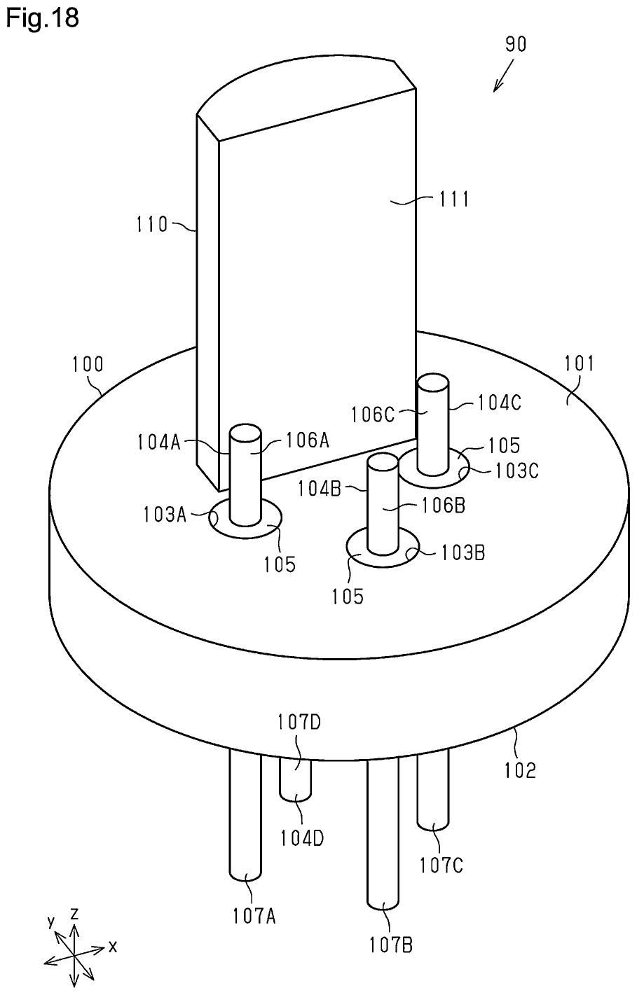

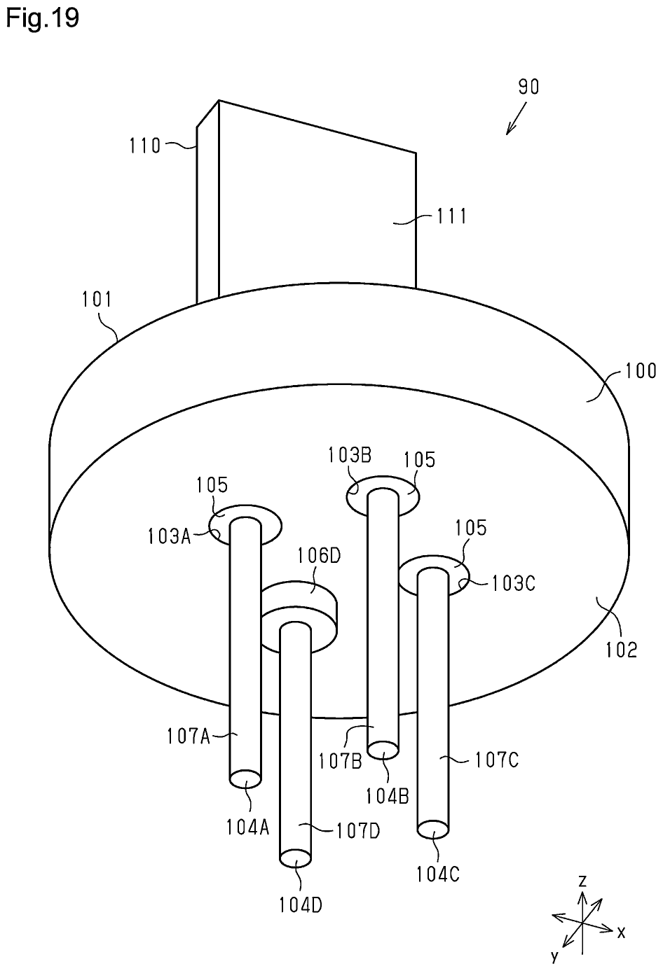

As shown in FIGS. 18 and 19, in the present embodiment, the base 100 and the heat sink 110 are integrally formed in the stem 90. The stem 90 is formed from, for example, a conductive material such as Cu, a Cu alloy, Fe, a Fe alloy, Al, an Al alloy. That is, the stem 90 includes a conductive base 100 and a conductive heat sink 110. Alternatively, the base 100 and the heat sink 110 may be separately formed. In this case, the material forming the base 100 may differ from the material forming the heat sink 110.

As viewed in the z-direction, the base 100 is substantially circular. In the present embodiment, the diameter of the base 100 is approximately 5.6 mm, and the thickness of the base 100 is approximately 1.2 mm. The diameter and the thickness of the base 100 may be changed in any manner. The base 100 includes a base front surface 101 and a base back surface 102 facing opposite directions in the z-direction.

The heat sink 110 is offset from the center of the base 100 in the y-direction. As viewed in the z-direction, the heat sink 110 is substantially sectoral. The heat sink 110 extends from the base 100 in the z-direction. In the present embodiment, the height of the heat sink 110 from the base front surface 101 of the base 100 (dimension of the heat sink 110 in the z-direction) is approximately 4.45 mm. The maximum thickness of the heat sink 110 (dimension of the heat sink 110 in the y-direction) is approximately 0.75 mm. The height and the thickness of the heat sink 110 may be changed in any manner.

The heat sink 110 includes a planar support surface 111. The support surface 111 is planar and parallel to the xz plane. The semiconductor light emitting device 10B (refer to FIG. 16) is mounted on the support surface 111. For example, the semiconductor light emitting device 10B is bonded to the support surface 111 by a conductive bonding material (not shown) such as solder paste or Ag paste. In the present embodiment, the y-direction refers to the thickness-wise direction of the substrate 20. In the present embodiment, “viewed in the y-direction” refers to viewing in the thickness-wise direction of the substrate 20.

Through holes extend through the base 100 in the thickness-wise direction of the base 100 (the z-direction). In the present embodiment, the through holes include, for example, three through holes 103A, 103B, and 103C. The through holes 103A, 103B, and 103C are offset from the center of the base 100 in the y-direction opposite to the heat sink 110. As viewed in the z-direction, the through holes 103A, 103B, and 103C are, for example, substantially circular. In the present embodiment, the through holes 103A, 103B, and 103C have the same diameter, which is, for example, approximately 1.0 mm. The diameter of the through holes 103A, 103B, and 103C may be changed in any manner.

The semiconductor light emitting unit 200 includes lead pins configured to electrically connect the semiconductor light emitting device 10B to a circuit board when the semiconductor light emitting unit 200 is mounted on the circuit board. In the present embodiment, the lead pins include four lead pins 104A, 104B, 104C, and 104D.

The lead pins 104A, 104B, and 104C extend through the base 100 in the thickness-wise direction (the z-direction). More specifically, the lead pin 104A is inserted into the through hole 103A, the lead pin 104B is inserted into the through hole 103B, and the lead pin 104C is inserted into the through hole 103C. Insulation members 105 fill the through holes 103A to 103C to electrically insulate the lead pins 104A to 104C from the base 100. The insulation members 105 are formed from, for example, an insulative resin material or a glass material.

The lead pins 104A to 104C project from the base front surface 101 and the base back surface 102 of the base 100 in the z-direction. The lead pins 104A, 104B, and 104C include connectors 106A, 106B, and 106C and terminals 107A, 107B, and 107C. The connectors 106A to 106C are portions of the lead pins 104A to 104C projecting from the base front surface 101 in the z-direction and electrically connected to the semiconductor light emitting device 10B. The terminals 107A to 107C are portions of the lead pins 104A to 104C projecting from the base back surface 102 in the z-direction and used as external terminals that are electrically connected to a circuit substrate when the semiconductor light emitting unit 200 is mounted on the circuit substrate.

As shown in FIG. 17, the lead pin 104D projects from the base back surface 102 of the base 100 in the z-direction but does not project from the base front surface 101 in the z-direction. As viewed in the z-direction, the lead pin 104D overlaps the heat sink 110. The lead pin 104D includes a connector 106D and a terminal 107D. The connector 106D is located on one of two ends of the lead pin 104D in the z-direction located close to the base 100. The connector 106D is bonded to the base 100. Thus, the lead pin 104D is electrically connected to the base 100. The terminal 107D is a portion of the lead pin 104D projecting from the connector 106D in the z-direction and used as an external terminal that is electrically connected to a circuit substrate when the semiconductor light emitting unit 200 is mounted on the circuit substrate.

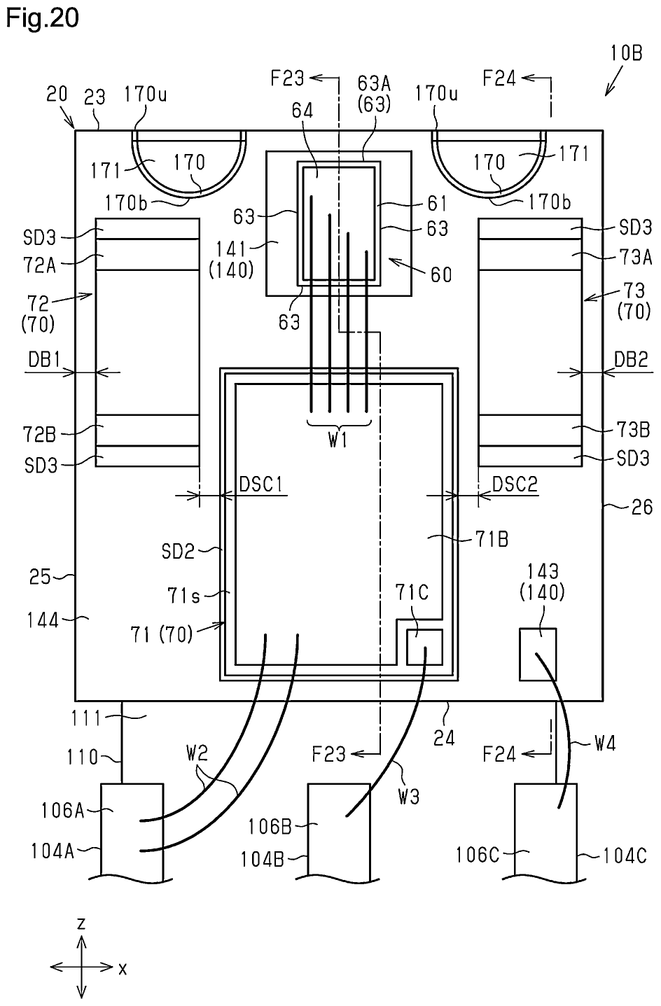

As shown in FIG. 20, in the semiconductor light emitting device 10B, the switching element 71 is electrically connected to the lead pins 104A and 104B by second wires W2 and a third wire W3, respectively. Hence, in the semiconductor light emitting device 10B, the third front surface interconnect 33 and the fourth front surface interconnect 34 (refer to FIG. 3) of the front surface interconnect 30 and the third back surface interconnect 43 and the fourth back surface interconnect 44 (refer to FIG. 4) of the back surface interconnect 40 are omitted as compared to the semiconductor light emitting device 10A of the first embodiment. Thus, the dimension of the long sides of the substrate 20 (dimension of the substrate 20 in the z-direction) of the semiconductor light emitting device 10B is smaller than the dimension of the long sides of the substrate 20 (dimension of the substrate 20 in the y-direction) of the semiconductor light emitting device 10A of the first embodiment.

The arrangement and the electrical connection of the semiconductor light emitting element 60, the switching element 71, and the capacitors 72 and 73 of the semiconductor light emitting device 10B are the same as those of the semiconductor light emitting device 10A of the first embodiment. The semiconductor light emitting device 10B includes a front surface insulation layer 144 arranged on the substrate front surface 21 of the substrate 20. The front surface insulation layer 144 is formed to cover the entire substrate front surface 21. Thus, the front surface insulation layer 144 covers the front surface interconnect 140. The front surface insulation layer 144 includes openings that expose the front surface interconnect 140 where the semiconductor light emitting element 60, the switching element 71, and the capacitors 72 and 73 are mounted. The front surface insulation layer 144 is formed from, for example, an insulation material such as silicon dioxide (SiO₂).

The substrate 20 of the semiconductor light emitting device 10B is smaller than the substrate 20 of the semiconductor light emitting device 10A of the first embodiment in dimension in the x-direction. For example, in the semiconductor light emitting device 10B, the distance DB1 between the capacitor 72 and the third substrate side surface 25 in the x-direction is equal to the distance DSC1 between the capacitor 72 and the switching element 71 in the x-direction. The distance DB2 between the capacitor 73 and the fourth substrate side surface 26 in the x-direction is equal to the distance DSC2 between the capacitor 73 and the switching element 71 in the x-direction. When the difference between the distance DB1 and the distance DSC1 is, for example, within 10% of the distance DSC1, it is considered that the distance DB1 is equal to the distance DSC1. When the difference between the distance DB2 and the distance DSC2 is, for example, within 10% of the distance DSC2, it is considered that the distance DB2 is equal to the distance DSC2. This structure allows the capacitors 72 and 73 to be located adjacent to the switching element 71 while reducing the size of the substrate 20 in the x-direction.

The distance DB1 may be greater than the distance DSC1. In an example, the distance DB1 is greater than the distance DSC1 and less than or equal to twice the distance DSC1. Also, the distance DB2 may be greater than the distance DSC2. In an example, the distance DB2 is greater than the distance DSC2 and less than or equal to twice the distance DSC2. This structure also allows the capacitors 72 and 73 to be located adjacent to the switching element 71 while reducing the size of the substrate 20 in the x-direction.

In another example, the distance DB1 may be less than the distance DSC1. The distance DB2 may be less than the distance DSC2. This structure allows the capacitors 72 and 73 to be located adjacent to the switching element 71 while further reducing the size of the substrate 20 in the x-direction.

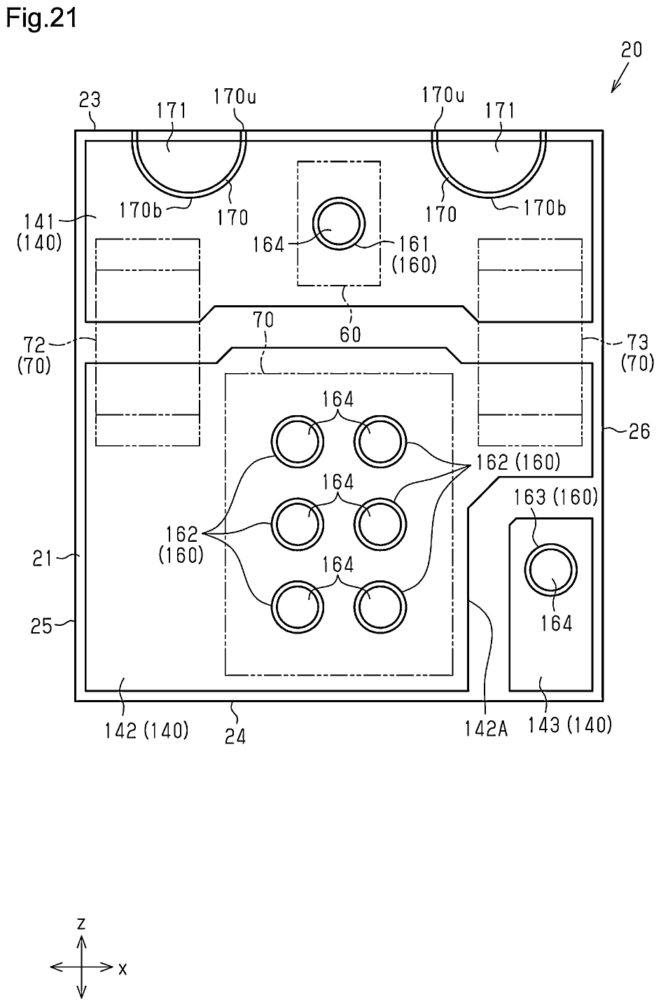

FIG. 21 is a plan view of the substrate 20. For the sake of convenience, FIG. 21 does not show the front surface insulation layer 144 and indicates the semiconductor light emitting element 60, the switching element 71, and the capacitors 72 and 73 with double-dashed lines.

As shown in FIG. 21, the front surface interconnect 140 includes a first front surface interconnect 141, a second front surface interconnect 142, and an external interconnect 143. The first front surface interconnect 141, which has the same shape and the same arrangement as the first front surface interconnect 31 of the first embodiment, will not be described in detail.

The second front surface interconnect 142 is located adjacent to the first front surface interconnect 141 in the z-direction. In the z-direction, the second front surface interconnect 142 is located on the substrate front surface 21 closer to the second substrate side surface 24 than to the first substrate side surface 23. The second front surface interconnect 142 includes a depression 142A located toward the fourth substrate side surface 26 and the second substrate side surface 24. As viewed in the z-direction, the depression 142A overlaps the capacitor 73.

The external interconnect 143 is arranged in the depression 142A of the second front surface interconnect 142. The external interconnect 143 is electrically connected to the lead pin 104C by a fourth wire W4 (refer to FIG. 20). As shown in FIG. 20, the front surface insulation layer 144 includes an opening that exposes the external interconnect 143. The fourth wire W4 is connected to the external interconnect 143 through the opening in the front surface insulation layer 144. As viewed in the y-direction, the external interconnect 143 is rectangular so that the long sides extend in the z-direction and the short sides extend in the x-direction.

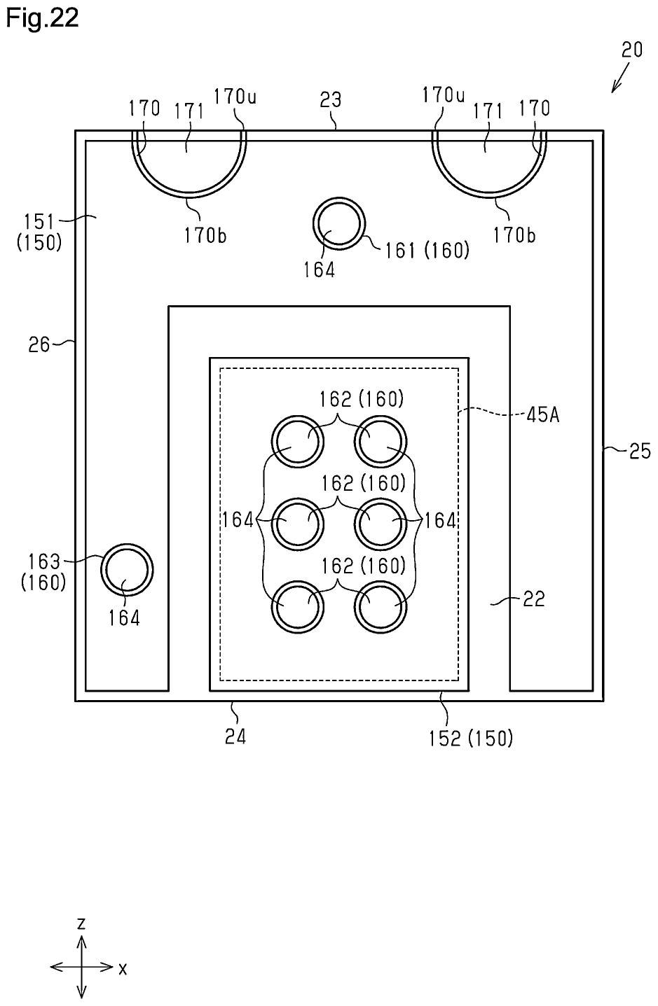

FIG. 22 is a back view of the substrate 20. For the sake of convenience, FIG. 22 does not show the back surface insulation layer 45.

As shown in FIG. 22, the back surface interconnect 150 includes a first back surface interconnect 151 and a second back surface interconnect 152.

The first back surface interconnect 151 is electrically connected to the first front surface interconnect 141 and the external interconnect 143 (refer to FIG. 21). More specifically, the first back surface interconnect 151 is electrically connected to the second electrode 65 (cathode electrode) of the semiconductor light emitting element 60 and the first electrodes 72A and 73A (refer to FIG. 20) of the capacitors 72 and 73. As viewed in the y-direction, the first back surface interconnect 151 is C-shaped and extends on a peripheral portion of the substrate back surface 22 along the first substrate side surface 23, the third substrate side surface 25, and the fourth substrate side surface 26. In other words, as viewed in the y-direction, the first back surface interconnect 151 is C-shaped and is open at the second substrate side surface 24. As viewed in the y-direction, the first back surface interconnect 151 is located to overlap with the first front surface interconnect 141 and the external interconnect 143 and partially overlaps with the second front surface interconnect 142 (refer to FIG. 21). As viewed in the y-direction, the area of the first back surface interconnect 151 is greater than the area of the first front surface interconnect 141. Moreover, as viewed in the y-direction, the area of the first back surface interconnect 151 is greater than the total of the area of the first front surface interconnect 141 and the area of the external interconnect 143.

The second back surface interconnect 152 is electrically connected to the second front surface interconnect 142. More specifically, the second back surface interconnect 152 is electrically connected to the first electrode 71A (drain electrode) of the switching element 71. The second back surface interconnect 152 is arranged in the C-shaped first back surface interconnect 151. As viewed in the y-direction, the second back surface interconnect 152 is located to overlap the switching element 71. As viewed in the y-direction, the area of the second back surface interconnect 152 is smaller than the area of the first back surface interconnect 151.

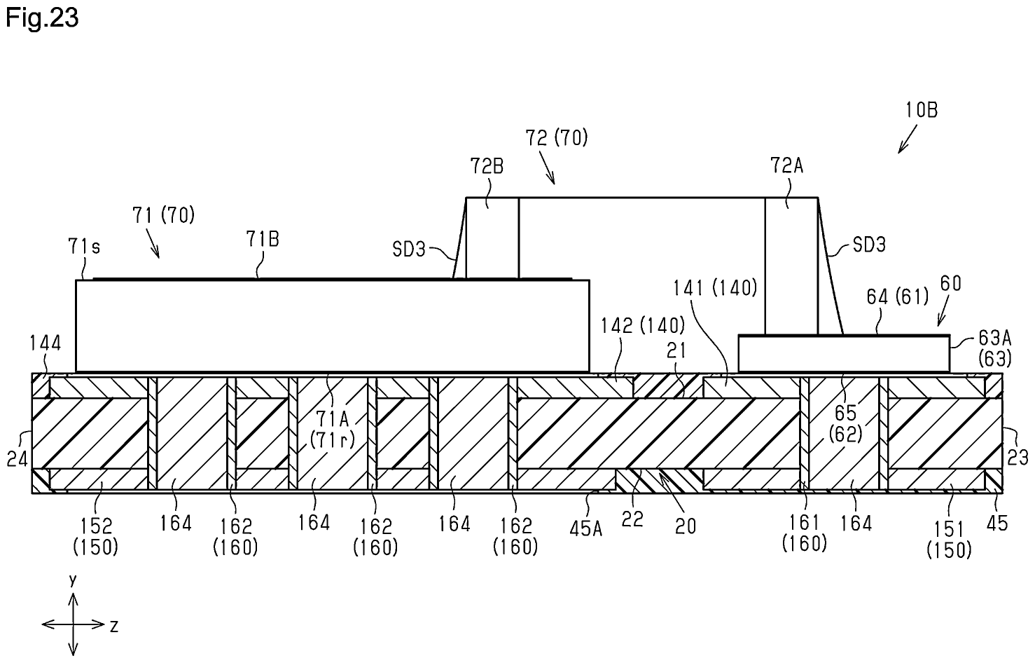

As shown in FIG. 23, the back surface insulation layer 45 covers the first back surface interconnect 151. The back surface insulation layer 45 includes an opening 45A that exposes the second back surface interconnect 152. As indicated by the broken lines shown in FIG. 22, the opening 45A is open to the second back surface interconnect 152 excluding peripheral portions of the second back surface interconnect 152. In other words, the back surface insulation layer 45 covers the peripheral portions of the second back surface interconnect 152.

Although not shown, a conductive bonding material such as solder paste or Ag paste is applied to the second back surface interconnect 152 through the opening 45A. The conductive bonding material bonds the second back surface interconnect 152 and the support surface 111 (refer to FIG. 18) of the heat sink 110. Thus, the semiconductor light emitting device 10B is mounted on the support surface 111. Also, the second back surface interconnect 152 is electrically connected to the heat sink 110 by the conductive bonding material. The first back surface interconnect 151 is insulated from the heat sink 110 since the back surface insulation layer 45 covers the first back surface interconnect 151.

As shown in FIGS. 21 and 22, the semiconductor light emitting device 10B includes inner through holes 160 connecting the front surface interconnect 140 and the back surface interconnect 150. As viewed in the y-direction, the inner through holes 160 are arranged inward from the first to fourth substrate side surfaces 23 to 26 of the substrate 20. The inner through holes 160 include a first inner through hole 161, second inner through holes 162, and a third inner through hole 163.

In the present embodiment, as viewed in the y-direction, the first to third through holes 161 to 163 are each circular. In other words, the first to third inner through holes 161 to 163 are each cylindrical. In the present embodiment, the first to third inner through holes 161 to 163 are equal to each other in size (diameter of the first to third inner through holes 161 to 163). When the largest difference between the first to third inner through holes 161 to 163 is, for example, within 10% of the size of the first inner through hole 161, it is considered that the first to third inner through holes 161 to 163 are equal to each other in size.

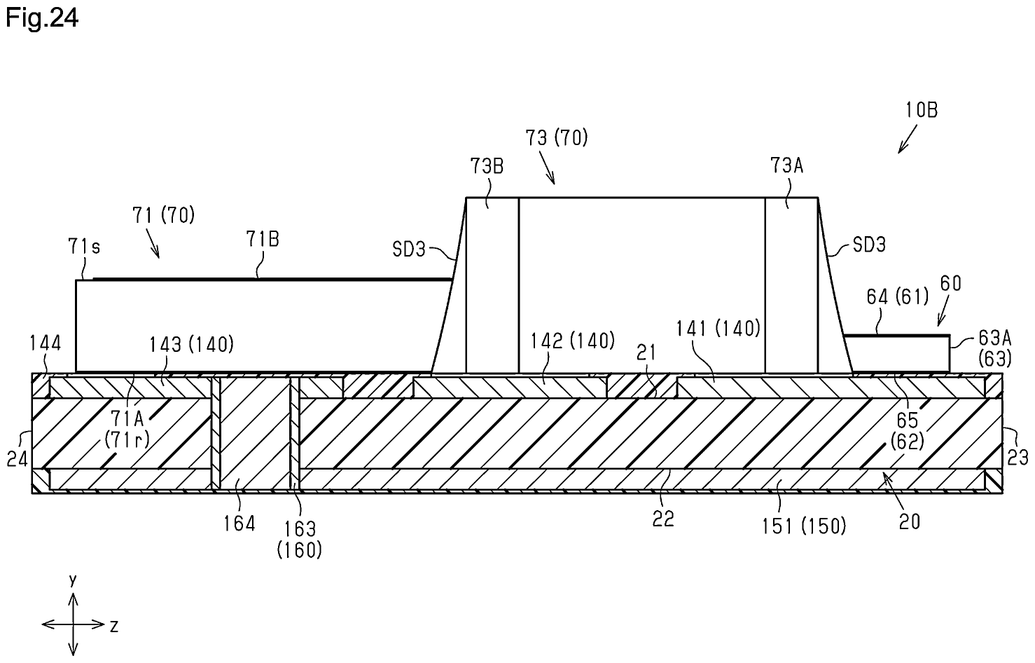

The first to third inner through holes 161 to 163 are formed from a conductive material (in the present embodiment, Cu). As shown in FIGS. 23 and 24, the inside of the first to third inner through holes 161 to 163 is filled with heat dissipation members 164. The heat dissipation members 164 fill the inside of the first to third inner through holes 161 to 163. The heat dissipation members 164 are formed from, for example, a metal material. An example of the metal material is Cu. That is, the heat dissipation members 164 and the first to third inner through holes 161 to 164 may be formed from the same material.

The material of the heat dissipation members 164 may be changed in any manner. In an example, the heat dissipation members 164 may be formed from a metal material that differs from the metal material forming the first to third inner through holes 161 to 163. Alternatively, the heat dissipation members 164 may be formed from an insulation material having a good heat dissipation property such as ceramic instead of a metal material.

As shown in FIGS. 21 and 23, the first inner through hole 161 is an interconnect connecting the first front surface interconnect 141 and the first back surface interconnect 151. The first inner through hole 161 electrically connects the first front surface interconnect 141 to the first back surface interconnect 151. In the present embodiment, the single first inner through hole 161 is arranged. As viewed in the y-direction, the first inner through hole 161 overlaps the semiconductor light emitting element 60.

The second inner through holes 162 each are an interconnect connecting the second front surface interconnect 142 and the second back surface interconnect 152. The second inner through holes 162 electrically connect the second front surface interconnect 142 and the second back surface interconnect 152. Multiple (in the present embodiment, six) second inner through holes 162 are arranged. As viewed in the y-direction, the second inner through holes 162 overlap the switching element 71.

As shown in FIGS. 21 and 24, the third inner through hole 163 is an interconnect connecting the external interconnect 143 and the first back surface interconnect 151. The third inner through hole 163 electrically connects the external interconnect 143 and the first back surface interconnect 151. The third inner through hole 163 is a single hole. In the present embodiment, the third inner through hole 163 is located in the external interconnect 143 toward the first substrate side surface 23 in the z-direction.

The number of each of the first to third inner through holes 161 to 163 may be changed in any manner. The shape of the first to third inner through holes 161 to 163 as viewed in the z-direction may be changed in any manner. For example, each of the first to third inner through holes 161 to 163 may have a different shape as viewed in the y-direction. The size of each of the first to third inner through holes 161 to 163 may be changed in any manner. For example, each of the first to third inner through holes 161 to 163 may have a different size.

As shown in FIG. 20, the first substrate side surface 23 of the substrate 20 includes end surface through holes 170 extending through the substrate 20 in the y-direction, that is, the thickness-wise direction of the substrate 20. The end surface through holes 170 connect the first front surface interconnect 141 and the first back surface interconnect 151 (refer to FIG. 22).

As viewed in the y-direction, the end surface through holes 170 are recessed from the first substrate side surface 23 toward the second substrate side surface 24 in the z-direction. As viewed in the y-direction, the end surface through holes 170 have the form of a curved recess. In the present embodiment, as viewed in the y-direction, the end surface through holes 170 are semicircular. In addition to the first substrate side surface 23, the first front surface interconnect 141 and the first back surface interconnect 151 include a semicircular recess. The end surface through holes 170, which are interconnects formed from a conductive material, are arranged on the recessed semicircular side surfaces of the first substrate side surface 23, the first front surface interconnect 141, and the first back surface interconnect 151. The end surface through holes 170 extend along the recessed semicircular side surfaces. Each end surface through hole 170 includes an open end 170u. The open end 170u includes a portion corresponding to the first substrate side surface 23 that is flush with the first substrate side surface 23, a portion corresponding to the first front surface interconnect 141 that is flush with the first front surface interconnect 141, and a portion corresponding to the first back surface interconnect 151 that is flush with the first back surface interconnect 151. Thus, in the present embodiment, opposite ends of the end surface through holes 170 in the y-direction include a step. The conductive material forming the end surface through holes 170 may be, for example, Cu. That is, the material forming the end surface through holes 170 is the same as the material forming the inner through holes 160 (refer to FIG. 22). The conductive material forming the end surface through holes 170 may be changed in any manner.

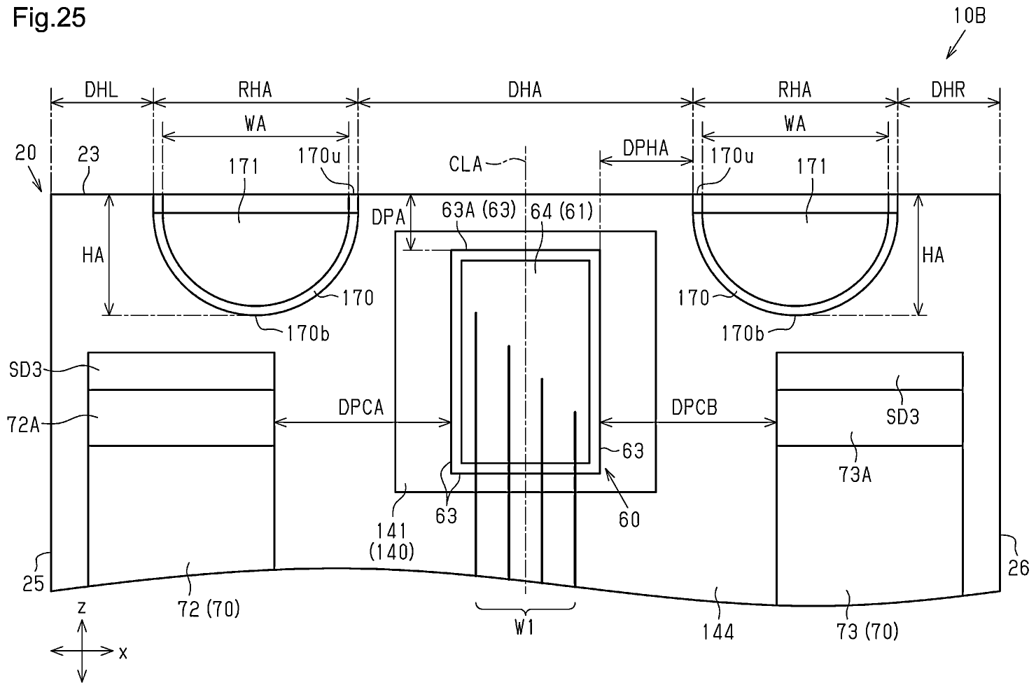

As shown in FIG. 25, in the present embodiment, the end surface through holes 170 have an opening width WA that is greater than a depth-wise dimension HA of the end surface through holes 170. As viewed in the y-direction, the opening width WA of the end surface through hole 170 is defined by the distance in the open end 170u of the end surface through hole 170 in the x-direction. The depth-wise dimension HA of the end surface through hole 170 is defined by the maximum distance between the open end 170u of the end surface through hole 170 and a side surface 170b of the end surface through hole 170 in the z-direction. In the present embodiment, the opening width WA of the end surface through hole 170 is greater than the outer diameters of the first to third inner through holes 161 to 163 (refer to FIG. 22). The depth-wise dimension HA of the end surface through hole 170 is greater than or equal to the outer diameters of the first to third inner through holes 161 to 163.

In the semiconductor light emitting device 10B, the opening width WA of the end surface through hole 170 is, for example, greater than the dimension of the semiconductor light emitting element 60 in the x-direction. The size of the opening width WA may be changed in any manner. In an example, the opening width WA of the end surface through hole 170 may be less than or equal to the dimension of the semiconductor light emitting element 60 in the x-direction.

Multiple (in the present embodiment, two) end surface through holes 170 are arranged. In the present embodiment, the two end surface through holes 170 are identical to each other in shape and size. The two end surface through holes 170 are aligned with each other in the z-direction and separated from each other in the x-direction. In the present embodiment, the two end surface through holes 170 are symmetrically arranged with respect to a centerline CLA extending in the z-direction through the center of the substrate 20 in the x-direction. In the present embodiment, a distance DHA between the two end surface through holes 170 in the x-direction is greater than a distance DHL in the x-direction between the third substrate side surface 25 and the end surface through hole 170 that is located toward the third substrate side surface 25. The distance DHA is greater than a distance DHR in the x-direction between the fourth substrate side surface 26 and the end surface through hole 170 that is located toward the fourth substrate side surface 26.

The distance DHA is greater than the dimension of the semiconductor light emitting element 60 in the x-direction. The distance DHA is greater than the dimension of each of the capacitors 72 and 73 in the x-direction and less than the dimension of the switching element 71 (refer to FIG. 20) in the x-direction.

As viewed in the z-direction, the two end surface through holes 170 are separated from the semiconductor light emitting element 60. More specifically, as viewed in the y-direction, the two end surface through holes 170 are separately located at opposite sides of the semiconductor light emitting element 60 in the x-direction. As viewed in the y-direction, the end surface through holes 170 are located adjacent to the semiconductor light emitting element 60 in the x-direction. In the present embodiment, a distance DPHA between the end surface through hole 170 and the semiconductor light emitting element 60 in the x-direction is less than the opening width WA of the end surface through hole 170. The distance DPHA is also less than the dimension of the semiconductor light emitting element 60 in the x-direction. As viewed in the y-direction, the distance DPHA is defined by the distance between the side surface 170b of the end surface through hole 170 and the semiconductor light emitting element 60 in the x-direction. In other words, the distance DPHA is the minimum distance between the end surface through hole 170 and the semiconductor light emitting element 60 in the x-direction.

The end surface through hole 170 partially overlaps the semiconductor light emitting element 60 as viewed in a direction extending along the first substrate side surface 23 (x-direction). More specifically, the side surface 170b of the end surface through hole 170 includes a portion located toward the second substrate side surface 24 (toward the switching element 71) from the light emitting element side surface 63A of the semiconductor light emitting element 60. In other words, the distance DPA between the first substrate side surface 23 and the light emitting element side surface 63A (light emitting surface) of the semiconductor light emitting element 60 in the z-direction is less than the depth-wise dimension HA of the end surface through hole 170. The distance DPA is set so that light emitted from the semiconductor light emitting element 60 does not strike the substrate front surface 21 of the substrate 20.

The arrangement relationship among the two end surface through holes 170, the switching element 71, and the capacitors 72 and 73 is the same as the arrangement relationship among the two end surface through holes 51A, the switching element 71, and the capacitors 72 and 73 of the first embodiment. Thus, the arrangement relationship among the two end surface through holes 170, the switching element 71, and the capacitors 72 and 73 will not be described in detail.

Each end surface through hole 170 has an outer diameter RHA that is greater than or equal to the distance DPCA between the semiconductor light emitting element 60 and the capacitor 72 in the x-direction. In the present embodiment, the outer diameter RHA of the end surface through hole 170 is greater than the distance DPCA between the semiconductor light emitting element 60 and the capacitor 72 in the x-direction.

The outer diameter RHA of the end surface through hole 170 is greater than or equal to the distance DPCB between the semiconductor light emitting element 60 and the capacitor 73 in the x-direction. In the present embodiment, the outer diameter RHA of the end surface through hole 170 is greater than the distance DPCB between the semiconductor light emitting element 60 and the capacitor 73 in the x-direction.

Each end surface through hole 170 is filled with a heat dissipation member 171. The heat dissipation member 171 is flush with the end surfaces of the open ends 170u of the end surface through hole 170. Opposite ends of the heat dissipation member 171 in the y-direction include a step in the same manner as the open ends 170u of the end surface through hole 170. As viewed in the y-direction, the heat dissipation member 171 is substantially semicircular. The heat dissipation member 171 is equal to the end surface through hole 170 in the dimension in the y-direction.

The heat dissipation member 171 is formed from, for example, a metal material. An example of the metal material is Cu. That is, the heat dissipation member 171 and the end surface through hole 170 may be formed from the same material.

The material of the heat dissipation member 171 may be changed in any manner. In an example, the heat dissipation member 171 may be formed from a metal material that differs from the metal material forming the end surface through hole 170. Alternatively, the heat dissipation member 171 may be formed from an insulation material having a good heat dissipation property such as ceramic instead of a metal material.

The present embodiment differs from the first embodiment in that the third substrate side surface 25 and the fourth substrate side surface 26 do not include an end surface through hole. More specifically, the end surface through holes arranged in the substrate 20 correspond to the end surface through holes 170 connecting the first front surface interconnect 141 and the first back surface interconnect 151 and arranged in only the first substrate side surface 23 without being arranged in the third substrate side surface 25 and the fourth substrate side surface 26. In this case, the second front surface interconnect 142 and the second back surface interconnect 152 are electrically connected by the second inner through holes 162.

The connection structure of the semiconductor light emitting device 10B with the lead pins 104A to 104D will now be described.

As shown in FIG. 20, the second wires W2 connect the connector 106A of the lead pin 104A and one of two ends of the second electrode 71B (source electrode) of the switching element 71 in the z-direction located closer to the lead pin 104A. Thus, the second electrode 71B of the switching element 71 is electrically connected to the lead pin 104A. In other words, the terminal 107A of the lead pin 104A includes a source terminal.

The third wire W3 connects the control electrode 71C (gate electrode) of the switching element 71 and the connector 106B of the lead pin 104B. Thus, the control electrode 71C of the switching element 71 is electrically connected to the lead pin 104B. In other words, the terminal 107B of the lead pin 104B includes a gate terminal.

The fourth wire W4 connects the external interconnect 143 and the connector 106C of the lead pin 104C. The external interconnect 143 is electrically connected to the second electrode 65 (cathode electrode) of the semiconductor light emitting element 60 through the third inner through hole 163, the first back surface interconnect 151, and the first front surface interconnect 141. In other words, the terminal 107C of the lead pin 104C includes a cathode terminal.

The second back surface interconnect 152 is connected to the heat sink 110 by a conductive bonding material (not shown) such as solder paste or Ag paste. Since the heat sink 110 is electrically connected to the lead pin 104D by the base 100, the second back surface interconnect 152 is electrically connected to the lead pin 104D. The second back surface interconnect 152 is electrically connected to the first electrode 71A (drain electrode) of the switching element 71. In other words, the terminal 107D of the lead pin 104D includes a drain terminal.

When the semiconductor light emitting device 10B, which has been described above, is applied to the laser system LS (refer to FIG. 9), the electrical connection configuration of the semiconductor light emitting device 10B with the drive power supply DV, the current limiting resistor R, the diode D, and the driver circuit PM is the same as the electrical connection configuration of the semiconductor light emitting device 10A with the drive power supply DV, the current limiting resistor R, the diode D, and the driver circuit PM in the first embodiment.

### Advantages

The semiconductor light emitting device 10B and the semiconductor light emitting unit 200 of the present embodiment obtain the following advantages in addition to the advantages of the first embodiment.
(2-1) The semiconductor light emitting unit 200 includes the semiconductor light emitting device 10B, the stem 90, and the surrounding member 130. The stem 90 includes the conductive base 100 and the conductive heat sink 110 arranged upright on the base 100. The semiconductor light emitting device 10B is mounted on the heat sink 110. The surrounding member 130 is arranged on the base 100 to surround the semiconductor light emitting device 10B and the heat sink 110. The semiconductor light emitting device 10B includes the substrate 20, which is mounted on the heat sink 110, and the semiconductor light emitting element 60 and the light emitting element control circuit 70, which are mounted on the substrate 20. The light emitting element control circuit 70 includes the switching element 71 configured to control the supply of current to the semiconductor light emitting element 60. The switching element 71 is arranged as a vertical MOSFET.

This structure shortens the wiring path of the switching element 71 as compared to when the switching element 71 is a lateral MOSFET. As a result, the semiconductor light emitting device 10B, which is mounted on the stem 90, is reduced in size. In addition, the wiring path of current formed by the capacitors 72 and 73, the switching element 71, and the semiconductor light emitting element 60 is shortened as compared to when the switching element 71 is a lateral MOSFET. This decreases parasitic inductance in the wiring path.
(2-2) The lead pins 104A to 104D electrically connects the semiconductor light emitting unit 200 to a circuit substrate on which the semiconductor light emitting unit 200 is mounted.

In this structure, the semiconductor light emitting device 10B is controlled through the lead pins 104A to 104D by the driver circuit PM arranged on the circuit substrate. In addition, the lead pins 104A to 104D form a heat dissipation path from the semiconductor light emitting device 10B to the circuit substrate.
(2-3) The lead pin 104D is fixed to the base 100 and is electrically connected to the switching element 71 by the base 100, the heat sink 110, the second back surface interconnect 152, the second inner through holes 162, and the second front surface interconnect 142.

In this structure, when heat is generated in the switching element 71, the heat is emitted to the outside of the semiconductor light emitting unit 200 through the second front surface interconnect 142, the second inner through holes 162, the second back surface interconnect 152, the heat sink 110, the base 100, and the lead pin 104D. Thus, the volume of the heat transfer path that transfers heat from the switching element 71 to the outside of the semiconductor light emitting device 10B is increased. This further improves the heat dissipation property of the semiconductor light emitting device 10B.

### Third Embodiment

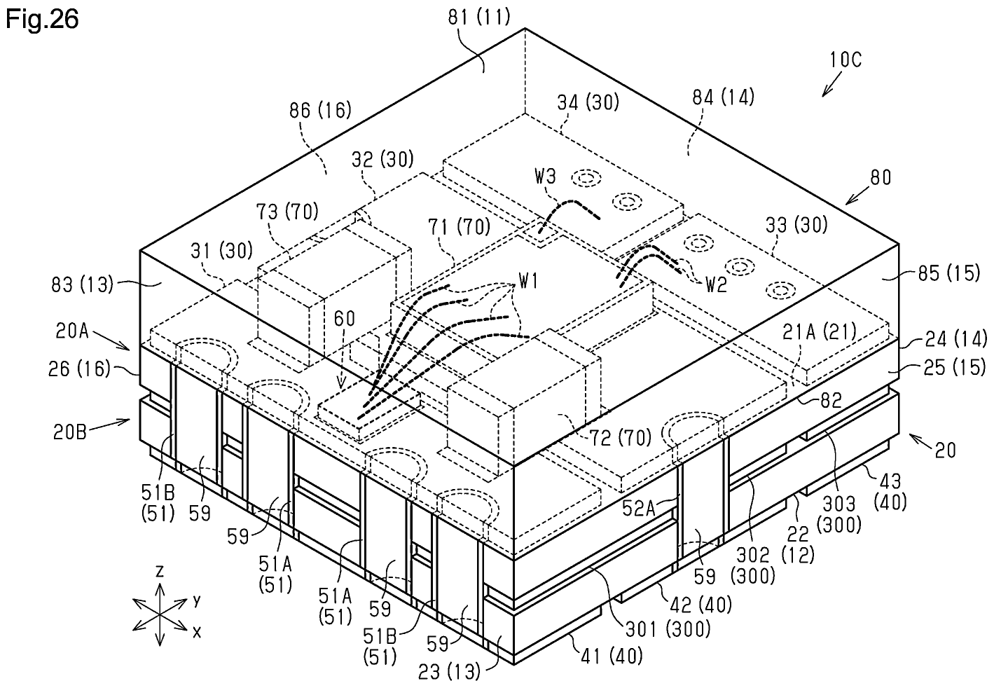

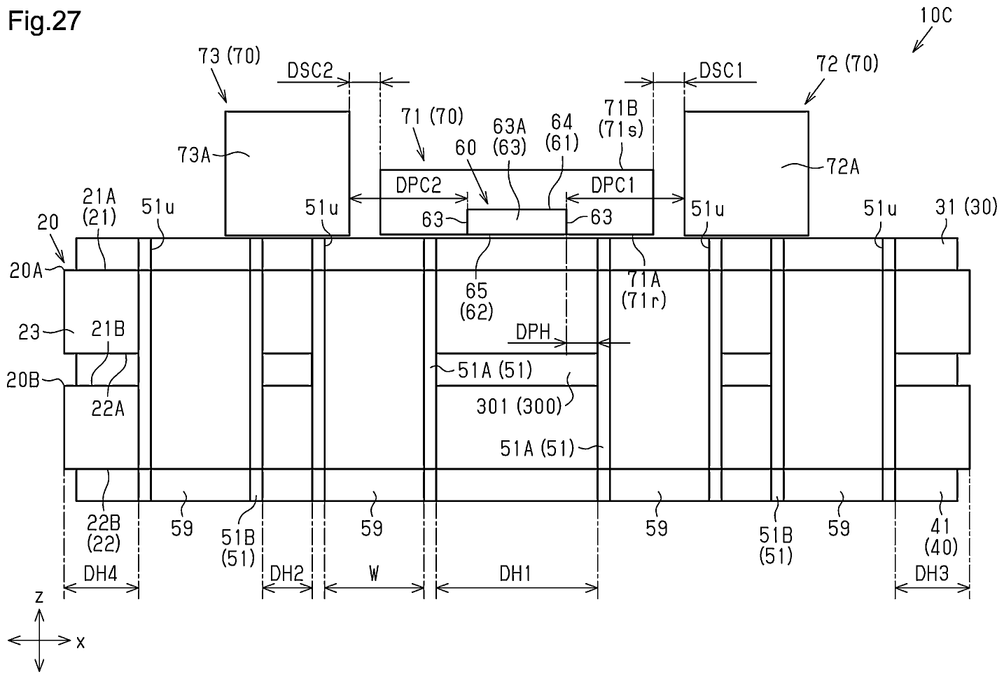

A third embodiment of a semiconductor light emitting device 10C will now be described with reference to FIGS. 26 to 31. The semiconductor light emitting device 10C of the present embodiment differs from the semiconductor light emitting device 10A of the first embodiment in the structures of a substrate and an inner through hole. In the following description of the semiconductor light emitting device 10C, same reference numerals are given to those components that are the same as the corresponding components of the semiconductor light emitting device 10A of the first embodiment. Such components will not be described in detail. For the sake of convenience, FIGS. 26 and 27 do not show the back surface insulation layer 45 and an intermediate insulation layer 305, which will be described later. For the sake of convenience, FIG. 27 does not show the encapsulation resin 80.

As shown in FIG. 26, the semiconductor light emitting device 10C includes a substrate 20 including a front surface substrate 20A and a back surface substrate 20B. In the thickness-wise direction of the substrate 20 (the z-direction), the front surface substrate 20A and the back surface substrate 20B are stacked on each other. The front surface substrate 20A and the back surface substrate 20B are formed from an insulative material. In the present embodiment, the front surface substrate 20A and the back surface substrate 20B are formed from a material including glass epoxy resin.

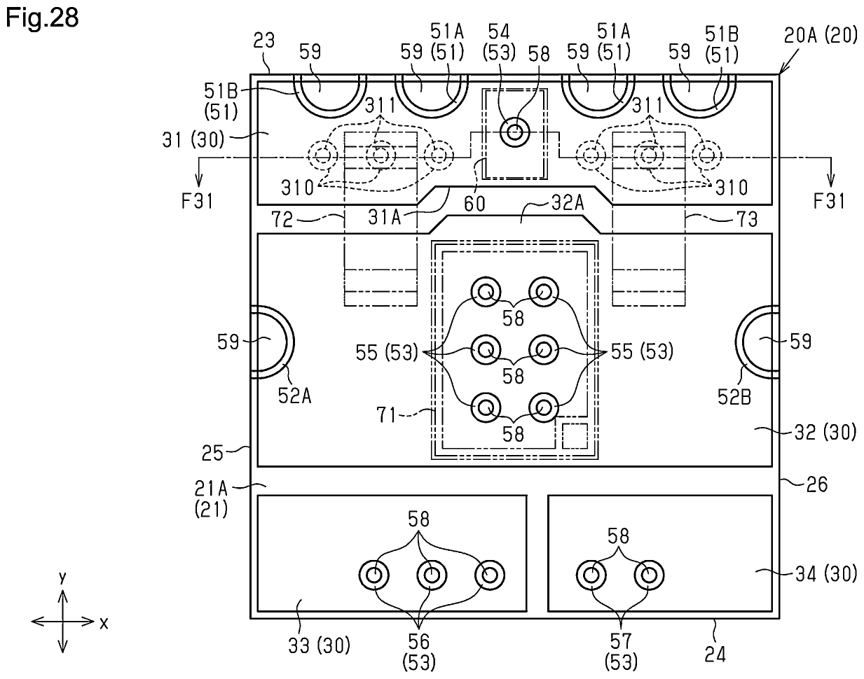

The front surface substrate 20A forms the substrate front surface 21 of the substrate 20. As shown in FIG. 27, the front surface substrate 20A includes a substrate front surface 21A and a substrate back surface 22A facing opposite directions in the z-direction. In other words, the substrate front surface 21A defines the substrate front surface 21 of the substrate 20. Thus, the front surface interconnect 30 is formed on the substrate front surface 21A of the front surface substrate 20A. As shown in FIG. 28, in the present embodiment, the front surface interconnect 30 includes first to fourth front surface interconnects 31 to 34 in the same manner as the first embodiment.

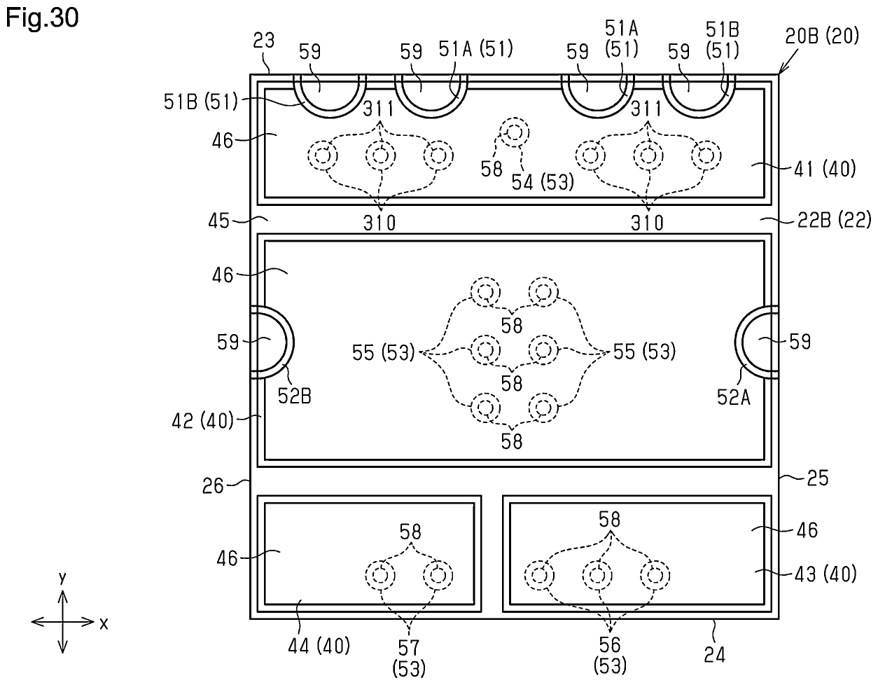

As shown in FIG. 27, the back surface substrate 20B forms the substrate back surface 22 of the substrate 20. The back surface substrate 20B includes a substrate front surface 21B and a substrate back surface 22B facing opposite directions in the z-direction. In other words, the substrate back surface 22B defines the substrate back surface 22 of the substrate 20. Thus, the back surface interconnect 40 is formed on the substrate back surface 22B of the back surface substrate 20B. As shown in FIG. 30, in the present embodiment, the back surface interconnect 40 includes first to fourth back surface interconnects 41 to 44 in the same manner as the first embodiment.

As shown in FIGS. 26, 27, and 29, the semiconductor light emitting device 10C includes an intermediate interconnect 300 and the intermediate insulation layer 305 sandwiched between the front surface substrate 20A and the back surface substrate 20B. The intermediate interconnect 300 is formed from the same material as the front surface interconnect 30 and the back surface interconnect 40. The intermediate interconnect 300 is formed from Cu or a Cu alloy.

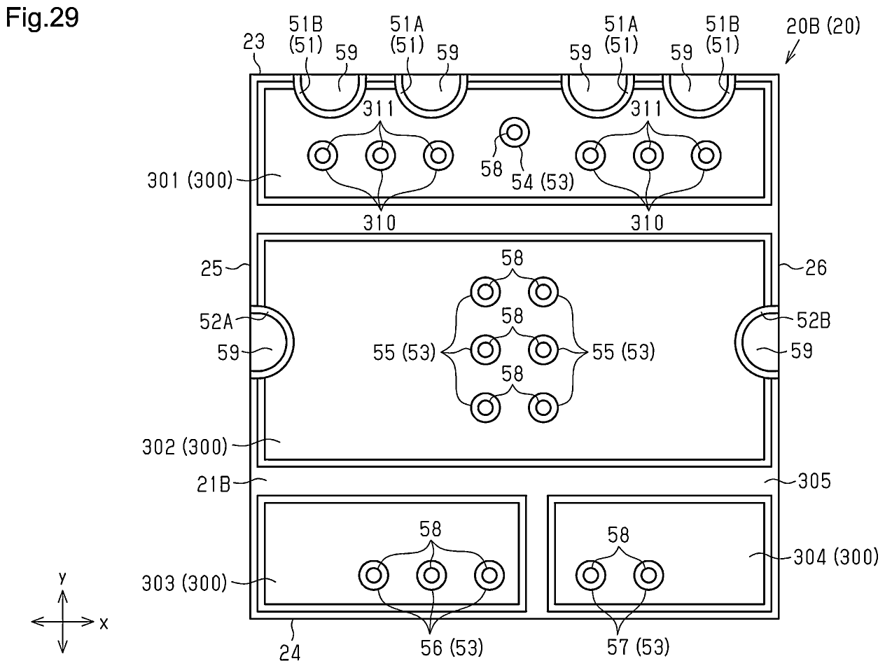

As shown in FIG. 29, the intermediate interconnect 300 includes a first intermediate interconnect 301, a second intermediate interconnect 302, a third intermediate interconnect 303, and a fourth intermediate interconnect 304. In the present embodiment, the first to fourth intermediate interconnects 301 to 304 are identical in shape to the first to fourth back surface interconnects 41 to 44. As shown in FIGS. 28 to 30, as viewed in the z-direction, the first intermediate interconnect 301 is located to overlap with the first back surface interconnect 41 and the first front surface interconnect 31. As viewed in the z-direction, the second intermediate interconnect 302 is located to overlap the second back surface interconnect 42. As viewed in the z-direction, the third intermediate interconnect 303 is located to overlap with the third back surface interconnect 43 and the third front surface interconnect 33. As viewed in the z-direction, the fourth intermediate interconnect 304 is located to overlap with the fourth back surface interconnect 44 and the fourth front surface interconnect 34.

The intermediate insulation layer 305 covers the substrate front surface 21B of the back surface substrate 20B excluding the intermediate interconnect 300. The intermediate insulation layer 305 is in contact with the substrate back surface 22A of the front surface substrate 20A. The intermediate insulation layer 305 is formed simultaneously with the front surface substrate 20A or the back surface substrate 20B. The material forming the intermediate insulation layer 305 is, for example, the same as the material forming the back surface insulation layer 45.

As shown in FIGS. 28, 29, and 31, the semiconductor light emitting device 10C includes fifth inner through holes 310 in addition to the first to fourth inner through holes 54 to 57. The fifth inner through holes 310 each correspond to a “second inner through hole extending through the back surface substrate at a position differing from the first inner through hole as viewed in the thickness-wise direction of the substrate and connecting the intermediate interconnect and the back surface interconnect.”

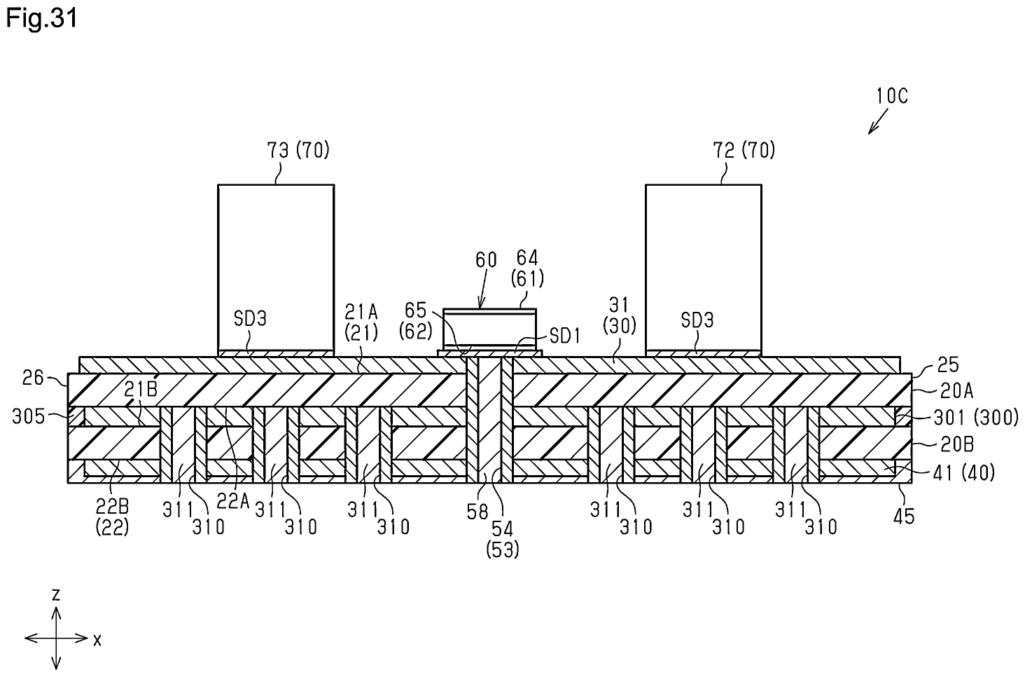

The fifth inner through holes 310 each are an interconnect connecting the first intermediate interconnect 301 and the first back surface interconnect 41. The fifth inner through holes 310 electrically connect the first intermediate interconnect 301 and the first back surface interconnect 41. The fifth inner through holes 310 extend through the back surface substrate 20B. As shown in FIG. 31, the fifth inner through holes 310 are located toward the substrate back surface 22 from the front surface substrate 20A. The fifth inner through holes 310 are greater than the first inner through hole 54 in the dimension in the z-direction.

As shown in FIGS. 28 to 30, as viewed in the z-direction, the fifth inner through holes 310 are circular. The fifth inner through holes 310 are equal to the first to fourth inner through holes 54 to 57 in diameter. When the largest difference in diameter between the fifth inner through holes 310 and the first to fourth inner through holes 54 to 57 is, for example, within 10% of the diameter of the fifth inner through holes 310, it is considered that the fifth inner through holes 310 are equal to the first to fourth inner through holes 54 to 57 in diameter.

Multiple (in the present embodiment, six) fifth inner through holes 310 are arranged. As viewed in the z-direction, the fifth inner through holes 310 are aligned with each other in the y-direction and separated from each other in the x-direction. In the present embodiment, three of the fifth inner through holes 310 are arranged at each of opposite sides of the first inner through hole 54 in the x-direction. The fifth inner through holes 310 are located closer to the second substrate side surface 24 in the y-direction than the first inner through hole 54 is. As shown in FIG. 28, as viewed in the z-direction, one of the fifth inner through holes 310 overlaps the capacitor 72. As viewed in the z-direction, another one of the fifth inner through holes 310 overlaps the capacitor 73. In the present embodiment, the material forming the fifth inner through holes 310 is the same as the material forming the first to fourth inner through holes 54 to 57. The material forming the fifth inner through holes 310 may be changed in any manner. For example, the material forming the fifth inner through holes 310 differs from the material forming the first to fourth inner through holes 54 to 57.

Heat dissipation members 311 are arranged in the fifth inner through holes 310. The heat dissipation members 311 fill the inside of the fifth inner through holes 310. The heat dissipation members 311 may be formed from, for example, a metal material. An example of the metal material is Cu. That is, the heat dissipation members 311 and the fifth inner through holes 310 may be formed from the same material.

The material of the heat dissipation members 311 may be changed in any manner. In an example, the heat dissipation members 311 may be formed from a metal material that differs from the metal material forming the fifth inner through holes 310. Alternatively, the heat dissipation members 311 may be formed from an insulation material having a good heat dissipation property such as ceramic instead of a metal material.

As shown in FIGS. 28 to 30, in the same manner as the first embodiment, the first substrate side surface 23 of the substrate 20 includes the end surface through holes 51A and 51B extending through the substrate 20 in the z-direction, that is, the thickness-wise direction of the substrate 20. In the present embodiment, the end surface through holes 51A and 51B extend through the front surface substrate 20A and the back surface substrate 20B in the z-direction, that is, the thickness-wise direction of the substrate 20, and connecting the first front surface interconnect 31, the first intermediate interconnect 301, and the first back surface interconnect 41. In the present embodiment, the first substrate side surface 23 of the front surface substrate 20A, the first substrate side surface 23 of the back surface substrate 20B, the first front surface interconnect 31, the first intermediate interconnect 301, and the first back surface interconnect 41 each include a semicircular recess. The end surface through holes 51A and 51B are arranged along the recessed semicircular side surfaces of the first substrate side surface 23 of the front surface substrate 20A, the first substrate side surface 23 of the back surface substrate 20B, the first front surface interconnect 31, the first intermediate interconnect 301, and the first back surface interconnect 41.

In the same manner as the first embodiment, the third substrate side surface 25 and the fourth substrate side surface 26 of the substrate 20 include the end surface through holes 52A and 52B extending through the substrate 20 in the z-direction, that is, the thickness-wise direction of the substrate 20. The end surface through holes 52A and 52B extend through the front surface substrate 20A and the back surface substrate 20B in the z-direction, that is, the thickness-wise direction of the substrate 20, and connect the second front surface interconnect 32, the second intermediate interconnect 302, and the second back surface interconnect 42.

In the present embodiment, the third substrate side surface 25 of the front surface substrate 20A, the third substrate side surface 25 of the back surface substrate 20B, the second front surface interconnect 32, the second intermediate interconnect 302, and the second back surface interconnect 42 each include a semicircular recess. The end surface through hole 52A is arranged along the recessed semicircular side surfaces of the third substrate side surface 25 of the front surface substrate 20A, the third substrate side surface 25 of the back surface substrate 20B, the second front surface interconnect 32, the second intermediate interconnect 302, and the second back surface interconnect 42.

In the present embodiment, the fourth substrate side surface 26 of the front surface substrate 20A, the fourth substrate side surface 26 of the back surface substrate 20B, the second front surface interconnect 32, the second intermediate interconnect 302, and the second back surface interconnect 42 each include a semicircular recess. The end surface through hole 52B is arranged along the recessed semicircular side surfaces of the fourth substrate side surface 26 of the front surface substrate 20A, the fourth substrate side surface 26 of the back surface substrate 20B, the second front surface interconnect 32, the second intermediate interconnect 302, and the second back surface interconnect 42.

The shape, the size, and the arrangement of the end surface through holes 51A and 51B of the present embodiment are the same as those of the end surface through holes 51A and 51B (refer to FIG. 3) of the first embodiment. The shape, the size, and the arrangement of the end surface through holes 52A and 52B are the same as those of the end surface through holes 52A and 52B of the first embodiment.

### Advantages

The semiconductor light emitting device 10C of the present embodiment has the following advantages in addition to the advantages of the first embodiment.
(3-1) The substrate 20 includes the front surface substrate 20A, which includes the front surface interconnect 30, and the back surface substrate 20B, which includes the back surface interconnect 40. The semiconductor light emitting device 10C includes the intermediate interconnect 300 sandwiched between the front surface substrate 20A and the back surface substrate 20B. The end surface through holes 51 (51A, 51B) extend through the front surface substrate 20A and the back surface substrate 20B in the thickness-wise direction of the substrate 20 and connect the front surface interconnect 30 (first front surface interconnect 31), the intermediate interconnect 300 (first intermediate interconnect 301), and the back surface interconnect 40 (first back surface interconnect 41).

In this structure, when the semiconductor light emitting element 60 generates heat, the heat may transfer from the end surface through holes 51 (51A, 51B) to the intermediate interconnect 300 (first intermediate interconnect 301). The heat transfers from the intermediate interconnect 300 (first intermediate interconnect 301) to the back surface interconnect 40 (first back surface interconnect 41) through the fifth inner through holes 310. Thus, the volume of the heat transfer path that transfers heat from the semiconductor light emitting element 60 to the outside of the semiconductor light emitting device 10C is increased. This improves the heat dissipation property of the semiconductor light emitting device 10C. In addition, the heat generated by the semiconductor light emitting element 60 may transfer from the intermediate interconnect 300 (first intermediate interconnect 301) to the end surface through holes 51A and 51B. This improves the heat dissipation property of the semiconductor light emitting device 10C.
(3-2) The semiconductor light emitting device 10C includes the first inner through hole 54 and the fifth inner through hole 310. The fifth inner through hole 310 connects the first intermediate interconnect 301 and the first back surface interconnect 41.

This structure increases the number of heat dissipation paths from the semiconductor light emitting element 60 to the first back surface interconnect 41, thereby improving the heat dissipation property of the semiconductor light emitting device 10C.

In the semiconductor light emitting device 10C, the looped wiring paths of the switching element 71, the capacitors 72 and 73, and the semiconductor light emitting element 60 are formed by the first electrodes 72A and 73A of the capacitors 72 and 73, the first front surface interconnect 31, the semiconductor light emitting element 60, the switching element 71, and the second electrodes 72B and 73B of the capacitors 72 and 73. The first intermediate interconnect 301 is excluded from the looped wiring paths. The fifth inner through hole 310 is located away from the looped wiring paths. Thus, the heat dissipation property of the semiconductor light emitting device 10C is improved without interference with a flow of current to the semiconductor light emitting element 60.
(3-3) Multiple fifth inner through holes 310 are provided.

In this structure, the greater number of heat dissipation paths from the semiconductor light emitting element 60 to the first back surface interconnect 41 further improves the heat dissipation property of the semiconductor light emitting device 10C.
(3-4) As viewed in the z-direction, the fifth inner through holes 310 are located to overlap the capacitors 72 and 73.

In this structure, as viewed in the z-direction, the fifth inner through holes 310 are located to overlap with the looped wiring paths of the switching element 71, the capacitors 72 and 73, and the semiconductor light emitting element 60. Even when overlapping the looped wiring paths as viewed in the z-direction, the fifth inner through holes 310 are not arranged in the first front surface interconnect 31 and thus do not interfere with flow of current in the looped wiring paths. This increases the flexibility in the arrangement of the fifth inner through holes 310.

### MODIFIED EXAMPLES

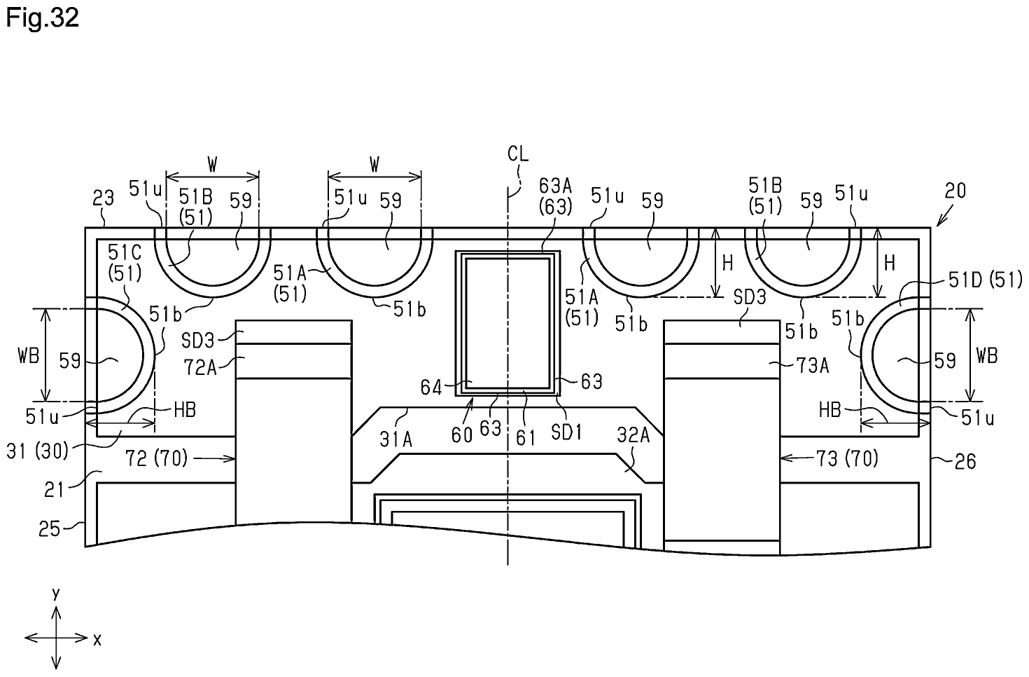

The embodiments described above may be modified as follows. The embodiments described above and the modified examples described below can be combined as long as the combined modifications remain technically consistent with each other. The modified examples will be described with reference to FIGS. 32 to 36, which do not show the first wire W1 and the encapsulation resin 80 for the sake of convenience.

In the first embodiment, the layout, the size, and the shape of the end surface through holes 51 may be changed in any manner.

In a first example, as shown in FIG. 32, the end surface through holes 51 may further be arranged in the third substrate side surface 25 and the fourth substrate side surface 26. For the sake of brevity, the end surface through hole 51 arranged in the third substrate side surface 25 is referred to as an “end surface through hole 51C,” and the end surface through hole 51 arranged in the fourth substrate side surface 26 is referred to as an “end surface through hole 51D.” The end surface through holes 51C and 51D connect the first front surface interconnect 31 and the first back surface interconnect 41. As viewed in the x-direction, the end surface through hole 51C is located to overlap the first electrode 72A of the capacitor 72. As viewed in the x-direction, the end surface through hole 51D is located to overlap the first electrode 73A of the capacitor 73. That is, the end surface through holes 51C and 51D are located closer to the second substrate side surface 24 than the end surface through holes 51A and 51B are. In the illustrated example, the end surface through holes 51C and 51D are identical in size and shape to the end surface through holes 51A and 51B. The end surface through holes 51C and 51D are formed from, for example, Cu. The material forming the end surface through holes 51C and 51D is, for example, the same as the material forming the end surface through holes 51A and 51B.

In the illustrated example, the end surface through holes 51C and 51D are filled with heat dissipation members 59. The heat dissipation members 59 filling the end surface through holes 51C and 51D are identical in size and shape to the heat dissipation members 59 filling the end surface through holes 51A and 51B. The material filling the end surface through holes 51C and 51D to form the heat dissipation members 59 is the same as the material filling the end surface through holes 51A and 51B to form the heat dissipation members 59.

In this structure, the end surface through holes 51C and 51D increase the number of paths that dissipate heat from the semiconductor light emitting element 60 to the outside of the substrate 20, thereby further improving the heat dissipation property of the semiconductor light emitting device 10A. In addition, the heat dissipation members 59 filling the end surface through holes 51C and 51D increase the volume of the heat transfer path that transfers heat from the semiconductor light emitting element 60 to the outside of the semiconductor light emitting device 10A. This further improves the heat dissipation property of the semiconductor light emitting device 10A.

The size of the end surface through holes 51C and 51D may be changed in any manner. In an example, the end surface through holes 51C and 51D may each have an opening width WB that is greater than the opening width W of the end surface through holes 51A and 51B. The end surface through holes 51C and 51D may each have a depth-wise dimension HB that is larger than the depth-wise dimension H of the end surface through holes 51A and 51B.

In the first example, at least one of the heat dissipation members 59 filling the end surface through holes 51A, 51B, 51C, and 51D may be omitted.

In the first example, the two end surface through holes 51B may be omitted. In this case, the end surface through holes 51 include the two end surface through holes 51A and the end surface through holes 51C and 51D.

In the first example, the two end surface through holes 51A may be omitted. In this case, the end surface through holes 51 include the two end surface through holes 51B and the end surface through holes 51C and 51D.

In the first example, the two end surface through holes 51A and the two end surface through holes 51B may be omitted. In this case, the end surface through holes 51 include the end surface through holes 51C and 51D. That is, the end surface through hole 51 refers to an end surface through hole that connects the first front surface interconnect 31, on which the semiconductor light emitting element 60 is mounted, and the first back surface interconnect 41, which is electrically connected to the first front surface interconnect 31.

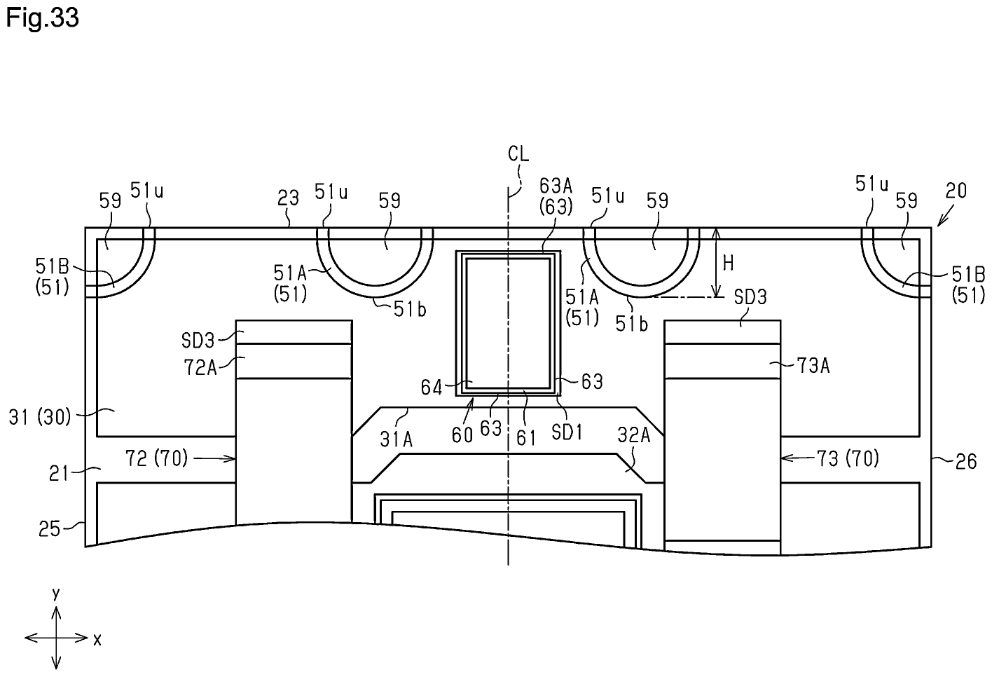

In a second example, as shown in FIG. 33, as viewed in the thickness-wise direction of the substrate 20, the end surface through holes 51B may be arranged in two of the four corners of the substrate 20 located at the first substrate side surface 23. Of the two end surface through holes 51B, the end surface through hole 51B located closer to the third substrate side surface 25 is arranged in the first substrate side surface 23 and the third substrate side surface 25. Of the two end surface through holes 51B, the end surface through hole 51B located closer to the fourth substrate side surface 26 is arranged in the first substrate side surface 23 and the fourth substrate side surface 26. In the illustrated example, as viewed in the z-direction, the end surface through hole 51B is quadrantal.

The size of the end surface through hole 51B may be changed in any manner. In an example, the end surface through hole 51B may have a radius that is greater than the radius of the end surface through hole 51A (the depth-wise dimension H of the end surface through hole 51A).

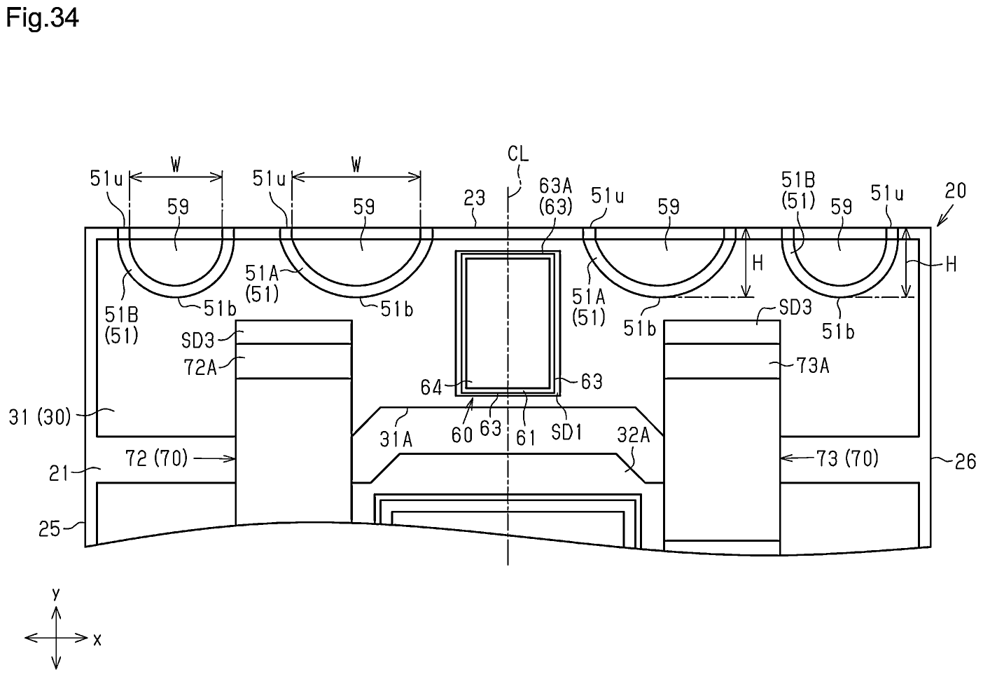

In a third example, as shown in FIG. 34, the opening width W of the two end surface through holes 51A may be greater than the opening width W of the two end surface through holes 51B.

In this structure, the two end surface through holes 51A, located close to the semiconductor light emitting element 60, are increased in volume so that heat is efficiently transferred from the semiconductor light emitting element 60 to the two end surface through holes 51A. Thus, the heat dissipation property of the semiconductor light emitting device 10A is improved. In the third example, the opening width W of the two end surface through holes 51B may be greater than the opening width W of the two end surface through holes 51A.

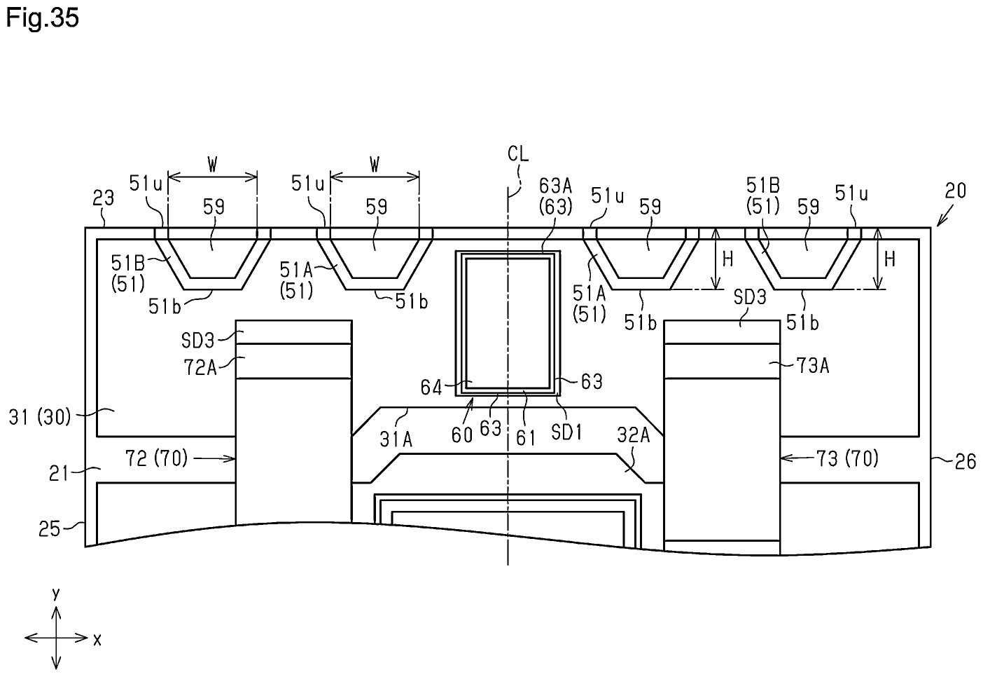

In a fourth example, the shape of the end surface through hole 51 as viewed in the z-direction is not limited to a semicircle and may be changed in any manner. In one example, as shown in FIG. 35, the shape of the end surface through hole 51 as viewed in the z-direction is a recessed trapezoid that is tapered from the first substrate side surface 23 toward the second substrate side surface 24. In addition to the first substrate side surface 23, the first front surface interconnect 31 and the first back surface interconnect 41 include a trapezoidal recess. The end surface through holes 51, which are interconnects formed from a conductive material, are arranged on the recessed trapezoidal side surfaces of the first substrate side surface 23, the first front surface interconnect 31, and the first back surface interconnect 41. The end surface through holes 51 extend along the recessed trapezoidal side surfaces. The open end 51u of the end surface through hole 51 is flush with the first substrate side surface 23. In the illustrated example, the opening width W of the end surface through hole 51 is greater than the depth-wise dimension H of the end surface through hole 51. As viewed in the z-direction, the opening width W of the end surface through hole 51 is defined by the distance in the open end 51u of the end surface through hole 51 in the x-direction. The depth-wise dimension H of the end surface through hole 51 is defined by the distance between the open end 51u of the end surface through hole 51 and a side surface 51b of the end surface through hole 51 in the y-direction.

Two or more of the first to fourth examples may be combined with each other. The first to fourth examples may be applied to the semiconductor light emitting device 10C of the third embodiment. In this case, the end surface through holes 51 connect the first front surface interconnect 31, the first intermediate interconnect 301, and the first back surface interconnect 41. In the semiconductor light emitting device 10B of the second embodiment, the semicircular shape of the end surface through hole 170 may be changed to a recessed trapezoidal shape as in the fourth example.

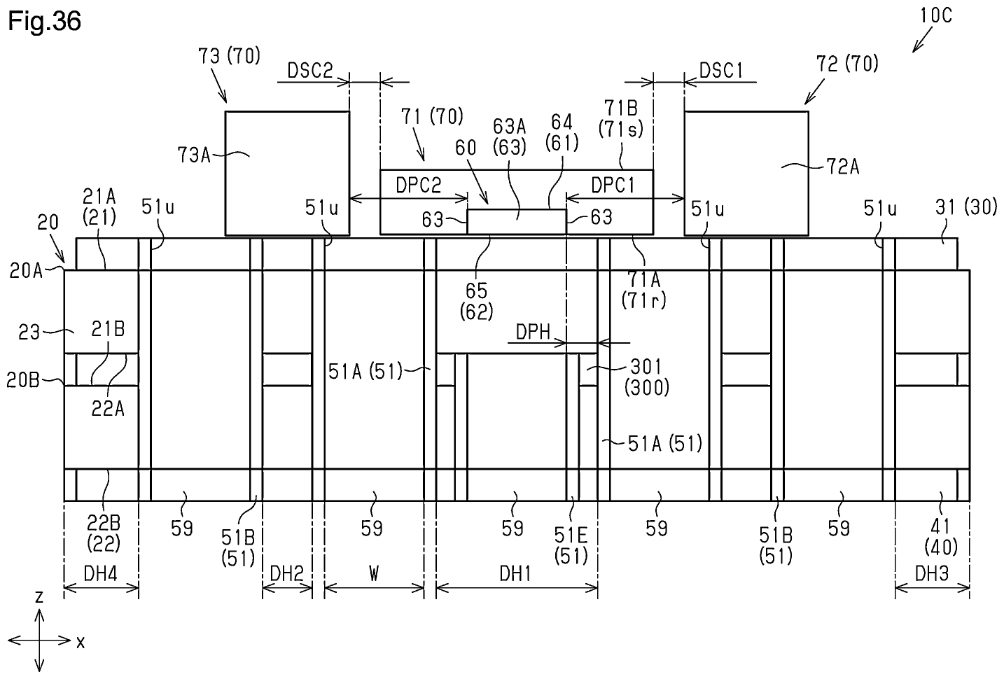

In the third embodiment, as shown in FIG. 36, the first substrate side surface 23 of the substrate 20 may include an end surface through hole 51E extending through the back surface substrate 20B and connecting the first intermediate interconnect 301 and the first back surface interconnect 41. As viewed in the z-direction, the end surface through hole 51E is located to overlap the semiconductor light emitting element 60. The end surface through hole 51E extends through the back surface substrate 20B in the thickness-wise direction but is not arranged in the front surface substrate 20A. Hence, the dimension of the end surface through hole 51E in the z-direction is smaller than the dimension of the end surface through holes 51A and 51B in the z-direction. The end surface through hole 51E corresponds to a “back surface end surface through hole.”

This structure increases the number of paths that dissipate heat from the semiconductor light emitting element 60 to the outside of the substrate 20, thereby further improving the heat dissipation property of the semiconductor light emitting device 10A. The end surface through hole 51E is arranged in the back surface substrate 20B but is not arranged in the front surface substrate 20A. Thus, the end surface through hole 51E is covered by the front surface substrate 20A in the z-direction. This limits irradiation of the end surface through holes 51 with light from the semiconductor light emitting element 60.

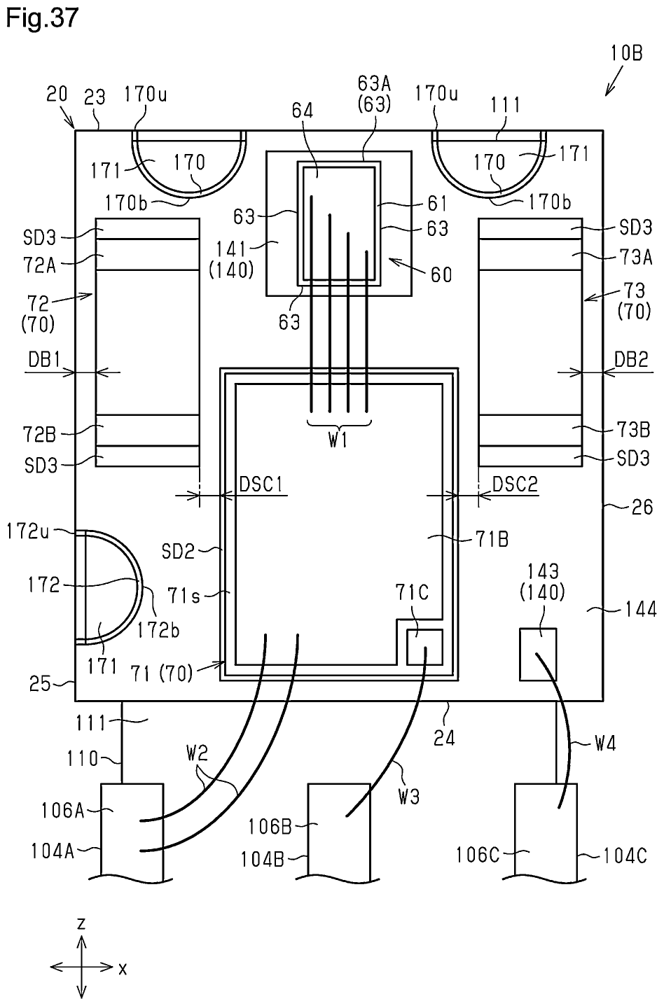

In the second embodiment, as shown in FIG. 37, the third substrate side surface 25 of the substrate 20 may include an end surface through hole 172. In this case, the end surface through hole 172 is located closer to the second substrate side surface 24 than the capacitor 72 is. The end surface through hole 172 corresponds to a “control circuit end surface through hole.”

As viewed in the y-direction, the end surface through hole 172 is, for example, semicircular. The end surface through hole 172 includes a side surface 172b and an open end 172u that is open toward the third substrate side surface 25. In the illustrated example, the end surface through hole 172 is identical in shape and size to the end surface through hole 170. The shape and the size of the end surface through hole 172 may be changed in any manner. In an example, the end surface through hole 172 may differ in shape and size from the end surface through hole 170. The number of end surface through holes 172 may be changed in any manner. In an example, multiple end surface through holes 172 may be provided.

The end surface through hole 172 may be filled with a heat dissipation member 171. The material filling the end surface through hole 172 to form the heat dissipation member 171 is the same as the material filling the end surface through hole 170 to form the heat dissipation member 171. The material filling the end surface through hole 172 to form the heat dissipation member 171 may be changed in any manner and may, for example, differ from the material filling the end surface through hole 170 to form the heat dissipation member 171. The heat dissipation member 171 filling the end surface through hole 172 corresponds to a “control circuit heat dissipation member.”

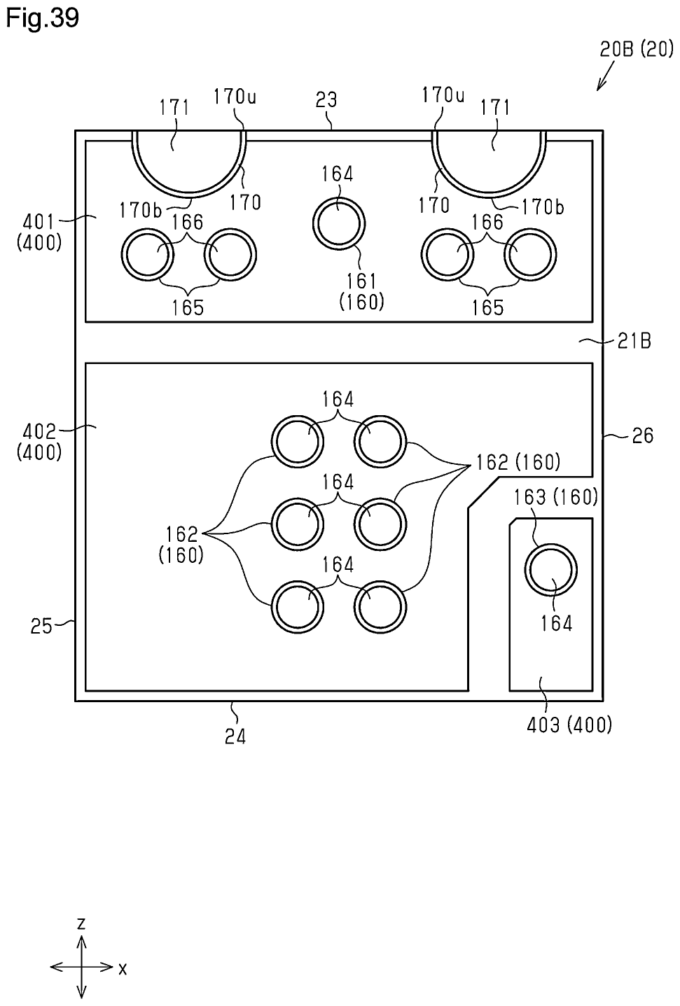

In the second embodiment, the substrate 20 of the semiconductor light emitting device 10B may have a structure in which the front surface substrate 20A and the back surface substrate 20B are stacked in the thickness-wise direction of the substrate 20 (y-direction) in the same manner as the third embodiment. In this case, the semiconductor light emitting device 10B includes an intermediate interconnect 400 (refer to FIG. 39) sandwiched between the front surface substrate 20A and the back surface substrate 20B.

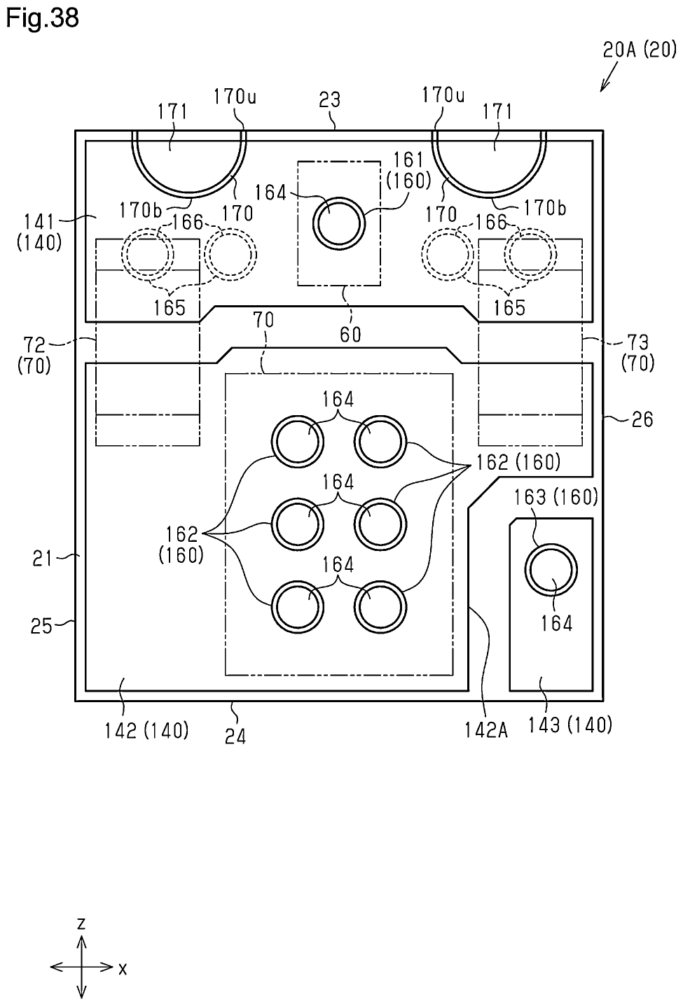

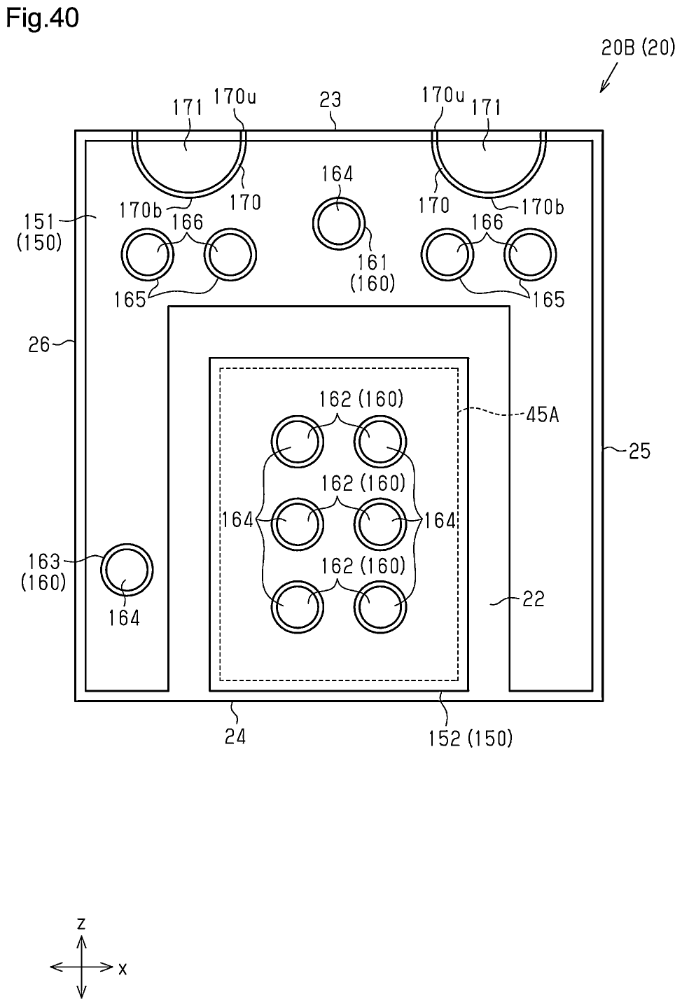

As shown in FIG. 38, the front surface interconnect 140 is formed on the substrate front surface 21A of the front surface substrate 20A. As shown in FIG. 40, the back surface interconnect 150 is formed on the substrate back surface 22B of the back surface substrate 20B. In an example, the front surface interconnect 140 and the back surface interconnect 150 are the same as the front surface interconnect 140 and the back surface interconnect 150 of the second embodiment. As shown in FIG. 38, the front surface interconnect 140 includes the first front surface interconnect 141, the second front surface interconnect 142, and the external interconnect 143. As shown in FIG. 40, the back surface interconnect 150 includes the first back surface interconnect 151 and the second back surface interconnect 152.

As shown in FIG. 39, the intermediate interconnect 400 includes a first intermediate interconnect 401, a second intermediate interconnect 402, and a third intermediate interconnect 403.

The first intermediate interconnect 401 is electrically connected to the first front surface interconnect 141 and the first back surface interconnect 151. As viewed in the y-direction, the first intermediate interconnect 401 is located to overlap the first front surface interconnect 141 and the first back surface interconnect 151. As viewed in the y-direction, the first intermediate interconnect 401 is rectangular so that the long sides extend in the x-direction and the short sides extend in the z-direction.

The second intermediate interconnect 402 is electrically connected to the second front surface interconnect 142 and the second back surface interconnect 152. As viewed in the y-direction, the second intermediate interconnect 402 is located to overlap the second front surface interconnect 142 and the first back surface interconnect 151. The second intermediate interconnect 402 is, for example, identical to the second front surface interconnect 142 in the shape as viewed in the y-direction.

The third intermediate interconnect 403 is electrically connected to the external interconnect 143 and the first back surface interconnect 151. The third intermediate interconnect 403 is located to overlap with the external interconnect 143 and the first back surface interconnect 151 as viewed in the y-direction. The third intermediate interconnect 403 is, for example, identical to the external interconnect 143 in the shape as viewed in the y-direction.

As shown in FIGS. 38 to 40, the semiconductor light emitting device 10B includes fourth inner through holes 165 in addition to the first to third inner through holes 161 to 163. The fourth inner through holes 165 each correspond to a “second inner through hole extending through the back surface substrate at a position differing from the first inner through hole as viewed in the thickness-wise direction of the substrate and connecting the intermediate interconnect and the back surface interconnect.”

The fourth inner through holes 165 each are an interconnect connecting the first intermediate interconnect 401 and the first back surface interconnect 151. The fourth inner through holes 165 electrically connect the first intermediate interconnect 401 and the first back surface interconnect 151. The fourth inner through holes 165 extend through the back surface substrate 20B. In the y-direction, that is, the thickness-wise direction of the substrate 20, the fourth inner through holes 165 are located closer to the substrate back surface 22 than to the front surface substrate 20A. The fourth inner through holes 165 are greater than the first inner through hole 161 in the dimension in the y-direction.

As viewed in the y-direction, the fourth inner through holes 165 are circular. The fourth inner through holes 165 are equal to the first to third inner through holes 161 to 163 in diameter. When the largest difference in diameter between the fourth inner through holes 165 and the first to third inner through holes 161 to 163 is, for example, within 10% of the diameter of the fourth inner through hole 165, it is considered that the fourth inner through holes 165 are equal to the first to third inner through holes 161 to 163 in diameter.

As shown in FIG. 39, multiple (in the present embodiment, four) fourth inner through holes 165 are arranged. As viewed in the y-direction, the fourth inner through holes 165 are aligned with each other in the z-direction and separated from each other in the x-direction. In the present embodiment, two of the fourth inner through holes 165 are arranged at each of opposite sides of the first inner through hole 161 in the x-direction. The fourth inner through holes 165 are located closer to the second substrate side surface 24 in the z-direction than the first inner through hole 161 is. As shown in FIG. 38, as viewed in the y-direction, one of the fourth inner through holes 165 overlaps the capacitor 72. As viewed in the y-direction, another one of the fourth inner through holes 165 overlaps the capacitor 73. In the present embodiment, the material forming the fourth inner through holes 165 is the same as the material forming the first to third inner through holes 161 to 163. The material forming the fourth inner through holes 165 may be changed in any manner. For example, the material forming the fourth inner through holes 165 may differ from the material forming the first to third inner through holes 161 to 163.

Heat dissipation members 166 are arranged in the fourth inner through holes 165. The heat dissipation members 166 fill the inside of the fourth inner through holes 165. The heat dissipation members 166 may be formed from, for example, a metal material. An example of the metal material is Cu. That is, the heat dissipation members 166 and the fourth inner through holes 165 may be formed from the same material.

The material of the heat dissipation members 166 may be changed in any manner. In an example, the heat dissipation members 166 may be formed from a metal material that differs from the metal material forming the fourth inner through holes 165. Alternatively, the heat dissipation members 166 may be formed from an insulation material having a good heat dissipation property such as ceramic instead of a metal material.

As shown in FIGS. 38 to 40, in the same manner as the second embodiment, the first substrate side surface 23 of the substrate 20 includes the two end surface through holes 170 extending through the substrate 20 in the z-direction, that is, the thickness-wise direction of the substrate 20. The shape, the size, and the arrangement of the two end surface through holes 170 are the same as those of the end surface through holes 170 (refer to FIG. 25) of the second embodiment. The end surface through holes 170 connect the first front surface interconnect 141, the first intermediate interconnect 401, and the first back surface interconnect 151. This structure obtains the same advantages as the third embodiment.

In the third embodiment, the structure of the substrate 20 may be changed in any manner. In an example, the substrate 20 may include the front surface substrate 20A, the back surface substrate 20B, and an intermediate substrate. The intermediate substrate is sandwiched between the front surface substrate 20A and the back surface substrate 20B. In this case, the intermediate interconnect 300 may include a front surface intermediate interconnect sandwiched between the front surface substrate 20A and the intermediate substrate and a back surface intermediate interconnect sandwiched between the back surface substrate 20B and the intermediate substrate. Also, the substrate 20 of the semiconductor light emitting device 10B in the second embodiment may be changed in the same manner.

In the third embodiment, the number of fifth inner through holes 310 may be changed in any manner. In an example, the number of fifth inner through holes 310 may be one, two, three, and five or greater.

In the third embodiment, the fifth inner through holes 310 may be omitted.

In the third embodiment, the end surface through holes 51 do not have to be connected to the first intermediate interconnect 301. At least one of the end surface through holes 52A and 52B do not have to be connected to the second intermediate interconnect 302.

In the first and third embodiments, the opening width W of the end surface through holes 52A and 52B may differ from the opening width W of the end surface through hole 51. The depth-wise dimension H of the end surface through holes 52A and 52B may differ from the depth-wise dimension H of the end surface through hole 51.

In the first and third embodiments, at least one of the heat dissipation members 59 filling the end surface through holes 51A and 51B may be omitted. At least one of the heat dissipation members 59 filling the end surface through holes 52A and 52B may be omitted.

In the first and third embodiments, at least one of the end surface through holes 52A and 52B may be omitted. When the end surface through holes 52A and 52B are omitted, the second front surface interconnect 32 and the second back surface interconnect 42 are electrically connected by the second inner through holes 55. In this modified example, the end surface through holes arranged in the substrate 20 are the end surface through holes 51 connecting the first front surface interconnect 31 and the first back surface interconnect 41. That is, the end surface through holes are formed in only the first substrate side surface 23 and thus are not formed in the third substrate side surface 25 and the fourth substrate side surface 26. The second inner through hole 55 corresponds to a “control circuit inner through hole.”

In the second embodiment, at least one of the heat dissipation members 171 filling the end surface through holes 170 may be omitted.

In the first and third embodiments, the encapsulation resin 80 does not have to overlap the end surface through holes 51 as viewed in the z-direction. In an example, the first encapsulation side surface 83 of the encapsulation resin 80 may include semicircular recesses as viewed in the z-direction in the same manner as the end surface through holes 51.

In the first and third embodiments, the encapsulation resin 80 does not have to overlap the end surface through holes 52A and 52B as viewed in the z-direction. In an example, the third encapsulation side surface 85 of the encapsulation resin 80 may include a semicircular recess as viewed in the z-direction in the same manner as the end surface through hole 52A. The fourth encapsulation side surface 86 of the encapsulation resin 80 may include a semicircular recess as viewed in the z-direction in the same manner as the end surface through hole 52B.

In the first and third embodiments, the encapsulation resin 80 may be omitted from the semiconductor light emitting devices 10A and 10C.

In the first and second embodiments, the heat dissipation members 58 and 164 filling the inner through holes 53 and 160 may be omitted. In the third embodiment, the heat dissipation members 311 filling the fifth inner through holes 310 may be omitted.

In the first embodiment, the positions of the capacitors 72 and 73 in the x-direction may be changed in any manner. In an example, the capacitor 72 may be arranged on the substrate 20 so that the distance between the third substrate side surface 25 of the substrate 20 and the capacitor 72 in the x-direction is less than or equal to the distance DSC1 between the capacitor 72 and the switching element 71 in the x-direction. In an example, the capacitor 73 may be arranged on the substrate 20 so that the distance between the fourth substrate side surface 26 of the substrate 20 and the capacitor 73 in the x-direction is less than or equal to the distance DSC2 between the capacitor 73 and the switching element 71 in the x-direction.

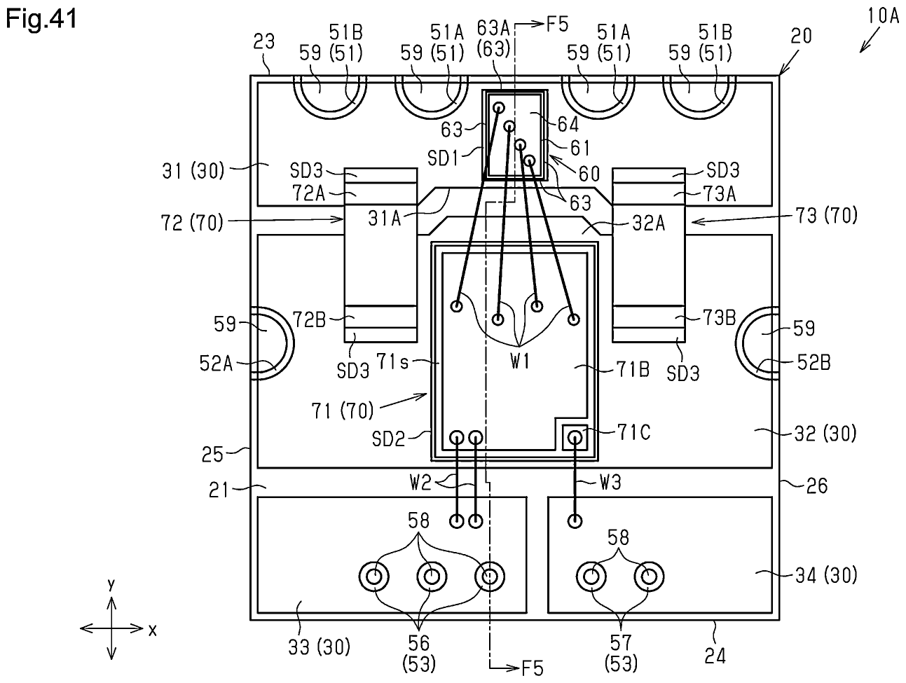

In the first and third embodiments, the positions of the capacitors 72 and 73 in the y-direction may be changed in any manner. In an example, the capacitors 72 and 73 may be arranged not to overlap the semiconductor light emitting element 60 as viewed in a direction extending along the first substrate side surface 23. In an example, as shown in FIG. 41, as viewed in a direction (x-direction) extending along the first substrate side surface 23, the capacitors 72 and 73 are located toward the second substrate side surface 24 from the semiconductor light emitting element 60. Also, in the second embodiment, the positions of the capacitors 72 and 73 in the z-direction may be changed in any manner. In an example, as viewed in a direction (x-direction) extending along the first substrate side surface 23, the capacitors 72 and 73 are located toward the second substrate side surface 24 from the semiconductor light emitting element 60.

In each embodiment, the number of capacitors may be changed in any manner. In an example, the number of capacitors may be one. The number of capacitors may be set in accordance with the amount of current supplied to the semiconductor light emitting element 60.

In each embodiment, the capacitors 72 and 73 may be omitted from the light emitting element control circuit 70.

In each embodiment, the switching element 71 may be omitted from the light emitting element control circuit 70.

In each embodiment, the light emitting element control circuit 70 may be omitted.

In each embodiment, the semiconductor light emitting devices 10A to 10C may include at least one of the diode D, the current limiting resistor R, and the driver circuit PM.

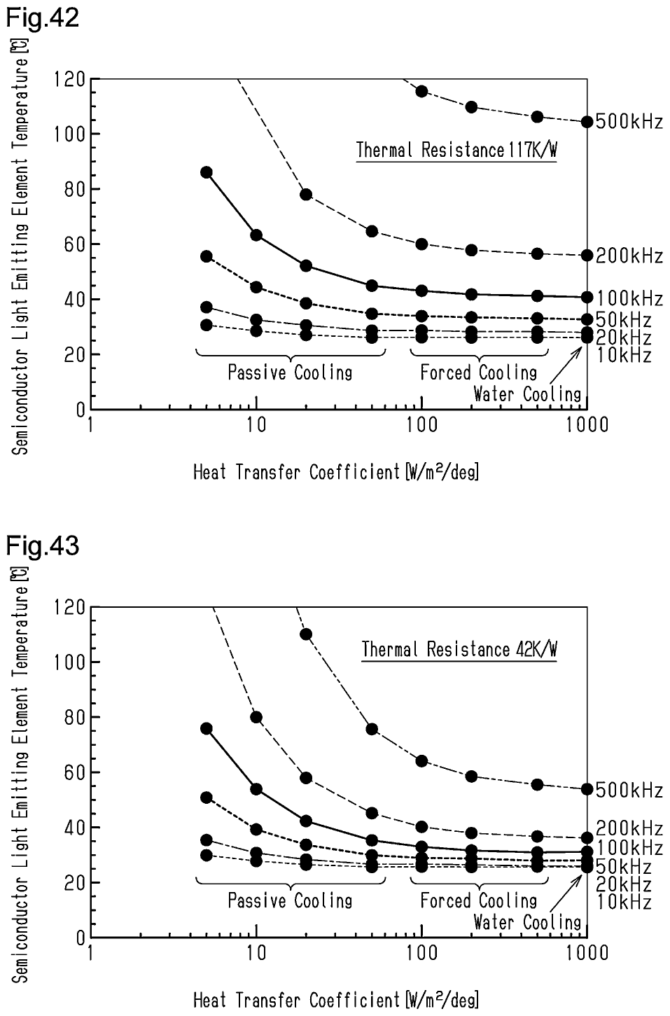

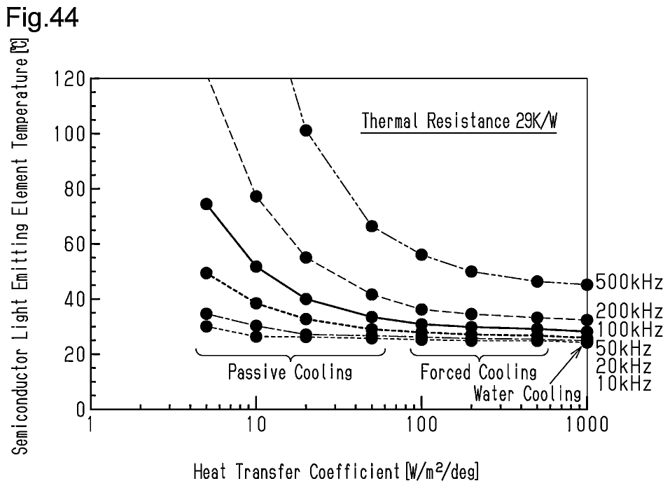

In each embodiment, the material forming the substrate 20 may be changed in any manner. In an example, the substrate 20 may be formed from a material including any one of glass epoxy resin, alumina, and aluminum nitride. FIGS. 42 to 44 are graphs showing the relationship between the temperature and the heat transfer coefficient of the semiconductor light emitting element 60 when the material of the substrate 20 is changed. FIG. 42 is a graph when glass epoxy resin is used as the material of the substrate 20. FIG. 43 is a graph when alumina is used as the material of the substrate 20. FIG. 44 is a graph when aluminum nitride is used as the material of the substrate 20.

As shown in FIGS. 42 to 44, when the material of the substrate 20 is glass epoxy resin, the thermal resistance coefficient is 117 K/W. When the material is alumina, the thermal resistance coefficient is 42K/W. When the material is aluminum nitride, the thermal resistance coefficient is 29K/W. Therefore, when the material of the substrate 20 is aluminum nitride, the heat dissipation property of the substrate 20 is improved as compared to when the material is glass epoxy resin and alumina. As described above, the material forming the substrate 20 may be changed from the glass epoxy resin to alumina or aluminum nitride based on the heat dissipation property required of the semiconductor light emitting devices 10A to 10C.

In this specification, “at least one of A and B” should be understood to mean “only A, or only B, or both A and B.”

In the present disclosure, the term “on” includes the meaning of “above” in addition to the meaning of “on” unless otherwise clearly indicated in the context. Therefore, the phrase “first member formed on second member” is intended to mean that the first member may be formed on the second member in contact with the second member in one embodiment and that the first member may be located above the second member without contacting the second member in another embodiment. In other words, the term “on” does not exclude a structure in which another member is formed between the first member and the second member.

The z-direction as referred to in the present disclosure does not necessarily have to be the vertical direction and does not necessarily have to fully conform to the vertical direction. In the structures according to the present disclosure, “upward” and “downward” in the z-direction as referred to in the present description are not limited to “upward” and “downward” in the vertical direction. In an example, the x-direction may conform to the vertical direction. In another example, the y-direction may conform to the vertical direction.

### Clauses

The technical aspects that are understood from the embodiment and the modified examples will be described below. To facilitate understanding without intention to limit, the reference signs of the elements in the embodiments are given to the corresponding elements in the clause with parentheses. The reference signs are used as examples to facilitate understanding, and the components in each clause are not limited to those components given with the reference signs.
1. A semiconductor light emitting device (10A), including:
a substrate (20) including a substrate front surface (21), a substrate back surface (22) opposite to the substrate front surface (21), and a substrate side surface (23 to 26);
a front surface interconnect (30) formed on the substrate front surface (21);
a back surface interconnect (40) formed on the substrate back surface (22); and
a semiconductor light emitting element (60) mounted on the front surface interconnect (30) and including a light emitting surface (63A) configured to emit light in a predetermined direction, in which
the substrate side surface (23 to 26) includes
   a first substrate side surface (23) facing a same direction as the light emitting surface (63A), and
   a second substrate side surface (24) opposite to the first substrate side surface (23),
   the semiconductor light emitting element (60) is located closer to the first substrate side surface (23) than to the second substrate side surface (24), and
the first substrate side surface (23) includes an end surface through hole (51/51A, 51B) extending through the substrate (20) in a thickness-wise direction (z-direction) of the substrate (20) and connecting the front surface interconnect (30) and the back surface interconnect (40).
2. The semiconductor light emitting device according to clause 1, in which as viewed in the thickness-wise direction (z-direction) of the substrate (20), the end surface through hole (51/51A, 51B) is arranged in the first substrate side surface (23) and separated from the semiconductor light emitting element (60).
3. The semiconductor light emitting device according to clause 2, in which as viewed in the thickness-wise direction (z-direction) of the substrate (20), the end surface through hole (51/51A, 51B) is located adjacent to the semiconductor light emitting element (60) in a direction extending along the first substrate side surface (23).
4. The semiconductor light emitting device according to clause 3, in which a distance (DPH) between the end surface through hole (51/51A, 51B) and the semiconductor light emitting element (60) is less than an opening width (W) of the end surface through hole (51/51A, 51B).
5. The semiconductor light emitting device according to any one of clauses 1 to 4, in which the end surface through hole (51/51A, 51B) is one of multiple end surface through holes (51/51A, 51B) located in the first substrate side surface (23).
6. The semiconductor light emitting device according to any one of clauses 1 to 5, in which as viewed in a direction (x-direction) extending along the first substrate side surface (23), the end surface through hole (51/51A, 51B) partially overlaps the semiconductor light emitting element (60).
7. The semiconductor light emitting device according to clause 6, in which a distance (DP) between the first substrate side surface (23) and the light emitting surface (63A) of the semiconductor light emitting element (60) is less than a depth-wise dimension (H) of the end surface through hole (51/51A, 51B).
8. The semiconductor light emitting device according to any one of clauses 1 to 7, in which the end surface through hole (51/51A, 51B) is filled with a heat dissipation member (59).
9. The semiconductor light emitting device according to any one of clauses 1 to 8, in which
as viewed in the thickness-wise direction (z-direction) of the substrate (20), the substrate (20) includes an inner through hole (53/54) overlapping the semiconductor light emitting element (60), and
the inner through hole (53/54) connects the front surface interconnect (30) and the back surface interconnect (40).
10. The semiconductor light emitting device according to clause 9, in which as viewed in the thickness-wise direction (z-direction) of the substrate (20), an opening width (W) of the end surface through hole (51/51A, 51B) is greater than a diameter of the inner through hole (53/54).
11. The semiconductor light emitting device according to clause 9 or 10, in which the inner through hole (53/54) is located closer to the second substrate side surface (24) than the end surface through hole (51/51A, 51B) is.
12. The semiconductor light emitting device according to any one of clauses 9 to 11, in which the inner through hole (53/54) is filled with a heat dissipation member (58).
13. The semiconductor light emitting device according to any one of clauses 1 to 12, further including:
a light emitting element control circuit (70) mounted on the front surface interconnect (30) and configured to have the semiconductor light emitting element (60) emit light.
14. The semiconductor light emitting device according to clause 13, in which
the light emitting element control circuit (70) includes a capacitor (72, 73) mounted on the front surface interconnect (30), and
as viewed in a direction (x-direction) extending along the first substrate side surface (23), the capacitor (72, 73) is located closer to the second substrate side surface (24) than the end surface through hole (51/51A, 51B) is.
15. The semiconductor light emitting device according to clause 14, in which as viewed in a direction (x-direction) extending along the first substrate side surface (23), the capacitor (72, 73) is located to overlap the semiconductor light emitting element (60).
16. The semiconductor light emitting device according to any one of clauses 13 to 15, in which
the light emitting element control circuit (70) includes a switching element (71) configured to control current supplied to the semiconductor light emitting element (60),
the front surface interconnect (30) includes
   a first front surface interconnect (31) on which the semiconductor light emitting element (60) is mounted, and
   a second front surface interconnect (32) on which the switching element (71) is mounted,
the back surface interconnect (40) includes
   a first back surface interconnect (41) overlapping the first front surface interconnect (31) as viewed in the thickness-wise direction (z-direction) of the substrate (20), and
   a second back surface interconnect (42) overlapping the second front surface interconnect (32) as viewed in the thickness-wise direction (z-direction) of the substrate (20), and
the end surface through hole (51/51A, 51B) connects the first front surface interconnect (31) and the first back surface interconnect (41).
17. The semiconductor light emitting device according to clause 16, in which
the substrate (20) includes a third substrate side surface (25) and a fourth substrate side surface (26) joining the first substrate side surface (23) and the second substrate side surface (24), and
at least one of the third substrate side surface (25) and the fourth substrate side surface (26) includes a control circuit end surface through hole (52A, 52B) connecting the second front surface interconnect (32) and the second back surface interconnect (42).
18. The semiconductor light emitting device according to clause 16 or 17, in which the substrate (20) includes a control circuit inner through hole (55) connecting the second front surface interconnect (32) and the second back surface interconnect (42).
19. The semiconductor light emitting device according to clause 14 or 15, in which
the light emitting element control circuit (70) includes a switching element (71) configured to control current supplied to the semiconductor light emitting element (60),
the front surface interconnect (30) includes
   a first front surface interconnect (31) on which the semiconductor light emitting element (60) is mounted, and
   a second front surface interconnect (32) on which the switching element (71) is mounted,
the back surface interconnect (40) includes
   a first back surface interconnect (41) overlapping the first front surface interconnect (31) as viewed in the thickness-wise direction (z-direction) of the substrate (20), and
   a second back surface interconnect (42) overlapping the second front surface interconnect (32) as viewed in the thickness-wise direction (z-direction) of the substrate (20),
   the capacitor is connected between the first front surface interconnect (31) and the second front surface interconnect (32), and
   the end surface through hole (51/51A, 51B) connects the first front surface interconnect (31) and the first back surface interconnect (41).
20. The semiconductor light emitting device according to any one of clauses 1 to 19, in which the substrate (20) includes
a front surface substrate (20A) on which the front surface interconnect (30) is formed, and
a back surface substrate (20B) on which the back surface interconnect (40) is formed,
the semiconductor light emitting device (10C), further including:
an intermediate interconnect (300) sandwiched between the front surface substrate (20A) and the back surface substrate (20B), in which the end surface through hole (51/51A, 51B) extends through the front surface substrate (20A) and the back surface substrate (20B) in the thickness-wise direction (z-direction) of the substrate (20) and connects the front surface interconnect (30), the intermediate interconnect (300), and the back surface interconnect (40).
21. The semiconductor light emitting device according to any one of clauses 1 to 20, further including:
a light-transmissive encapsulation resin (80) covering the substrate front surface (21) and the semiconductor light emitting element (60).
22. The semiconductor light emitting device according to clause 21, in which
the end surface through hole (51/51A, 51B) is filled with a heat dissipation member (59), and
as viewed in the thickness-wise direction (z-direction) of the substrate (20), the encapsulation resin (80) covers the end surface through hole (51/51A, 51B).
23. A semiconductor light emitting unit (200), including:
a stem (90) including a conductive base (100) and a conductive heat sink (110) arranged upright on the base (100), the semiconductor light emitting device (10B) according to any one of clauses 1 to 22 being mounted on the heat sink (110); and
a surrounding member (130) arranged on the base to surround the semiconductor light emitting device (10B) and the heat sink (110).
24. The semiconductor light emitting device according to clause 5, in which the end surface through holes (51/51A, 51B) are identical in size and shape.
25. The semiconductor light emitting device according to clause 5, in which
the end surface through holes (51/51A, 51B) include
   a first end surface through hole (51A) located near the semiconductor light emitting element (60), and
   a second end surface through hole (51B) located far from the semiconductor light emitting element (60), and
an opening width (W) of the first end surface through hole (51A) is greater than an opening width (W) of the second end surface through hole (51B).
26. The semiconductor light emitting device according to clause 5, in which the end surface through holes (51B) are arranged in two of four corners of the substrate (20) located at the first substrate side surface (23).
27. The semiconductor light emitting device according to clause 17, further including:
a light-transmissive encapsulation resin (80) covering the substrate front surface (21) and the semiconductor light emitting element (60), in which
the control circuit end surface through hole (52A, 52B) is filled with a control circuit heat dissipation member (59), and
as viewed in the thickness-wise direction (z-direction) of the substrate (20), the encapsulation resin (80) covers the control circuit end surface through hole (52A, 52B).
28. The semiconductor light emitting device according to clause 17 or 27, in which the substrate includes
a front surface substrate (20A) on which the front surface interconnect (30) is formed, and
a back surface substrate (20B) on which the back surface interconnect (40) is formed,
the semiconductor light emitting device (10C), further including:
an intermediate interconnect (300) sandwiched between the front surface substrate (20A) and the back surface substrate (20B),
in which the control circuit end surface through hole (52A, 52B) extends through the front surface substrate (20A) and the back surface substrate (20B) in the thickness-wise direction (z-direction) of the substrate (20) and connects the front surface interconnect (30), the intermediate interconnect (300), and the back surface interconnect (40).
29. The semiconductor light emitting device according to any one of clauses 1 to 22, in which as viewed in the thickness-wise direction (z-direction) of the substrate (20), the end surface through hole (51/51A, 51B) is semicircular.
30. The semiconductor light emitting device according to any one of clauses 9 to 12, in which
the substrate (20) includes
   a front surface substrate (20A) on which the front surface interconnect (30) is formed, and
   a back surface substrate (20B) on which the back surface interconnect (40) is formed,
the semiconductor light emitting device (10C) further including:
an intermediate interconnect (300) sandwiched between the front surface substrate (20A) and the back surface substrate (20B), in which
the inner through hole (53/54, 310) includes
   a first inner through hole (54) extending through the substrate (20) and overlapping the semiconductor light emitting element (60) as viewed in the thickness-wise direction (z-direction) of the substrate (20), and
   a second inner through hole (310) extending through the back surface substrate (20B) at a position differing from the first inner through hole (54) as viewed in the thickness-wise direction (z-direction) of the substrate (20) and connecting the intermediate interconnect (300) and the back surface interconnect (40).
31. The semiconductor light emitting device according to clause 30, in which the end surface through hole (51/51A, 51B) extends through the front surface substrate (20A) and the back surface substrate (20B) in the thickness-wise direction (z-direction) of the substrate (20) and connects the front surface interconnect (30), the intermediate interconnect (300), and the back surface interconnect (40).
32. The semiconductor light emitting device according to clause 30 or 31, in which the second inner through hole (310) is one of multiple second inner through holes.
33. The semiconductor light emitting device according to clause 20, in which the first substrate side surface (23) includes a back surface end surface through hole (51E) extending through the back surface substrate (20B) and connecting the intermediate interconnect (300) and the back surface interconnect (40).
34. The semiconductor light emitting device according to any one of clauses 1 to 20, in which the substrate (20) is formed from a material including any one of glass epoxy resin, alumina, and aluminum nitride.
35. The semiconductor light emitting device according to clause 13, in which
the light emitting element control circuit (70) includes
   a capacitor (72, 73) mounted on the front surface interconnect (30), and
   a switching element (71) configured to control current supplied to the semiconductor light emitting element (60),
the capacitor includes a first capacitor (72) and a second capacitor (73),
when a direction in which the semiconductor light emitting element (60) and the switching element (71) are arranged is referred to as a first direction (y-direction), and a direction orthogonal to the first direction (y-direction) as viewed in the thickness-wise direction (z-direction) of the substrate (20) is referred to as a second direction (x-direction), the first capacitor (72) and the second capacitor (73) are separately located at opposite sides of the semiconductor light emitting element (60) and the switching element (71) in the second direction (x-direction) adjacent to the semiconductor light emitting element (60) and the switching element (71).
36. The semiconductor light emitting device according to clause 35, in which
the switching element (71) includes a first side extending in the second direction (x-direction) and a second side extending in a direction (y-direction) orthogonal to the first side as viewed in the thickness-wise direction (z-direction) of the substrate (20), and
a distance between the first capacitor (72) and the second capacitor (73) is greater than the first side and is less than the second side.

The description above illustrates examples. One skilled in the art may recognize further possible combinations and replacements of the elements and methods (manufacturing processes) in addition to those listed for purposes of describing the techniques of the present disclosure. The present disclosure is intended to include any substitute, modification, changes included in the scope of the disclosure including the claims and the clauses.

What is claimed is:

1. A semiconductor light emitting device, comprising:
a substrate including a substrate front surface, a substrate back surface opposite to the substrate front surface, and a substrate side surface;
a front surface interconnect formed on the substrate front surface;
a back surface interconnect formed on the substrate back surface; and
a semiconductor light emitting element mounted on the front surface interconnect and including a light emitting surface configured to emit light in a predetermined direction, wherein
the substrate side surface includes
a first substrate side surface facing a same direction as the light emitting surface, and
a second substrate side surface opposite to the first substrate side surface,
the semiconductor light emitting element is located closer to the first substrate side surface than to the second substrate side surface, and
the first substrate side surface includes an end surface through hole extending through the substrate in a thickness-wise direction of the substrate and connecting the front surface interconnect and the back surface interconnect.

2. The semiconductor light emitting device according to claim 1, wherein as viewed in the thickness-wise direction of the substrate, the end surface through hole is arranged in the first substrate side surface and separated from the semiconductor light emitting element.

3. The semiconductor light emitting device according to claim 2, wherein as viewed in the thickness-wise direction of the substrate, the end surface through hole is located adjacent to the semiconductor light emitting element in a direction extending along the first substrate side surface.

4. The semiconductor light emitting device according to claim 3, wherein a distance between the end surface through hole and the semiconductor light emitting element is less than an opening width of the end surface through hole.

5. The semiconductor light emitting device according to claim 1, wherein the end surface through hole is one of multiple end surface through holes located in the first substrate side surface.

6. The semiconductor light emitting device according to claim 1, wherein as viewed in a direction extending along the first substrate side surface, the end surface through hole partially overlaps the semiconductor light emitting element.

7. The semiconductor light emitting device according to claim 6, wherein a distance between the first substrate side surface and the light emitting surface of the semiconductor light emitting element is less than a depth-wise dimension of the end surface through hole.

8. The semiconductor light emitting device according to claim 1, wherein the end surface through hole is filled with a heat dissipation member.

9. The semiconductor light emitting device according to claim 1, wherein
as viewed in the thickness-wise direction of the substrate, the substrate includes an inner through hole overlapping the semiconductor light emitting element, and
the inner through hole connects the front surface interconnect and the back surface interconnect.

10. The semiconductor light emitting device according to claim 9, wherein as viewed in the thickness-wise direction of the substrate, an opening width of the end surface through hole is greater than a diameter of the inner through hole.

11. The semiconductor light emitting device according to claim 9, wherein the inner through hole is located closer to the second substrate side surface than the end surface through hole is.

12. The semiconductor light emitting device according to claim 9, wherein the inner through hole is filled with a heat dissipation member.

13. The semiconductor light emitting device according to claim 1, further comprising:
a light emitting element control circuit mounted on the front surface interconnect and configured to have the semiconductor light emitting element emit light.

14. The semiconductor light emitting device according to claim 13, wherein
the light emitting element control circuit includes a capacitor mounted on the front surface interconnect, and
as viewed in a direction extending along the first substrate side surface, the capacitor is located closer to the second substrate side surface than the end surface through hole is.

15. The semiconductor light emitting device according to claim 14, wherein as viewed in a direction extending along the first substrate side surface, the capacitor is located to overlap the semiconductor light emitting element.

16. The semiconductor light emitting device according to claim 13, wherein
the light emitting element control circuit includes a switching element configured to control current supplied to the semiconductor light emitting element,
the front surface interconnect includes
a first front surface interconnect on which the semiconductor light emitting element is mounted, and
a second front surface interconnect on which the switching element is mounted,
the back surface interconnect includes
a first back surface interconnect overlapping the first front surface interconnect as viewed in the thickness-wise direction of the substrate, and
a second back surface interconnect overlapping the second front surface interconnect as viewed in the thickness-wise direction of the substrate, and
the end surface through hole connects the first front surface interconnect and the first back surface interconnect.

17. The semiconductor light emitting device according to claim 16, wherein
the substrate includes a third substrate side surface and a fourth substrate side surface joining the first substrate side surface and the second substrate side surface, and
at least one of the third substrate side surface and the fourth substrate side surface includes a control circuit end surface through hole connecting the second front surface interconnect and the second back surface interconnect.

18. The semiconductor light emitting device according to claim 1, wherein the substrate includes
a front surface substrate on which the front surface interconnect is formed, and
a back surface substrate on which the back surface interconnect is formed,
the semiconductor light emitting device, further comprising:
an intermediate interconnect sandwiched between the front surface substrate and the back surface substrate,
wherein the end surface through hole extends through the front surface substrate and the back surface substrate in the thickness-wise direction of the substrate and connects the front surface interconnect, the intermediate interconnect, and the back surface interconnect.

19. The semiconductor light emitting device according to claim 1, further comprising:
a light-transmissive encapsulation resin covering the substrate front surface and the semiconductor light emitting element.

20. The semiconductor light emitting device according to claim 19, wherein
the end surface through hole is filled with a heat dissipation member, and
as viewed in the thickness-wise direction of the substrate, the encapsulation resin covers the end surface through hole.
